(19) United States
(12) Patent Application Publication
(10) Pub. No.: US 2024/0237345 A1
(43) Pub. Date: Jul. 11, 2024

(54) THREE-DIMENSIONAL MEMORY DEVICE WITH HYBRID SUPPORT STRUCTURES AND METHODS OF MAKING THE SAME

(71) Applicant: SANDISK TECHNOLOGIES LLC, ADDISON, TX (US)

(72) Inventors: Kazuyuki IWATA, Yokkaichi (JP); Yusuke IKAWA, Yokohama (JP); Kei SAMURA, Yokohama (JP); Zhiwei CHEN, Nagoya (JP)

(21) Appl. No.: 18/355,860

(22) Filed: Jul. 20, 2023

Related U.S. Application Data
(60) Provisional application No. 63/478,526, filed on Jan. 5, 2023.

(51) Int. Cl. H10B 43/27; H10B 41/27

(52) U.S. Cl. CPC H10B 43/27; H10B 41/27

(57) ABSTRACT

A three-dimensional memory device includes a first-tier alternating stack of first insulating layers and first electrically conductive layers, a second-tier alternating stack of second insulating layers and second electrically conductive layers overlying the first-tier alternating stack, memory openings vertically extending through the second-tier alternating stack and the first-tier alternating stack, memory opening fill structures located in the memory openings, wherein each of the memory opening fill structures includes a respective vertical stack of memory elements and a respective vertical semiconductor channel including a respective portion of a semiconductor material, and hybrid support structures vertically extending at least through a respective subset of layers within the first-tier alternating stack. Each of the hybrid support structures includes a respective vertical stack of a dielectric support pillar and a composite support pillar having a respective dielectric outer surface and including a respective additional portion of the semiconductor material.

### FIELD

The present disclosure relates generally to the field of semiconductor devices, and particular to a three-dimensional memory device including hybrid support structures and methods of manufacturing the same.

### BACKGROUND

A three-dimensional memory device including three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device is provided, which comprises: a first-tier alternating stack of first insulating layers and first electrically conductive layers; a second-tier alternating stack of second insulating layers and second electrically conductive layers overlying the first-tier alternating stack; memory openings vertically extending through the second-tier alternating stack and the first-tier alternating stack; memory opening fill structures located in the memory openings, wherein each of the memory opening fill structures comprises a respective vertical stack of memory elements and a respective vertical semiconductor channel including a respective portion of a semiconductor material; and hybrid support structures vertically extending at least through a respective subset of layers within the first-tier alternating stack, wherein each of the hybrid support structures comprises a respective vertical stack of a dielectric support pillar and a composite support pillar having a respective dielectric outer surface and including a respective additional portion of the semiconductor material.

According to another aspect of the present disclosure, a method of forming a three-dimensional memory device is provided. The method comprises: forming a first-tier alternating stack of first insulating layers and first sacrificial material layers over a substrate; forming first-tier memory openings and first-tier support openings through the first-tier alternating stack; forming first-tier sacrificial memory opening fill structures in the first-tier memory openings; forming dielectric support pillars in the first-tier support openings; forming a second-tier alternating stack of second insulating layers and second sacrificial material layers over the second-tier alternating stack; forming second-tier memory openings over the first-tier sacrificial memory opening fill structures and forming second-tier support openings over the dielectric support pillars; forming inter-tier memory openings by removing the first-tier sacrificial memory opening fill structures from underneath the second-tier memory openings; forming memory opening fill structures in the inter-tier memory openings and forming composite support pillars in the second-tier support openings by depositing and patterning at least a memory material and a semiconductor material in each of the inter-tier memory openings and the second-tier support openings, wherein each of the memory opening fill structures comprises a respective vertical stack of memory elements comprising portions of the memory material and a respective vertical semiconductor channel comprising a portion of the semiconductor material; and replacing the first sacrificial material layers and the second sacrificial material layers with first electrically conductive layers and second electrically conductive layers, respectively.

According to yet another aspect of the present disclosure, a method of forming a three-dimensional memory device is provided. The method comprises: forming a first-tier alternating stack of first insulating layers and first sacrificial material layers over a substrate; forming a second-tier alternating stack of second insulating layers and second sacrificial material layers over the second-tier alternating stack; forming inter-tier memory openings and inter-tier support openings that vertically extend through the first-tier alternating stack and the second-tier alternating stack; forming memory opening fill structures and support pillar structures in the inter-tier memory openings and in the inter-tier support openings, respectively, by depositing and patterning at least a memory material and a semiconductor material in each of the inter-tier memory openings and the inter-tier support openings, wherein each of the memory opening fill structures and the support pillar structures comprises a respective vertical stack of memory elements comprising portions of the memory material and a respective vertical semiconductor channel comprising a portion of the semiconductor material; replacing an upper portion of each of the support pillar structures with a dielectric support pillar, wherein a remaining portion of each of the support pillar structures comprises a composite support pillar including a respective remaining portion of the memory material and a respective remaining portion of the semiconductor material; and replacing the first sacrificial material layers and the second sacrificial material layers with first electrically conductive layers and second electrically conductive layers, respectively.

### BRIEF DESCRIPTION OF THE DRAWINGS

FIG. 1A is a vertical cross-sectional view of a first exemplary structure after formation of semiconductor devices, lower level dielectric layers, lower metal interconnect structures, and in-process source level material layers on a semiconductor substrate according to a first embodiment of the present disclosure.

FIG. 1B is a top-down view of the first exemplary structure of FIG. 1A. The hinged vertical plane A-A′ is the plane of the vertical cross-sectional view of FIG. 1A.

FIG. 1C is a magnified view of the in-process source level material layers along the vertical plane C-C′ of FIG. 1B.

FIG. 2 is a vertical cross-sectional view of the first exemplary structure after formation of a first-tier alternating stack of first insulting layers and first spacer material layers according to the first embodiment of the present disclosure.

FIG. 3 is a vertical cross-sectional view of the first exemplary structure after patterning a first-tier staircase region, a first retro-stepped dielectric material portion, and an inter-tier dielectric layer according to the first embodiment of the present disclosure.

FIG. 4A is a vertical cross-sectional view of the first exemplary structure after formation of first-tier memory openings and first-tier support openings according to the first embodiment of the present disclosure.

FIG. 4B is a horizontal cross-sectional view of the first exemplary structure along the horizontal plane B-B′ of FIG. 4A. The hinged vertical plane A-A′ corresponds to the plane of the vertical cross-sectional view of FIG. 4A.

FIG. 4C is a magnified view of a portion of the first exemplary structure of FIG. 4A in region C shown in FIG. 4B.

FIG. 5A is a vertical cross-sectional view of the first exemplary structure after formation of a sacrificial mask material layer according to the first embodiment of the present disclosure.

FIG. 5B is a top-down view of the first exemplary structure of FIG. 5A. The hinged vertical plane A-A′ is the plane of the vertical cross-sectional view of FIG. 5A.

FIG. 6 is a vertical cross-sectional view of the first exemplary structure after deposition of at least one dielectric fill material layer according to the first embodiment of the present disclosure.

FIG. 7A is a vertical cross-sectional view of the first exemplary structure after formation of dielectric support pillars according to the first embodiment of the present disclosure.

FIG. 7B is a top-down view of the first exemplary structure of FIG. 7A. The hinged vertical plane A-A′ is the plane of the vertical cross-sectional view of FIG. 7A.

FIG. 7C is a magnified view of a portion of the first exemplary structure of FIG. 7A in region C shown in FIG. 7B.

FIG. 8A is a vertical cross-sectional view of the first exemplary structure after formation of first-tier sacrificial opening fill structures according to the first embodiment of the present disclosure.

FIG. 8B is a top-down view of the first exemplary structure of FIG. 8A. The hinged vertical plane A-A′ is the plane of the vertical cross-sectional view of FIG. 8A.

FIG. 8C is a magnified view of a portion of the first exemplary structure of FIG. 8A in region C shown in FIG. 8B.

FIG. 9 is a vertical cross-sectional view of the first exemplary structure after formation of a second-tier alternating stack of second insulating layers and second spacer material layers, second stepped surfaces, and a second retro-stepped dielectric material portion according to the first embodiment of the present disclosure.

FIG. 10A is a vertical cross-sectional view of the first exemplary structure after formation of second-tier memory openings and second-tier support openings according to the first embodiment of the present disclosure.

FIG. 10B is a horizontal cross-sectional view of the first exemplary structure along the horizontal plane B-B′ of FIG. 10A. The hinged vertical plane A-A′ corresponds to the plane of the vertical cross-sectional view of FIG. 10A.

FIG. 11 is a vertical cross-sectional view of the first exemplary structure after formation of inter-tier memory openings and inter-tier support openings according to the first embodiment of the present disclosure.

FIGS. 12A-12D illustrate sequential vertical cross-sectional views of an inter-tier memory opening or an inter-tier support opening during formation of a memory opening fill structure or a support pillar structure according to the first embodiment of the present disclosure.

FIGS. 13A-13D illustrate sequential vertical cross-sectional views of a region overlying a dielectric support pillar during formation of a composite support pillar according to the first embodiment of the present disclosure.

FIG. 14A is a vertical cross-sectional view of the first exemplary structure after formation of memory opening fill structures and support pillar structures according to the first embodiment of the present disclosure.

FIG. 14B is a horizontal cross-sectional view of the first exemplary structure along the horizontal plane B-B′ of FIG. 14A. The hinged vertical plane A-A′ corresponds to the plane of the vertical cross-sectional view of FIG. 14A.

FIG. 15A is a vertical cross-sectional view of the first exemplary structure after formation of a first contact-level dielectric layer and backside trenches according to the first embodiment of the present disclosure.

FIG. 15B is a horizontal cross-sectional view of the first exemplary structure along the horizontal plane B-B′ of FIG. 15A. The hinged vertical plane A-A′ corresponds to the plane of the vertical cross-sectional view of FIG. 15A.

FIG. 15C is a magnified view of a region of the first exemplary structure of FIG. 15A.

FIG. 16 is a vertical cross-sectional view of the first exemplary structure after formation of backside trench spacers according to the first embodiment of the present disclosure.

FIGS. 17A-17E illustrate sequential vertical cross-sectional views of memory opening fill structures and a backside trench during formation of source-level material layers according to the first embodiment of the present disclosure.

FIG. 18 is a vertical cross-sectional view of the first exemplary structure after formation of source-level material layers according to the first embodiment of the present disclosure.

FIG. 19 is a vertical cross-sectional view of the first exemplary structure after formation of backside recesses according to the first embodiment of the present disclosure.

FIG. 20A is a vertical cross-sectional view of the first exemplary structure after formation of electrically conductive layers according to the first embodiment of the present disclosure.

FIG. 20B is a horizontal cross-sectional view of the first exemplary structure along the horizontal plane B-B′ of FIG. 20A. The hinged vertical plane A-A′ corresponds to the plane of the vertical cross-sectional view of FIG. 20A.

FIG. 21A is a vertical cross-sectional view of the first exemplary structure after formation of backside trench fill structures in the backside trenches according to the first embodiment of the present disclosure.

FIG. 21B is a magnified view of a region of the first exemplary structure of FIG. 21A.

FIG. 22A is a vertical cross-sectional view of the first exemplary structure after formation of a second contact-level dielectric layer and various contact via structures according to the first embodiment of the present disclosure.

FIG. 22B is a horizontal cross-sectional view of the first exemplary structure along the vertical plane B-B′ of FIG. 22A. The hinged vertical plane A-A′ corresponds to the plane of the vertical cross-sectional view of FIG. 22A.

FIG. 22C is a vertical cross-sectional view of the first exemplary structure along the vertical plane C-C′.

FIG. 23 is a vertical cross-sectional view of the first exemplary structure after formation of through-memory-level via structures and upper metal line structures according to the first embodiment of the present disclosure.

FIG. 24A is a vertical cross-sectional view of a second exemplary structure after formation of first-tier sacrificial opening fill structures according to a second embodiment of the present disclosure.

FIG. 24B is a top-down view of the second exemplary structure of FIG. 24A. The hinged vertical plane A-A′ is the plane of the vertical cross-sectional view of FIG. 24A.

FIG. 24C is a magnified view of a portion of the second exemplary structure of FIG. 24A.

FIG. 25A is a vertical cross-sectional view of the second exemplary structure after formation of a second-tier alternating stack of second insulating layers and second spacer material layers, second stepped surfaces, a second retro-stepped dielectric material portion, second-tier memory openings, and second-tier support openings according to the second embodiment of the present disclosure.

FIG. 25B is a horizontal cross-sectional view of the second exemplary structure along the horizontal plane B-B′ of FIG. 25A. The hinged vertical plane A-A′ corresponds to the plane of the vertical cross-sectional view of FIG. 25A.

FIG. 26 is a vertical cross-sectional view of the second exemplary structure after formation of inter-tier memory openings and inter-tier support openings according to the second embodiment of the present disclosure.

FIG. 27A is a vertical cross-sectional view of the second exemplary structure after formation of memory opening fill structures and support pillar structures according to the second embodiment of the present disclosure.

FIG. 27B is a horizontal cross-sectional view of the second exemplary structure along the horizontal plane B-B′ of FIG. 27A. The hinged vertical plane A-A′ corresponds to the plane of the vertical cross-sectional view of FIG. 27A.

FIG. 27C is a magnified view of a memory opening fill structure in the second exemplary structure of FIGS. 27A and 27B.

FIG. 27D is a magnified view of a support pillar structure in the second exemplary structure of FIGS. 27A and 27B.

FIG. 28A is a vertical cross-sectional view of the second exemplary structure after formation of a patterned photoresist layer and removal of upper portions of an unmasked subset of the support pillar structures according to the second embodiment of the present disclosure.

FIG. 28B is a top-down view of the second exemplary structure of FIG. 28A. The hinged vertical plane A-A′ is the plane of the vertical cross-sectional view of FIG. 28A.

FIG. 28C is a magnified view of a region of the first exemplary structure of FIG. 28A around a region in which a composite support pillar is to be formed.

FIG. 29A is a vertical cross-sectional view of the second exemplary structure after deposition of at least one dielectric fill material layer according to the second embodiment of the present disclosure.

FIG. 29B is a magnified view of a region of the first exemplary structure of FIG. 29A around a composite support pillar.

FIG. 30A is a vertical cross-sectional view of the second exemplary structure after formation of dielectric support pillars according to the second embodiment of the present disclosure.

FIG. 30B is a top-down view of the second exemplary structure of FIG. 30A. The hinged vertical plane A-A′ is the plane of the vertical cross-sectional view of FIG. 30A.

FIG. 30C is a magnified view of a portion of the second exemplary structure of FIG. 30A around a hybrid support structure.

FIG. 31A is a vertical cross-sectional view of the second exemplary structure after formation of a first contact-level dielectric layer and backside trenches according to the second embodiment of the present disclosure.

FIG. 31B is a magnified view of a portion of the second exemplary structure of FIG. 31A around a hybrid support structure.

FIG. 32 is a vertical cross-sectional view of the second exemplary structure after formation of backside trench spacers according to the second embodiment of the present disclosure.

FIG. 33 is a vertical cross-sectional view of the second exemplary structure after formation of source-level material layers according to the second embodiment of the present disclosure.

FIG. 34A is a vertical cross-sectional view of the second exemplary structure after replacement of sacrificial material layers with electrically conductive layers according to the second embodiment of the present disclosure.

FIG. 34B is a horizontal cross-sectional view of the second exemplary structure along the horizontal plane B-B′ of FIG. 34A. The hinged vertical plane A-A′ corresponds to the plane of the vertical cross-sectional view of FIG. 34A.

FIG. 35A is a vertical cross-sectional view of the second exemplary structure after formation of backside trench fill structures in the backside trenches according to the second embodiment of the present disclosure.

FIG. 35B is a magnified view of a region of the second exemplary structure of FIG. 35A.

FIG. 36A is a vertical cross-sectional view of the second exemplary structure after formation of a second contact-level dielectric layer and various contact via structures according to the second embodiment of the present disclosure.

FIG. 36B is a horizontal cross-sectional view of the second exemplary structure along the vertical plane B-B′ of FIG. 36A. The hinged vertical plane A-A′ corresponds to the plane of the vertical cross-sectional view of FIG. 36A.

FIG. 36C is a vertical cross-sectional view of the second exemplary structure along the vertical plane C-C′.

FIG. 37 is a vertical cross-sectional view of the second exemplary structure after formation of through-memory-level via structures and upper metal line structures according to the second embodiment of the present disclosure.

FIG. 38A is a plan view of a third exemplary structure including a semiconductor die that contains multiple three-dimensional memory array regions according to a third embodiment of the present disclosure.

FIG. 38B is a schematic see-through top-down view of region M1 of the semiconductor die illustrated in FIG. 38A.

FIG. 38C is a schematic vertical cross-sectional view of a region of the semiconductor die along the vertical plane C-C′ of FIG. 38B.

FIG. 38D is a schematic vertical cross-sectional view of a region of the semiconductor die along the vertical plane D-D′ of FIG. 38B.

FIG. 38E is a schematic vertical cross-sectional view of a region of the semiconductor die along the vertical plane E-E′ of FIG. 38B.

FIG. 38F is a schematic vertical cross-sectional view of a region of the semiconductor die along the vertical plane F-F′ of FIG. 38B.

### DETAILED DESCRIPTION

As discussed above, embodiments of the present disclosure include three-dimensional memory devices including hybrid support structures and methods of manufacturing the same, the various aspects of which are described herein in detail. Embodiments of the present disclosure may be used to form various semiconductor devices, such as three-dimensional memory array devices comprising a plurality of NAND memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁵ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁻⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

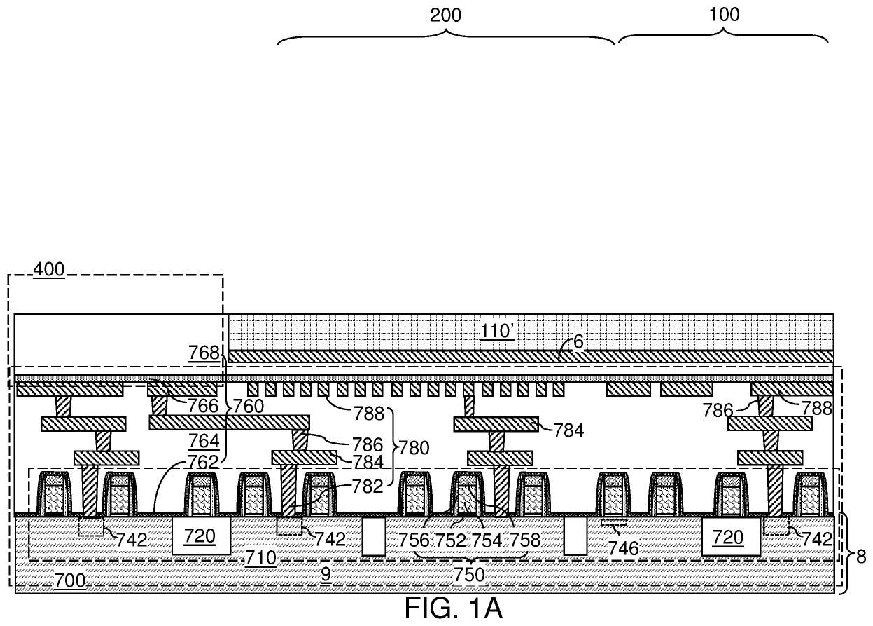

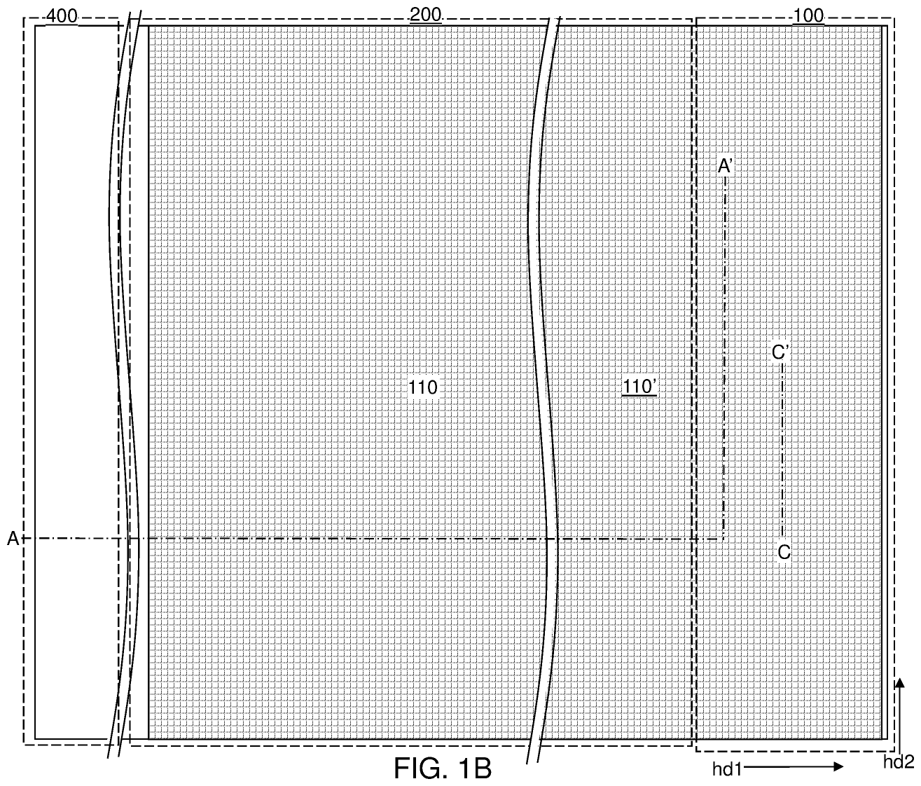

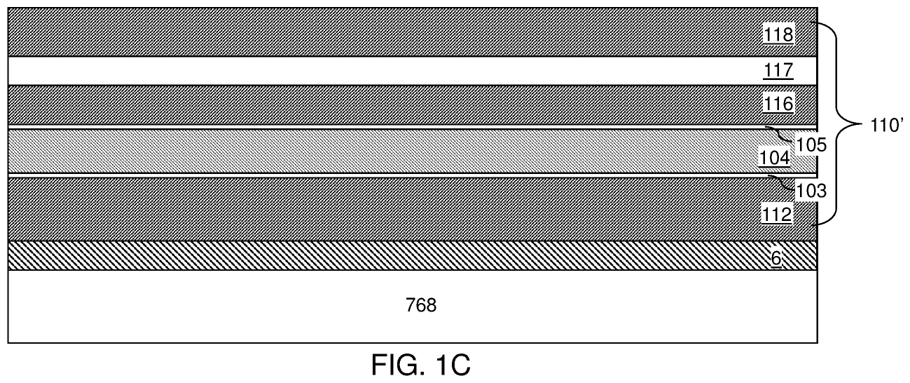

Referring to FIGS. 1A-1C, a first exemplary structure according to the first embodiment of the present disclosure is illustrated. FIG. 1C is a magnified view of an in-process source-level material layers 110′ illustrated in FIGS. 1A and 1B. The first exemplary structure includes a substrate 8 and semiconductor devices 710 formed thereupon. The substrate 8 includes a substrate semiconductor layer 9 at least at an upper portion thereof. Shallow trench isolation structures 720 may be formed in an upper portion of the substrate semiconductor layer 9 to provide electrical isolation from other semiconductor devices. The semiconductor devices 710 may include, for example, field effect transistors including respective transistor active regions 742 (i.e., source regions and drain regions), channel regions 746, and gate structures 750. The field effect transistors may be arranged in a CMOS configuration. Each gate structure 750 may include, for example, a gate dielectric 752, a gate electrode 754, a dielectric gate spacer 756 and a gate cap dielectric 758. The semiconductor devices 710 may include any semiconductor circuitry to support operation of a memory structure to be subsequently formed, which is typically referred to as a driver circuitry, which is also known as peripheral circuitry. As used herein, a peripheral circuitry refers to any, each, or all, of word line decoder circuitry, word line switching circuitry, bit line decoder circuitry, bit line sensing and/or switching circuitry, power supply/distribution circuitry, data buffer and/or latch, or any other semiconductor circuitry that may be implemented outside a memory array structure for a memory device. For example, the semiconductor devices may include word line switching devices for electrically biasing word lines of three-dimensional memory structures to be subsequently formed.

Dielectric material layers are formed over the semiconductor devices, which are herein referred to as lower-level dielectric material layers 760. The lower-level dielectric material layers 760 may include, for example, a dielectric liner 762 (such as a silicon nitride liner that blocks diffusion of mobile ions and/or apply appropriate stress to underlying structures), first dielectric material layers 764 that overlie the dielectric liner 762, a silicon nitride layer (e.g., hydrogen diffusion barrier) 766 that overlies the first dielectric material layers 764, and at least one second dielectric layer 768. The dielectric layer stack including the lower-level dielectric material layers 760 functions as a matrix for lower-level metal interconnect structures 780 that provide electrical wiring to and from the various nodes of the semiconductor devices and landing pads for through-memory-level contact via structures to be subsequently formed. The lower-level metal interconnect structures 780 are formed within the dielectric layer stack of the lower-level dielectric material layers 760, and comprise a lower-level metal line structure located under and optionally contacting a bottom surface of the silicon nitride layer 766.

For example, the lower-level metal interconnect structures 780 may be formed within the first dielectric material layers 764. The first dielectric material layers 764 may be a plurality of dielectric material layers in which various elements of the lower-level metal interconnect structures 780 are sequentially formed. Each dielectric material layer selected from the first dielectric material layers 764 may include any of doped silicate glass, undoped silicate glass, organosilicate glass, silicon nitride, silicon oxynitride, and dielectric metal oxides (such as aluminum oxide). In one embodiment, the first dielectric material layers 764 may comprise, or consist essentially of, dielectric material layers having dielectric constants that do not exceed the dielectric constant of undoped silicate glass (silicon oxide) of 3.9. The lower-level metal interconnect structures 780 may include various device contact via structures 782 (e.g., source and drain electrodes which contact the respective source and drain nodes of the device or gate electrode contacts), intermediate lower-level metal line structures 784, lower-level metal via structures 786, and landing-pad-level metal line structures 788 that are configured to function as landing pads for through-memory-level contact via structures to be subsequently formed.

The landing-pad-level metal line structures 788 may be formed within a topmost dielectric material layer of the first dielectric material layers 764 (which may be a plurality of dielectric material layers). Each of the lower-level metal interconnect structures 780 may include a metallic nitride liner and a metal fill structure. Top surfaces of the landing-pad-level metal line structures 788 and the topmost surface of the first dielectric material layers 764 may be planarized by a planarization process, such as chemical mechanical planarization. The silicon nitride layer 766 may be formed directly on the top surfaces of the landing-pad-level metal line structures 788 and the topmost surface of the first dielectric material layers 764.

The at least one second dielectric material layer 768 may include a single dielectric material layer or a plurality of dielectric material layers. Each dielectric material layer selected from the at least one second dielectric material layer 768 may include any of doped silicate glass, undoped silicate glass, and organosilicate glass. In one embodiment, the at least one first second material layer 768 may comprise, or consist essentially of, dielectric material layers having dielectric constants that do not exceed the dielectric constant of undoped silicate glass (silicon oxide) of 3.9.

An optional layer of a metallic material and a layer of a semiconductor material may be deposited over, or within patterned recesses of, the at least one second dielectric material layer 768, and is lithographically patterned to provide an optional conductive plate layer 6 and in-process source-level material layers 110′. The optional conductive plate layer 6, if present, provides a high conductivity conduction path for electrical current that flows into, or out of, the in-process source-level material layers 110′. The optional conductive plate layer 6 includes a conductive material such as a metal or a heavily doped semiconductor material. The optional conductive plate layer 6, for example, may include a tungsten layer having a thickness in a range from 3 nm to 100 nm, although lesser and greater thicknesses may also be used. A metal nitride layer (not shown) may be provided as a diffusion barrier layer on top of the conductive plate layer 6. The conductive plate layer 6 may function as a special source line in the completed device. In addition, the conductive plate layer 6 may comprise an etch stop layer and may comprise any suitable conductive, semiconductor or insulating layer. The optional conductive plate layer 6 may include a metallic compound material such as a conductive metallic nitride (e.g., TiN) and/or a metal (e.g., W). The thickness of the optional conductive plate layer 6 may be in a range from 5 nm to 100 nm, although lesser and greater thicknesses may also be used.

The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, a lower sacrificial liner 103, a source-level sacrificial layer 104, an upper sacrificial liner 105, an upper source-level semiconductor layer 116, a source-level insulating layer 117, and an optional source-select-level conductive layer 118.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selective to the lower sacrificial liner 103 and the upper sacrificial liner 105. In one embodiment, the source-level sacrificial layer 104 may include a semiconductor material such as undoped amorphous silicon or a silicon-germanium alloy with an atomic concentration of germanium greater than 20%. The thickness of the source-level sacrificial layer 104 may be in a range from 30 nm to 400 nm, such as from 60 nm to 200 nm, although lesser and greater thicknesses may also be used.

The lower sacrificial liner 103 and the upper sacrificial liner 105 include materials that may function as an etch stop material during removal of the source-level sacrificial layer 104. For example, the lower sacrificial liner 103 and the upper sacrificial liner 105 may include silicon oxide, silicon nitride, and/or a dielectric metal oxide. In one embodiment, each of the lower sacrificial liner 103 and the upper sacrificial liner 105 may include a silicon oxide layer having a thickness in a range from 2 nm to 30 nm, although lesser and greater thicknesses may also be used. The source-level insulating layer 117 includes a dielectric material such as silicon oxide. The thickness of the source-level insulating layer 117 may be in a range from 20 nm to 400 nm, such as from 40 nm to 200 nm, although lesser and greater thicknesses may also be used. The optional source-select-level conductive layer 118 may include a conductive material that may be used as a source-select-level gate electrode. For example, the optional source-select-level conductive layer 118 may include a doped semiconductor material such as doped polysilicon or doped amorphous silicon that may be subsequently converted into doped polysilicon by an anneal process. The thickness of the optional source-select-level conductive layer 118 may be in a range from 30 nm to 200 nm, such as from 60 nm to 100 nm, although lesser and greater thicknesses may also be used.

The in-process source-level material layers 110′ may be formed directly above a subset of the semiconductor devices on the substrate 8 (e.g., silicon wafer). As used herein, a first element is located “directly above” a second element if the first element is located above a horizontal plane including a topmost surface of the second element and an area of the first element and an area of the second element has an areal overlap in a plan view (i.e., along a vertical plane or direction perpendicular to the top surface of the substrate 8.

The optional conductive plate layer 6 and the in-process source-level material layers 110′ may be patterned to provide openings in areas in which through-memory-level contact via structures and through-dielectric contact via structures are to be subsequently formed. Patterned portions of the stack of the conductive plate layer 6 and the in-process source-level material layers 110′ are present in each memory array region 100 in which three-dimensional memory stack structures are to be subsequently formed.

The optional conductive plate layer 6 and the in-process source-level material layers 110′ may be patterned such that an opening extends over a staircase region 200 in which contact via structures contacting word line electrically conductive layers are to be subsequently formed. In one embodiment, the staircase region 200 may be laterally spaced from the memory array region 100 along a first horizontal direction hd1. A horizontal direction that is perpendicular to the first horizontal direction hd1 is herein referred to as a second horizontal direction hd2. In one embodiment, additional openings in the optional conductive plate layer 6 and the in-process source-level material layers 110′ may be formed within the area of a memory array region 100, in which a three-dimensional memory array including memory stack structures is to be subsequently formed. A peripheral device region 400 that is subsequently filled with a field dielectric material portion may be provided adjacent to the staircase region 200.

The region of the semiconductor devices 710 and the combination of the lower-level dielectric material layers 760 and the lower-level metal interconnect structures 780 is herein referred to an underlying peripheral device region 700, which is located underneath a memory-level assembly to be subsequently formed and includes peripheral devices for the memory-level assembly. The lower-level metal interconnect structures 780 are formed in the lower-level dielectric material layers 760.

The lower-level metal interconnect structures 780 may be electrically connected to active nodes (e.g., transistor active regions 742 or gate electrodes 754) of the semiconductor devices 710 (e.g., CMOS devices), and are located at the level of the lower-level dielectric material layers 760. Through-memory-level contact via structures may be subsequently formed directly on the lower-level metal interconnect structures 780 to provide electrical connection to memory devices to be subsequently formed. In one embodiment, the pattern of the lower-level metal interconnect structures 780 may be selected such that the landing-pad-level metal line structures 788 (which are a subset of the lower-level metal interconnect structures 780 located at the topmost portion of the lower-level metal interconnect structures 780) may provide landing pad structures for the through-memory-level contact via structures to be subsequently formed.

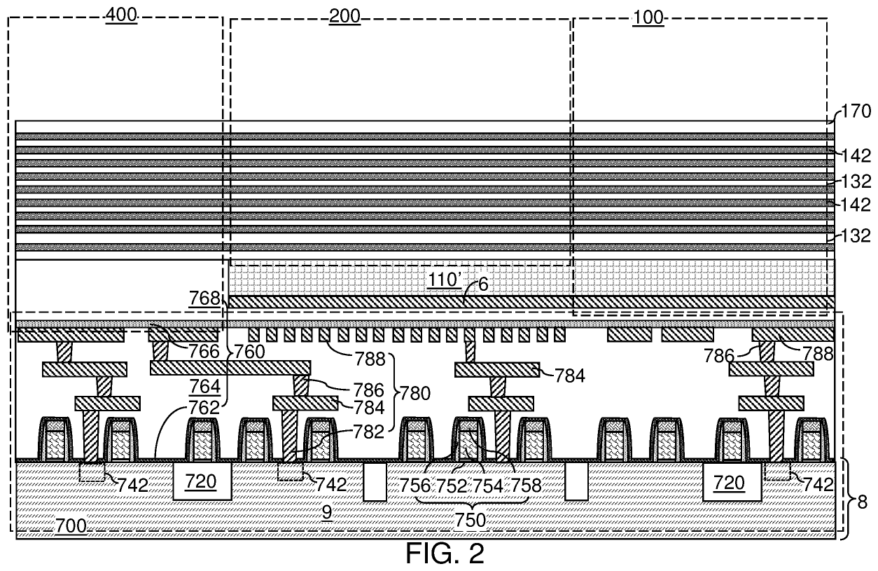

Referring to FIG. 2, an alternating stack of first material layers and second material layers is subsequently formed. Each first material layer may include a first material, and each second material layer may include a second material that is different from the first material. In case at least another alternating stack of material layers is subsequently formed over the alternating stack of the first material layers and the second material layers, the alternating stack is herein referred to as a first-tier alternating stack. The level of the first-tier alternating stack is herein referred to as a first-tier level, and the level of the alternating stack to be subsequently formed immediately above the first-tier level is herein referred to as a second-tier level, etc.

The first-tier alternating stack may include first insulting layers 132 as the first material layers, and first spacer material layers as the second material layers. In one embodiment, the first spacer material layers may be sacrificial material layers that are subsequently replaced with electrically conductive layers. In another embodiment, the first spacer material layers may be electrically conductive layers that are not subsequently replaced with other layers. While the present disclosure is described using embodiments in which sacrificial material layers are replaced with electrically conductive layers, embodiments in which the spacer material layers are formed as electrically conductive layers (thereby obviating the need to perform replacement processes) are expressly contemplated herein.

In one embodiment, the first material layers and the second material layers may be first insulating layers 132 and first sacrificial material layers 142, respectively. In one embodiment, each first insulating layer 132 may include a first insulating material, and each first sacrificial material layer 142 may include a first sacrificial material. An alternating plurality of first insulating layers 132 and first sacrificial material layers 142 is formed over the in-process source-level material layers 110′. As used herein, a “sacrificial material” refers to a material that is removed during a subsequent processing step.

As used herein, an alternating stack of first elements and second elements refers to a structure in which instances of the first elements and instances of the second elements alternate. Each instance of the first elements that is not an end element of the alternating plurality is adjoined by two instances of the second elements on both sides, and each instance of the second elements that is not an end element of the alternating plurality is adjoined by two instances of the first elements on both ends. The first elements may have the same thickness throughout, or may have different thicknesses. The second elements may have the same thickness throughout, or may have different thicknesses. The alternating plurality of first material layers and second material layers may begin with an instance of the first material layers or with an instance of the second material layers, and may end with an instance of the first material layers or with an instance of the second material layers. In one embodiment, an instance of the first elements and an instance of the second elements may form a unit that is repeated with periodicity within the alternating plurality.

The first-tier alternating stack (132, 142) may include first insulating layers 132 composed of the first material, and first sacrificial material layers 142 composed of the second material, which is different from the first material. The first material of the first insulating layers 132 may be at least one insulating material. Insulating materials that may be used for the first insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first insulating layers 132 may be silicon oxide.

The second material of the first sacrificial material layers 142 is a sacrificial material that may be removed selective to the first material of the first insulating layers 132. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The first sacrificial material layers 142 may comprise an insulating material, a semiconductor material, or a conductive material. The second material of the first sacrificial material layers 142 may be subsequently replaced with electrically conductive electrodes which may function, for example, as control gate electrodes of a vertical NAND device. In one embodiment, the first sacrificial material layers 142 may be material layers that comprise silicon nitride.

In one embodiment, the first insulating layers 132 may include silicon oxide, and sacrificial material layers may include silicon nitride sacrificial material layers. The first material of the first insulating layers 132 may be deposited, for example, by chemical vapor deposition (CVD). For example, if silicon oxide is used for the first insulating layers 132, tetraethylorthosilicate (TEOS) may be used as the precursor material for the CVD process. The second material of the first sacrificial material layers 142 may be formed, for example, CVD or atomic layer deposition (ALD).

The thicknesses of the first insulating layers 132 and the first sacrificial material layers 142 may be in a range from 20 nm to 50 nm, although lesser and greater thicknesses may be used for each first insulating layer 132 and for each first sacrificial material layer 142. The number of repetitions of the pairs of a first insulating layer 132 and a first sacrificial material layer 142 may be in a range from 2 to 1,024, and typically from 8 to 256, although a greater number of repetitions may also be used. In one embodiment, each first sacrificial material layer 142 in the first-tier alternating stack (132, 142) may have a uniform thickness that is substantially invariant within each respective first sacrificial material layer 142.

A first insulating cap layer 170 is subsequently formed over the first-tier alternating stack (132, 142). The first insulating cap layer 170 includes a dielectric material, which may be any dielectric material that may be used for the first insulating layers 132. In one embodiment, the first insulating cap layer 170 includes the same dielectric material as the first insulating layers 132. The thickness of the first insulating cap layer 170 may be in a range from 20 nm to 300 nm, although lesser and greater thicknesses may also be used.

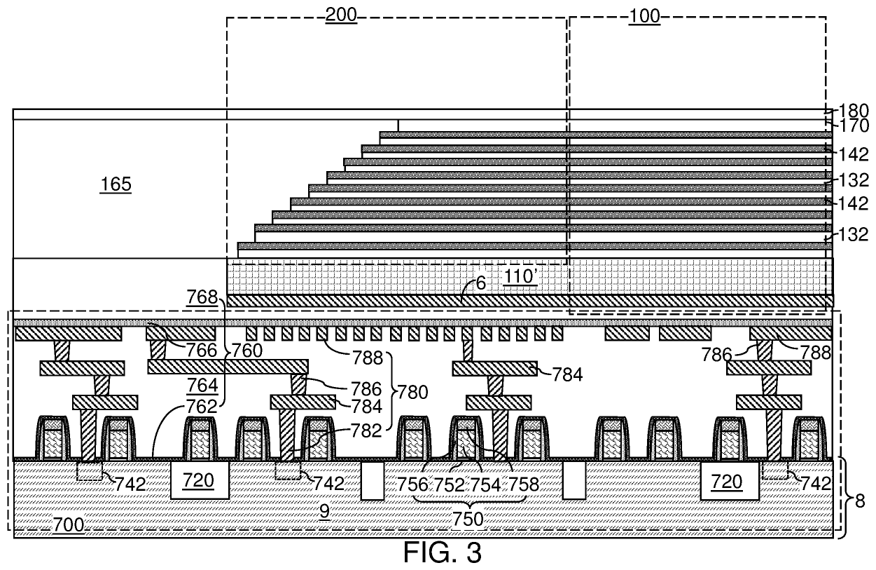

Referring to FIG. 3, the first insulating cap layer 170 and the first-tier alternating stack (132, 142) may be patterned to form first stepped surfaces in the staircase region 200. The staircase region 200 may include a respective first stepped area in which the first stepped surfaces are formed, and a second stepped area in which additional stepped surfaces are to be subsequently formed in a second-tier structure (to be subsequently formed over a first-tier structure) and/or additional tier structures. The first stepped surfaces may be formed, for example, by forming a mask layer (not shown) with an opening therein, etching a cavity within the levels of the first insulating cap layer 170, and iteratively expanding the etched area and vertically recessing the cavity by etching each pair of a first insulating layer 132 and a first sacrificial material layer 142 located directly underneath the bottom surface of the etched cavity within the etched area. In one embodiment, top surfaces of the first sacrificial material layers 142 may be physically exposed at the first stepped surfaces. The cavity overlying the first stepped surfaces is herein referred to as a first stepped cavity.

A dielectric fill material (such as undoped silicate glass or doped silicate glass) may be deposited to fill the first stepped cavity. Excess portions of the dielectric fill material may be removed from above the horizontal plane including the top surface of the first insulating cap layer 170. A remaining portion of the dielectric fill material that fills the region overlying the first stepped surfaces constitute a first retro-stepped dielectric material portion 165. As used herein, a “retro-stepped” element refers to an element that has stepped surfaces and a horizontal cross-sectional area that increases monotonically as a function of a vertical distance from a top surface of a substrate on which the element is present. The first-tier alternating stack (132, 142) and the first retro-stepped dielectric material portion 165 collectively constitute a first-tier structure, which is an in-process structure that is subsequently modified.

An inter-tier dielectric layer 180 may be optionally deposited over the first-tier structure (132, 142, 170, 165). The inter-tier dielectric layer 180 includes a dielectric material such as silicon oxide. In one embodiment, the inter-tier dielectric layer 180 may include a doped silicate glass having a greater etch rate than the material of the first insulating layers 132 (which may include an undoped silicate glass). For example, the inter-tier dielectric layer 180 may include phosphosilicate glass. The thickness of the inter-tier dielectric layer 180 may be in a range from 30 nm to 300 nm, although lesser and greater thicknesses may also be used.

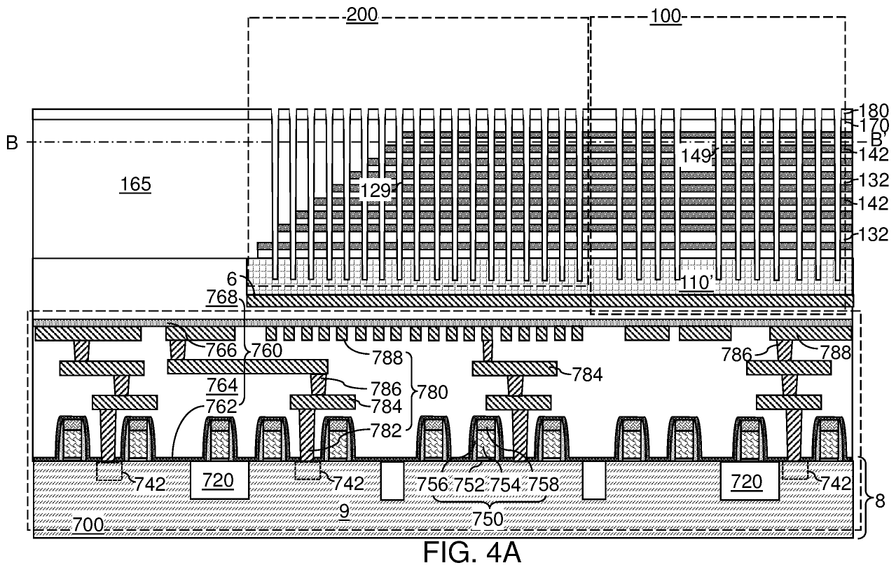

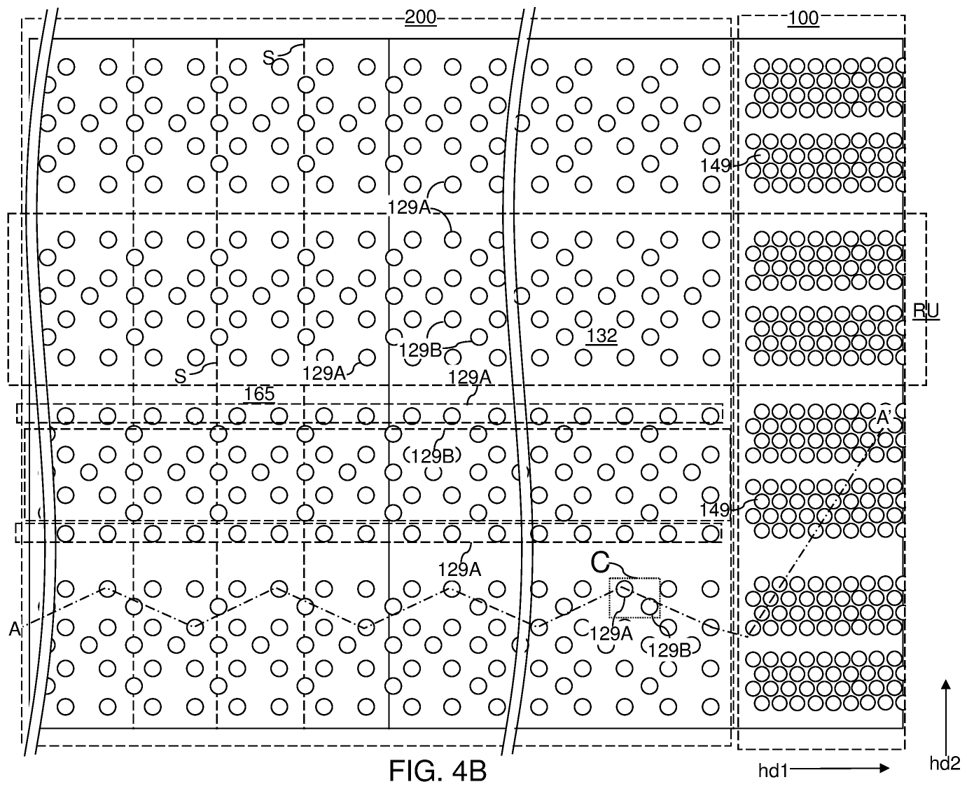

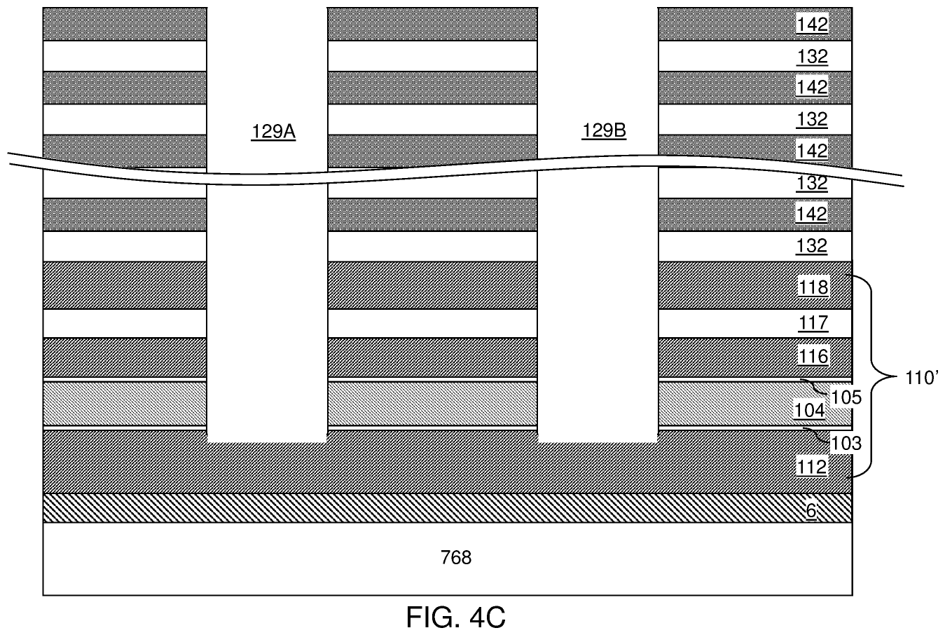

Referring to FIGS. 4A-4C, various first-tier openings (149, 129) may be formed through the inter-tier dielectric layer 180 and the first-tier structure (132, 142, 170, 165) and into the in-process source-level material layers 110′. A photoresist layer (not shown) may be applied over the inter-tier dielectric layer 180, and may be lithographically patterned to form various openings therethrough. The pattern of openings in the photoresist layer may be transferred through the inter-tier dielectric layer 180 and the first-tier structure (132, 142, 170, 165) and into the in-process source-level material layers 110′ by a first anisotropic etch process to form the various first-tier openings (149, 129) concurrently, i.e., during the first isotropic etch process. The various first-tier openings (149, 129) may include first-tier memory openings 149 and first-tier support openings 129. Locations of steps S in the first-tier alternating stack (132, 142) are illustrated as dotted lines in FIG. 4B.

The first-tier memory openings 149 are openings that are formed in the memory array region 100 through each layer within the first-tier alternating stack (132, 142) and are subsequently used to form memory stack structures therein. The first-tier memory openings 149 may be formed in clusters of first-tier memory openings 149 that are laterally spaced apart along the second horizontal direction hd2. Each cluster of first-tier memory openings 149 may be formed as a two-dimensional array of first-tier memory openings 149.

The first-tier support openings 129 are openings that are formed in the staircase region 200, and are subsequently employed to form support pillar structures. A subset of the first-tier support openings 129 that is formed through the first retro-stepped dielectric material portion 165 may be formed through a respective horizontal surface of the first stepped surfaces.

In one embodiment, the first anisotropic etch process may include an initial step in which the materials of the first-tier alternating stack (132, 142) are etched concurrently with the material of the first retro-stepped dielectric material portion 165. The chemistry of the initial etch step may alternate to optimize etching of the first and second materials in the first-tier alternating stack (132, 142) while providing a comparable average etch rate to the material of the first retro-stepped dielectric material portion 165. The first anisotropic etch process may use, for example, a series of reactive ion etch processes or a single reaction etch process (e.g., CF₄/O₂/Ar etch). The sidewalls of the various first-tier openings (149, 129) may be substantially vertical, or may be tapered.

After etching through the alternating stack (132, 142) and the first retro-stepped dielectric material portion 165, the chemistry of a terminal portion of the first anisotropic etch process may be selected to etch through the dielectric material(s) of the at least one second dielectric layer 768 with a higher etch rate than an average etch rate for the in-process source-level material layers 110′. For example, the terminal portion of the anisotropic etch process may include a step that etches the dielectric material(s) of the at least one second dielectric layer 768 selective to a semiconductor material within a component layer in the in-process source-level material layers 110′. In one embodiment, the terminal portion of the first anisotropic etch process may etch through the source-select-level conductive layer 118, the source-level insulating layer 117, the upper source-level semiconductor layer 116, the upper sacrificial liner 105, the source-level sacrificial layer 104, and the lower sacrificial liner 103, and at least partly into the lower source-level semiconductor layer 112. The terminal portion of the first anisotropic etch process may include at least one etch chemistry for etching the various semiconductor materials of the in-process source-level material layers 110′. The photoresist layer may be subsequently removed, for example, by ashing.

Optionally, the portions of the first-tier memory openings 149 and the first-tier support openings 129 at the level of the inter-tier dielectric layer 180 may be laterally expanded by an isotropic etch. In this case, the inter-tier dielectric layer 180 may comprise a dielectric material (such as borosilicate glass) having a greater etch rate than the first insulating layers 132 (that may include undoped silicate glass) in dilute hydrofluoric acid. An isotropic etch (such as a wet etch using HF) may be used to expand the lateral dimensions of the first-tier memory openings 149 at the level of the inter-tier dielectric layer 180. The portions of the first-tier memory openings 149 located at the level of the inter-tier dielectric layer 180 may be optionally widened to provide a larger landing pad for second-tier memory openings to be subsequently formed through a second-tier alternating stack (to be subsequently formed prior to formation of the second-tier memory openings). Optionally, a nitridation process and/or an oxidation process may be performed as necessary to form silicon nitride or silicon oxide dielectric liners (not shown) at the levels of the in-process source-level material layers 110′.

In one embodiment shown in FIGS. 4B and 4C, a first subset 129A of the first-tier support openings 129 may be formed at locations that are proximal to areas of backside trenches to be subsequently formed, and a second subset 129B of the first-tier support openings 129 may be formed at locations that are distal from the area of the backside trenches. In case the backside trenches to be subsequently formed extend along the first horizontal direction, the first subset 129A of the first-tier support openings 129 may include rows of first-tier support openings 129 that are arranged along the first horizontal direction hd1 adjacent to the areas of the backside trenches to be subsequently formed.

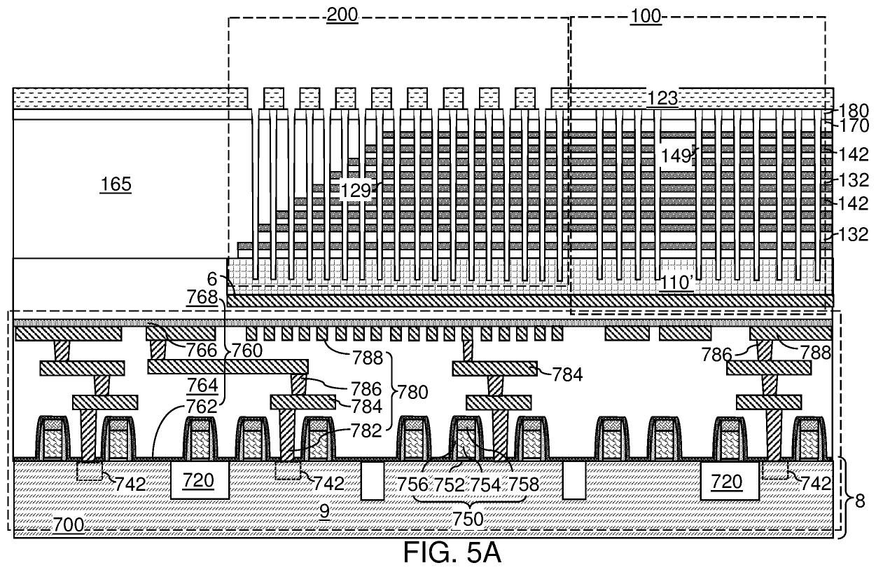

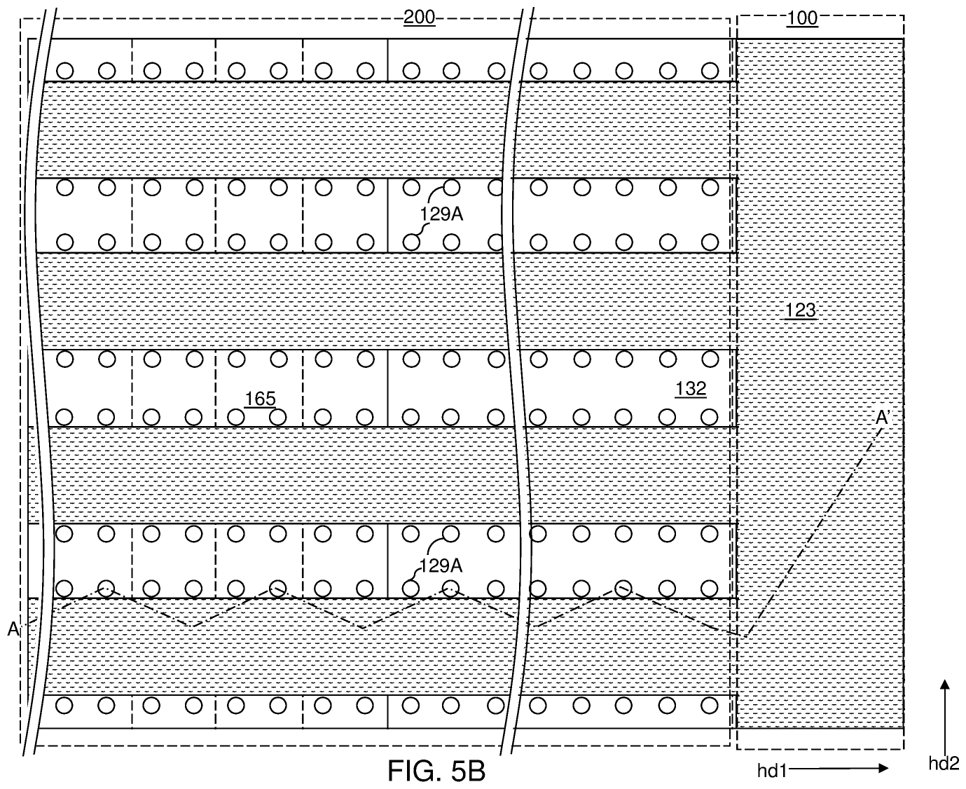

Referring to FIGS. 5A and 5B, a sacrificial mask material layer 123 can be formed over the inter-tier dielectric layer 180 by performing an anisotropic deposition process. The sacrificial mask material layer 123 may comprise a carbon-based material such as amorphous carbon, diamond-like carbon (DLC), or carbon-based patterning films known in the art. The sacrificial mask material layer 123 can be anisotropically deposited, for example, by plasma-enhanced chemical vapor deposition. The thickness of the sacrificial mask material layer 123 can be in a range from 100 nm to 1,000 nm, such as from 200 nm to 600 nm, although lesser and greater thicknesses may also be employed.

The sacrificial mask material layer 123 can be subsequently patterned, for example, by applying and patterning a photoresist layer (not shown) over the sacrificial mask material layer 123, and by removing portions of the sacrificial mask material layer 123 that are not covered by the patterned photoresist layer. The patterned photoresist layer can be subsequently removed, for example, by ashing.

The patterned sacrificial mask material layer 123 includes openings that overlie the first subset 129A of the first-tier support openings 129. The second subset 129B of the first-tier support openings 129 and the first-tier memory openings 149 can be covered by the patterned sacrificial mask material layer 123. The material of the sacrificial mask material layer 123 can be deposited with directionality with a small angular spread in the direction of deposition so that the sacrificial mask material layer 123 protrudes into upper portions of the second subset 129B of the first-tier support openings 129 and the first-tier memory openings 149. Cavities may be present in the lower portions of the second subset 129B of the first-tier support openings 129 and the first-tier memory openings 149.

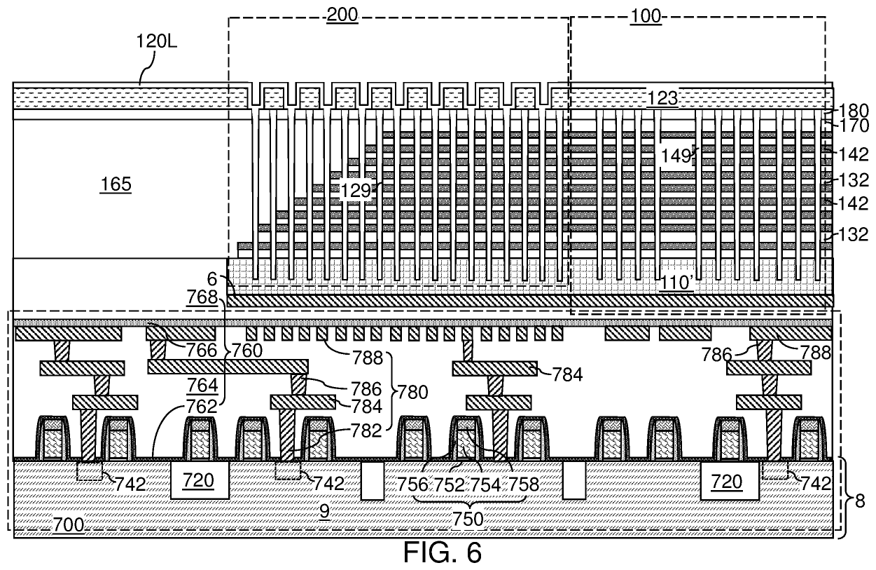

Referring to FIG. 6, at least one dielectric fill material layer 120L can be conformally deposited over the sacrificial mask material layer 123. The at least one dielectric fill material layer 120L comprises a dielectric fill material that can be deposited at a low temperature, i.e., at a temperature that does not induce decomposition of the material of the sacrificial mask material layer 123. In an illustrative example, the at least one dielectric fill material layer 120L may comprise a low-temperature oxide (LTO) layer and a silicate glass fill material layer. The at least one dielectric fill material layer 120L can be conformally deposited to fill volumes of the first subset 129A of the first-tier support openings 129.

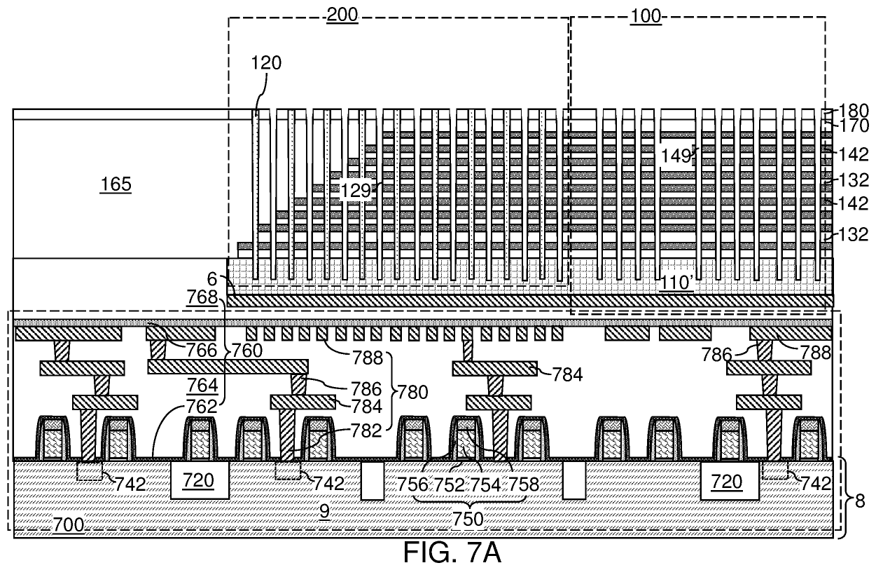

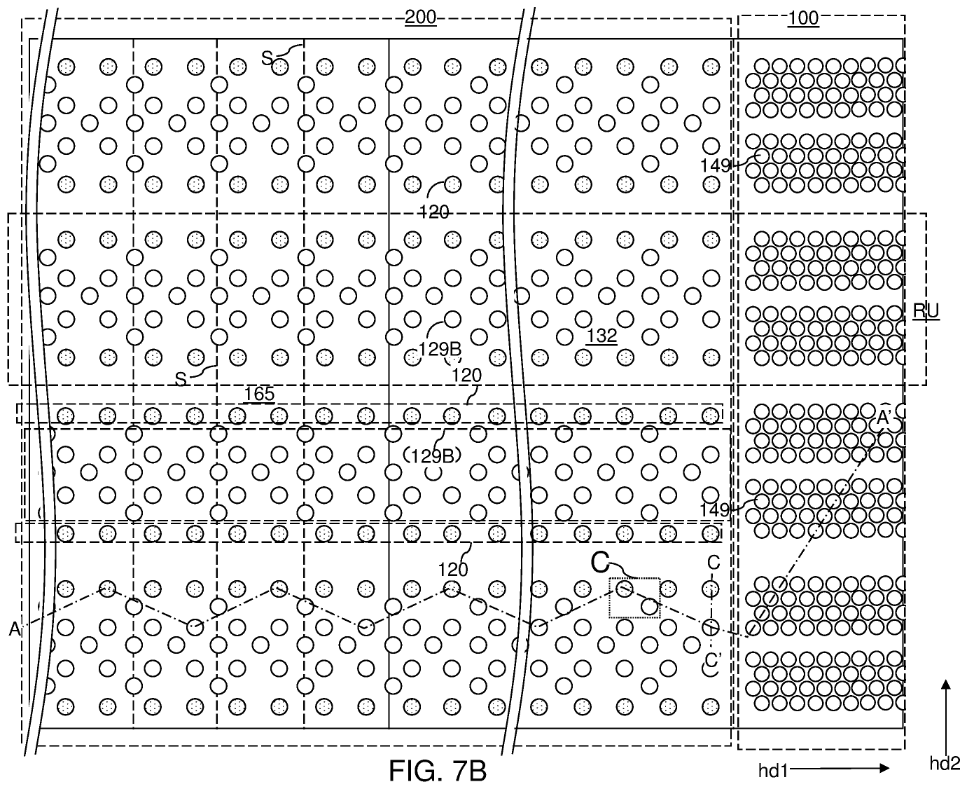

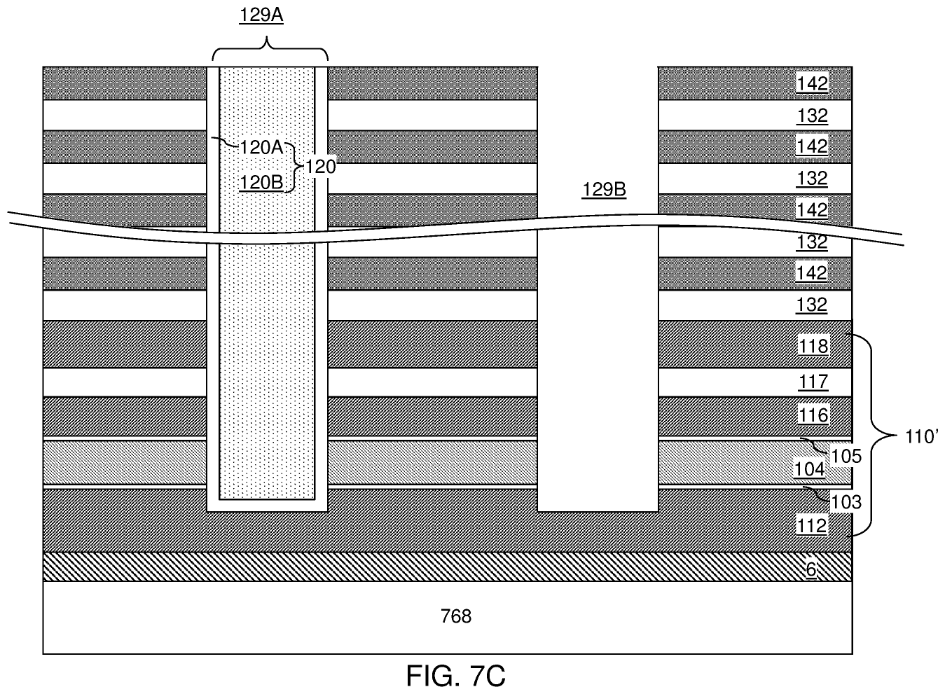

Referring to FIGS. 7A-7C, the at least one dielectric fill material layer 120L can be isotropically recessed, for example, by performing an isotropic etch process. Portions of the at least one dielectric fill material layer 120L that overlies the inter-tier dielectric layer 180 can be removed by the isotropic etch process. Each remaining portion of the at least one dielectric fill material layer 120L constitutes a dielectric support pillar 120. If the at least one dielectric fill material layer 120L includes a dielectric liner material and a dielectric fill material, then each of the dielectric support pillars 120 may comprise a dielectric liner 120A and a dielectric fill material portion 120B. In an illustrative example, the dielectric liner 120A may comprise a low-temperature oxide (LTO) material (which is a silicon oxide material formed at a low temperature), and the dielectric fill material portion 120B may comprise undoped silicate glass or a doped silicate glass. Optionally, a suitable reflow process may be performed as needed. Each first-tier support opening 129 within the first subset 129A of the first-tier support openings 129 can be filled with a respective dielectric support pillar 120. The sacrificial mask material layer 123 can be subsequently removed selective to the first-tier alternating stack (132, 142) and the dielectric support pillars 120, for example, by ashing. The second subset 129B of the first-tier support openings 129 and the first-tier memory openings 149 are reopened after removal of the sacrificial mask material layer 123.

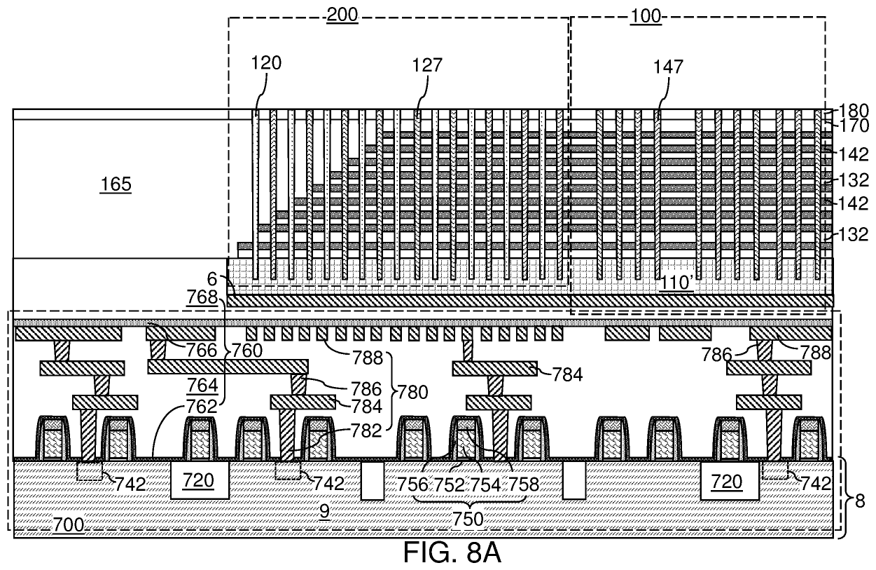

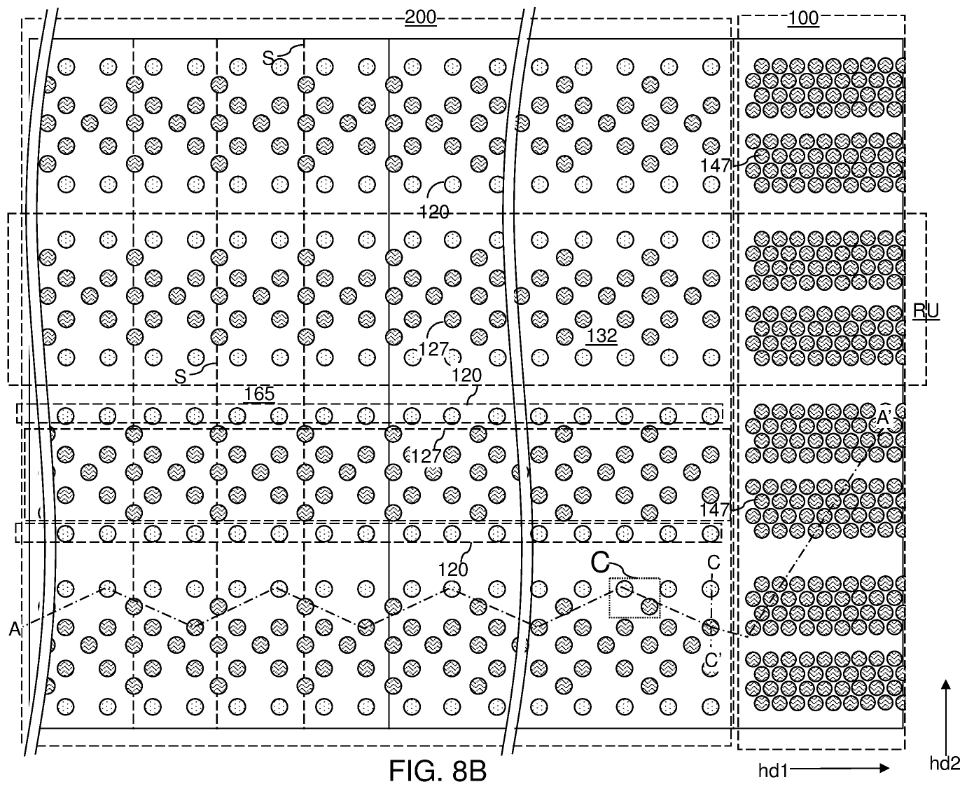

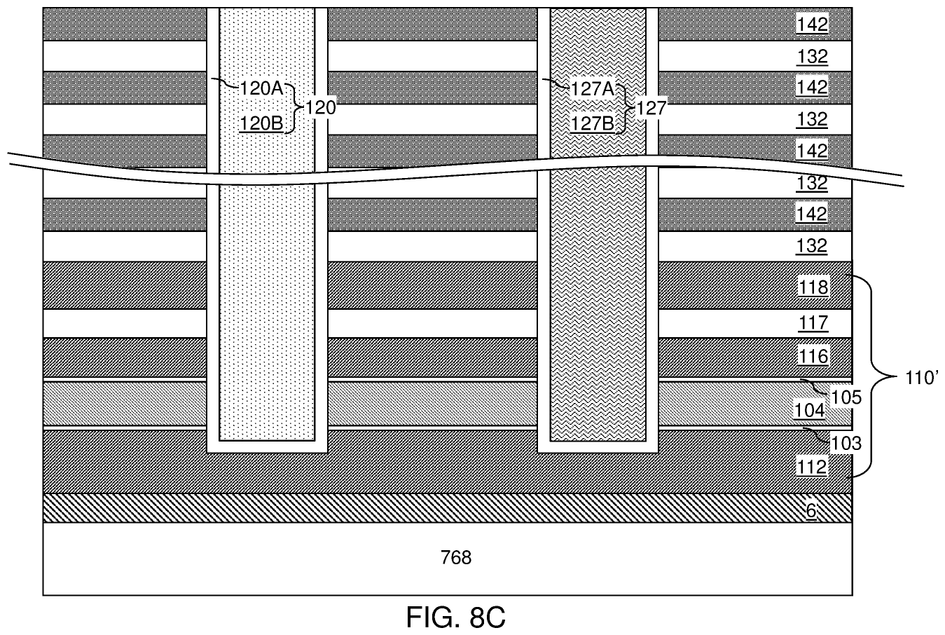

Referring to FIG. 8A-8C, a sacrificial first-tier liner material layer may be optionally deposited in peripheral portions of the second subset 129B of the first-tier support openings 129 and in the first-tier memory openings 149. The sacrificial first-tier liner material layer, if employed, may comprise a dielectric liner material, such a silicon oxide. The thickness of the sacrificial first-tier liner material layer may be in a range from 1 nm to 10 nm, such as from 2 nm to 5 nm, although lesser and greater thicknesses may also be employed.

A sacrificial first-tier fill material can be concurrently deposited in the second subset 129B of the first-tier support openings 129 and in the first-tier memory openings 149. The sacrificial first-tier fill material includes a material that may be subsequently removed selective to the materials of the first insulating layers 132 and the first sacrificial material layers 142.

In one embodiment, the sacrificial first-tier fill material may include a semiconductor material such as silicon (e.g., a-Si or polysilicon), a silicon-germanium alloy, germanium, a III-V compound semiconductor material, or a combination thereof. Optionally, a thin etch stop liner (such as a silicon oxide layer or a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In another embodiment, the sacrificial first-tier fill material may include a carbon-containing material (such as amorphous carbon or diamond-like carbon) that may be subsequently removed by ashing selective to the materials of the first-tier alternating stack (132, 142).

Portions of the deposited sacrificial material may be removed from above the inter-tier dielectric layer 180. For example, the sacrificial first-tier fill material may be recessed to a top surface of the inter-tier dielectric layer 180 using a planarization process. The planarization process may include a recess etch, chemical mechanical planarization (CMP), or a combination thereof. The top surface of the inter-tier dielectric layer 180 may be used as an etch stop layer or a planarization stop layer.

Remaining portions of the sacrificial first-tier fill material comprise sacrificial first-tier opening fill portions (147, 127). Specifically, each remaining portion of the sacrificial material in a first-tier memory opening 149 constitutes a sacrificial first-tier memory opening fill portion 147. Each remaining portion of the sacrificial material in a first-tier support opening 129 within the second subset 129B of the first-tier support openings 129 constitutes a sacrificial first-tier support opening fill portion 127.

The various sacrificial first-tier opening fill portions (147, 127) are concurrently formed, i.e., during a same set of processes including the deposition process that deposits the sacrificial first-tier fill material and the planarization process that removes the first-tier deposition process from above the first-tier alternating stack (132, 142) (such as from above the top surface of the inter-tier dielectric layer 180). The top surfaces of the sacrificial first-tier opening fill portions (147, 127) may be coplanar with the top surface of the inter-tier dielectric layer 180. Each of the sacrificial first-tier opening fill portions (147, 127) may or may not, include cavities therein.

In an illustrative example, each of the sacrificial first-tier opening fill portions (147, 127) may comprise a sacrificial first-tier liner (such as a sacrificial first-tier support opening liner 127A illustrated in FIG. 8C) and a sacrificial first-tier fill material portion (such as a sacrificial first-tier support opening fill material portion 127B illustrated in FIG. 8C).

Generally, the dielectric support pillars 120 comprise a different material than the first-tier sacrificial memory opening fill structures 147 so that the first-tier sacrificial memory opening fill structures 147 may be subsequently removed by performing a selective etch process or an ashing process that removes the material of the first-tier sacrificial memory opening fill structures 147 selective to the material of the dielectric pillar structures 120.

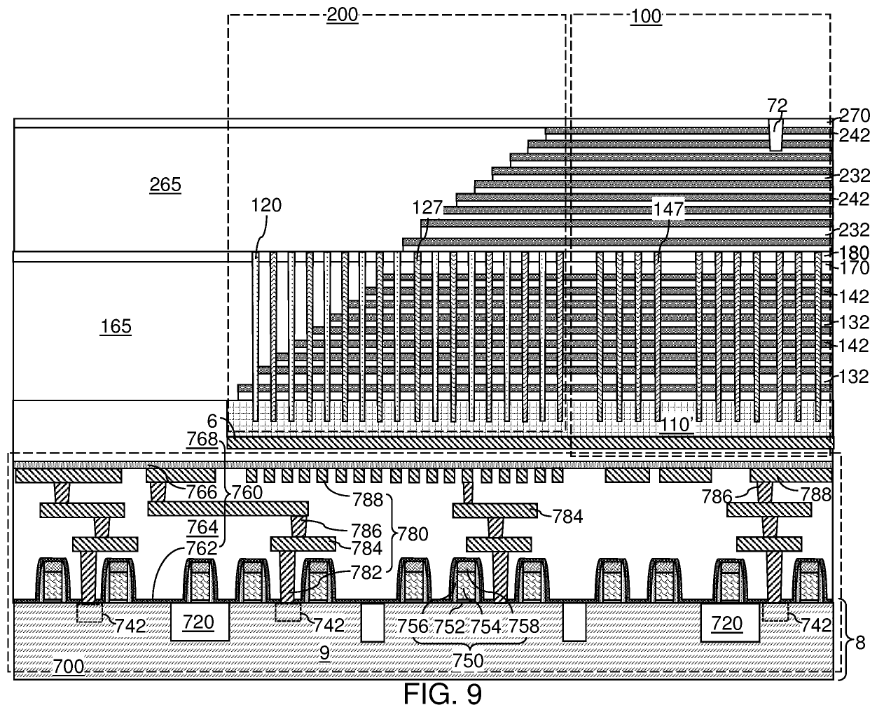

Referring to FIG. 9, a second-tier structure may be formed over the first-tier structure (132, 142, 165, 170, 147, 127, 120). The second-tier structure may include an additional alternating stack of insulating layers and spacer material layers, which may be sacrificial material layers. For example, a second-tier alternating stack (232, 242) of material layers may be subsequently formed on the top surface of the first-tier alternating stack (132, 142). The second-tier alternating stack (232, 242) includes an alternating plurality of third material layers and fourth material layers. Each third material layer may include a third material, and each fourth material layer may include a fourth material that is different from the third material. In one embodiment, the third material may be the same as the first material of the first insulating layer 132, and the fourth material may be the same as the second material of the first sacrificial material layers 142.

In one embodiment, the third material layers may be second insulating layers 232 and the fourth material layers may be second spacer material layers that provide vertical spacing between each vertically neighboring pair of the second insulating layers 232. In one embodiment, the third material layers and the fourth material layers may be second insulating layers 232 and second sacrificial material layers 242, respectively. The third material of the second insulating layers 232 may be at least one insulating material. The fourth material of the second sacrificial material layers 242 may be a sacrificial material that may be removed selective to the third material of the second insulating layers 232. The second sacrificial material layers 242 may comprise an insulating material, a semiconductor material, or a conductive material. The fourth material of the second sacrificial material layers 242 may be subsequently replaced with electrically conductive electrodes which may function, for example, as control gate electrodes of a vertical NAND device.

In one embodiment, each second insulating layer 232 may include a second insulating material, and each second sacrificial material layer 242 may include a second sacrificial material. In this case, the second-tier alternating stack (232, 242) may include an alternating plurality of second insulating layers 232 and second sacrificial material layers 242. The third material of the second insulating layers 232 may be deposited, for example, by chemical vapor deposition (CVD). The fourth material of the second sacrificial material layers 242 may be formed, for example, CVD or atomic layer deposition (ALD).

The third material of the second insulating layers 232 may be at least one insulating material. Insulating materials that may be used for the second insulating layers 232 may be any material that may be used for the first insulating layers 132. The fourth material of the second sacrificial material layers 242 is a sacrificial material that may be removed selective to the third material of the second insulating layers 232. Sacrificial materials that may be used for the second sacrificial material layers 242 may be any material that may be used for the first sacrificial material layers 142. In one embodiment, the second insulating material may be the same as the first insulating material, and the second sacrificial material may be the same as the first sacrificial material.

The thicknesses of the second insulating layers 232 and the second sacrificial material layers 242 may be in a range from 20 nm to 50 nm, although lesser and greater thicknesses may be used for each second insulating layer 232 and for each second sacrificial material layer 242. The number of repetitions of the pairs of a second insulating layer 232 and a second sacrificial material layer 242 may be in a range from 2 to 1,024, and typically from 8 to 256, although a greater number of repetitions may also be used. In one embodiment, each second sacrificial material layer 242 in the second-tier alternating stack (232, 242) may have a uniform thickness that is substantially invariant within each respective second sacrificial material layer 242.

Second stepped surfaces in the second stepped area may be formed in the staircase region 200 using a same set of processing steps as the processing steps used to form the first stepped surfaces in the first stepped area with suitable adjustment to the pattern of at least one masking layer. A second retro-stepped dielectric material portion 265 may be formed over the second stepped surfaces in the staircase region 200.

A second insulating cap layer 270 may be subsequently formed over the second-tier alternating stack (232, 242). The second insulating cap layer 270 includes a dielectric material that is different from the material of the second sacrificial material layers 242. In one embodiment, the second insulating cap layer 270 may include silicon oxide. In one embodiment, the first and second sacrificial material layers (142, 242) may comprise silicon nitride.

Generally speaking, at least one alternating stack of insulating layers (132, 232) and spacer material layers (such as sacrificial material layers (142, 242)) may be formed over the in-process source-level material layers 110′, and at least one retro-stepped dielectric material portion (165, 265) may be formed over the staircase regions on the at least one alternating stack (132, 142, 232, 242).

Optionally, drain-select-level isolation structures 72 may be formed through a subset of layers in an upper portion of the second-tier alternating stack (232, 242). The second sacrificial material layers 242 that are cut by the drain-select-level isolation structures 72 correspond to the levels in which drain-select-level electrically conductive layers are subsequently formed. The drain-select-level isolation structures 72 include a dielectric material such as silicon oxide. The drain-select-level isolation structures 72 may laterally extend along a first horizontal direction hd1, and may be laterally spaced apart along a second horizontal direction hd2 that is perpendicular to the first horizontal direction hd1. The combination of the second-tier alternating stack (232, 242), the second retro-stepped dielectric material portion 265, the second insulating cap layer 270, and the optional drain-select-level isolation structures 72 collectively constitute a second-tier structure (232, 242, 265, 270, 72).

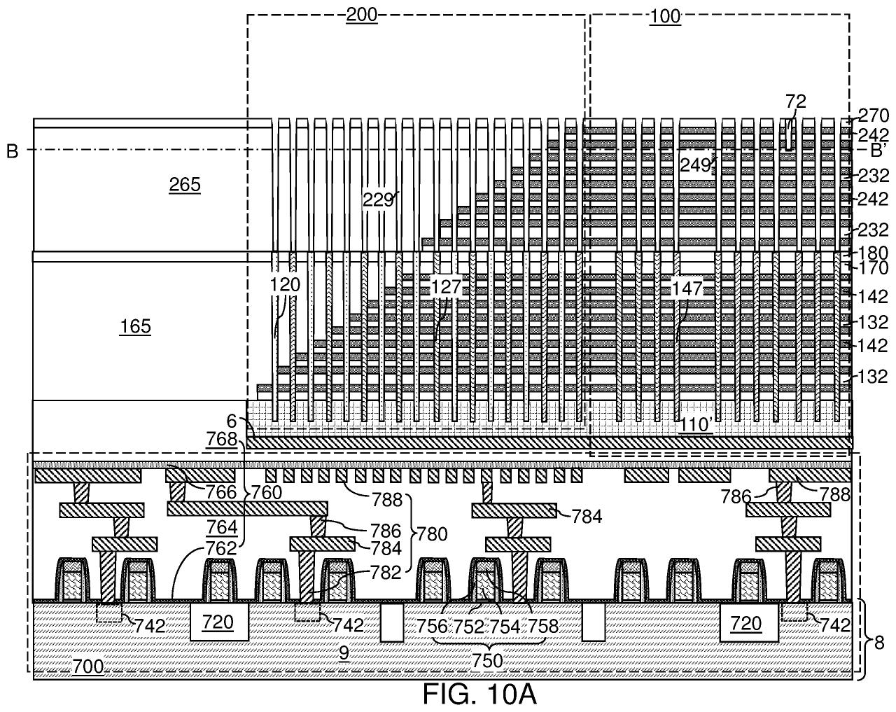

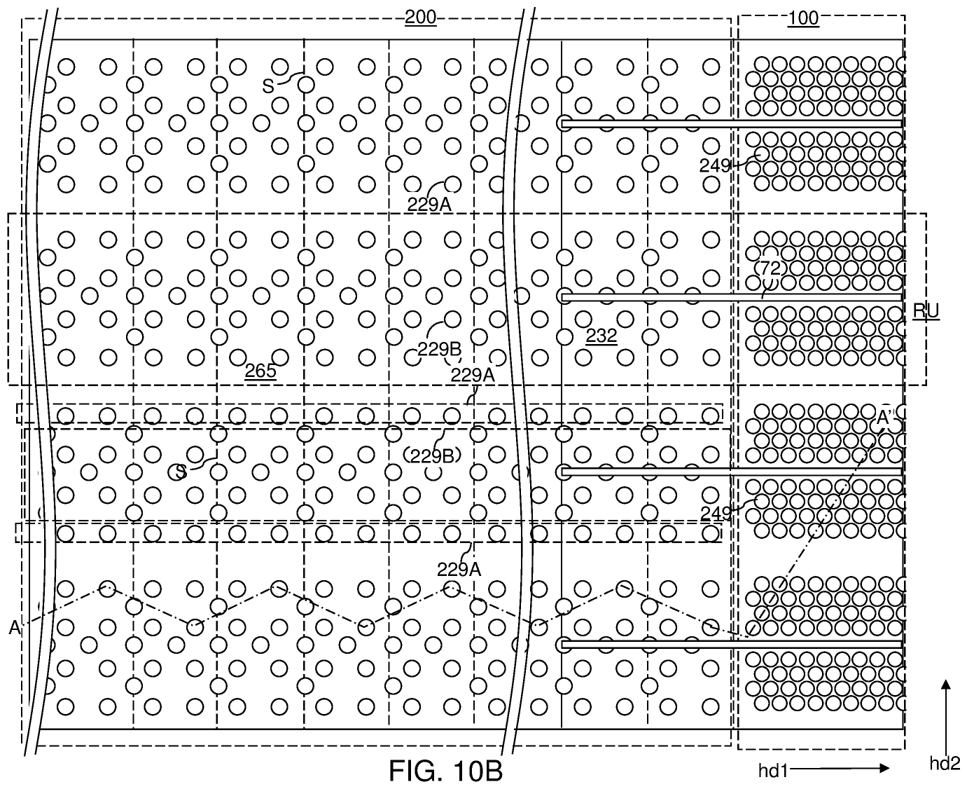

Referring to FIGS. 10A and 10B, various second-tier openings (249, 229) may be formed through the second-tier structure (232, 242, 265, 270, 72). A photoresist layer (not shown) may be applied over the second insulating cap layer 270, and may be lithographically patterned to form various openings therethrough. The pattern of the openings may be the same as the pattern of the various first-tier openings (149, 129), which is the same as the sacrificial first-tier opening fill portions (147, 127). Thus, the lithographic mask used to pattern the first-tier openings (149, 129) may be used to pattern the photoresist layer.

The pattern of openings in the photoresist layer may be transferred through the second-tier structure (232, 242, 265, 270, 72) by a second anisotropic etch process to form various second-tier openings (249, 229) concurrently, i.e., during the second anisotropic etch process. The various second-tier openings (249, 229) may include second-tier memory openings 249 and second-tier support openings 229.

The second-tier memory openings 249 are formed directly on a top surface of a respective one of the sacrificial first-tier memory opening fill portions 147. A first subset 229A of the second-tier support openings 229 is formed directly on a top surface of a respective one of the dielectric support pillars 120. A second subset 229B of the second-tier support openings 229 is formed directly on a top surface of a respective one of the sacrificial first-tier support opening fill portions 127. A predominant fraction, and/or each, of the second-tier support openings 229 may be formed through a horizontal surface within the second stepped surfaces, which include the interfacial surfaces between the second-tier alternating stack (232, 242) and the second retro-stepped dielectric material portion 265. Locations of steps S in the first-tier alternating stack (132, 142) and the second-tier alternating stack (232, 242) are illustrated as dotted lines in FIG. 10B.

The second anisotropic etch process may include an etch step in which the materials of the second-tier alternating stack (232, 242) are etched concurrently with the material of the second retro-stepped dielectric material portion 265. The chemistry of the etch step may alternate to optimize etching of the materials in the second-tier alternating stack (232, 242) while providing a comparable average etch rate to the material of the second retro-stepped dielectric material portion 265. The second anisotropic etch process may use, for example, a series of reactive ion etch processes or a single reaction etch process (e.g., CF/O₂/Ar etch). The sidewalls of the various second-tier openings (249, 229) may be substantially vertical, or may be tapered. A bottom periphery of each second-tier opening (249, 229) may be laterally offset, and/or may be located entirely within, a periphery of a top surface of an underlying sacrificial first-tier opening fill portion (147, 127) or an underlying dielectric support pillar 120. The photoresist layer may be subsequently removed, for example, by ashing.

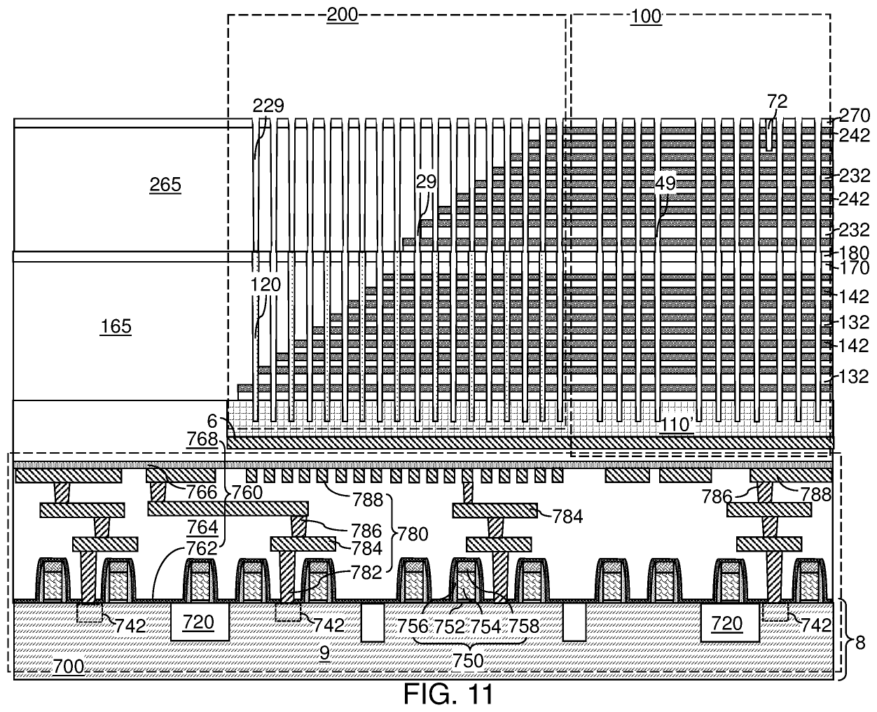

Referring to FIG. 11, the sacrificial first-tier fill material of the sacrificial first-tier opening fill portions (147, 127) may be removed using a selective removal process that removes the sacrificial first-tier fill material selective to the materials of the first and second insulating layers (132, 232), the first and second sacrificial material layers (142, 242), the first and second insulating cap layers (170, 270), the inter-tier dielectric layer 180, and the dielectric support pillars 120. For example, if the sacrificial first-tier opening fill portions (147, 127) comprise a carbon material, then the selective removal process comprises an ashing process. Alternatively, if the sacrificial first-tier opening fill portions (147, 127) comprise amorphous silicon, then the selective removal process comprises a selective etching process, such as a selective wet etch process using hot trimethyl-2 hydroxyethyl ammonium hydroxide (“hot TMY”) or tetramethyl ammonium hydroxide (TMAH). A memory opening 49, which is also referred to as an inter-tier memory opening 49, is formed in each contiguous combination of second-tier memory openings 249 from which a sacrificial first-tier memory opening fill portion 147 is removed. A support opening 29, which is also referred to as an inter-tier support opening 29, is formed in each contiguous combination of second-tier support openings 229 within the second subset 229B of the second-tier support openings 229 and a volume of the first-tier support openings 129 within the second subset 129B of the first-tier support openings 129 from which a sacrificial first-tier support opening fill portion 127 is removed. The dielectric pillar structures 120 are not removed underneath the second-tier support openings 229 within the first subset 229A of the second-tier support openings 229. Generally, the first-tier sacrificial memory opening fill structures 147 and the first-tier sacrificial support opening fill structures 127 may be removed by performing a selective removal process which selectively removes the materials of the first-tier sacrificial memory opening fill structures 147 and the first-tier sacrificial support opening fill structures 127 selective to the material of the dielectric pillar structures 120.

Therefore, each of the inter-tier memory openings 49 vertically extends through each layer within the first-tier alternating stack (132, 142) and the second-tier alternating stack (232, 242). Each of the inter-tier support openings 29 vertically extends through at least a subset of layers within the first-tier alternating stack (132, 142), and may vertically extend through at least the second retro-stepped dielectric material portion 265. Each of the inter-tier memory openings 49 and the inter-tier support openings 29 vertically extends from the horizontal plane including the top surface of the second insulating cap layer 270 into the in-process source-level material layers 110′. Each of the second-tier memory openings 229 overlies a respective dielectric pillar structure 120, and vertically extends from the horizontal plane including the top surface of the second insulating cap layer 270 to a top surface of the respective dielectric pillar structure 120. The bottom surface of each second-tier memory opening 229 may be located at or below the horizontal plane including the top surface of the inter-tier dielectric layer 180, and can be located above the horizontal plane including the bottom surface of the inter-tier dielectric layer 180.

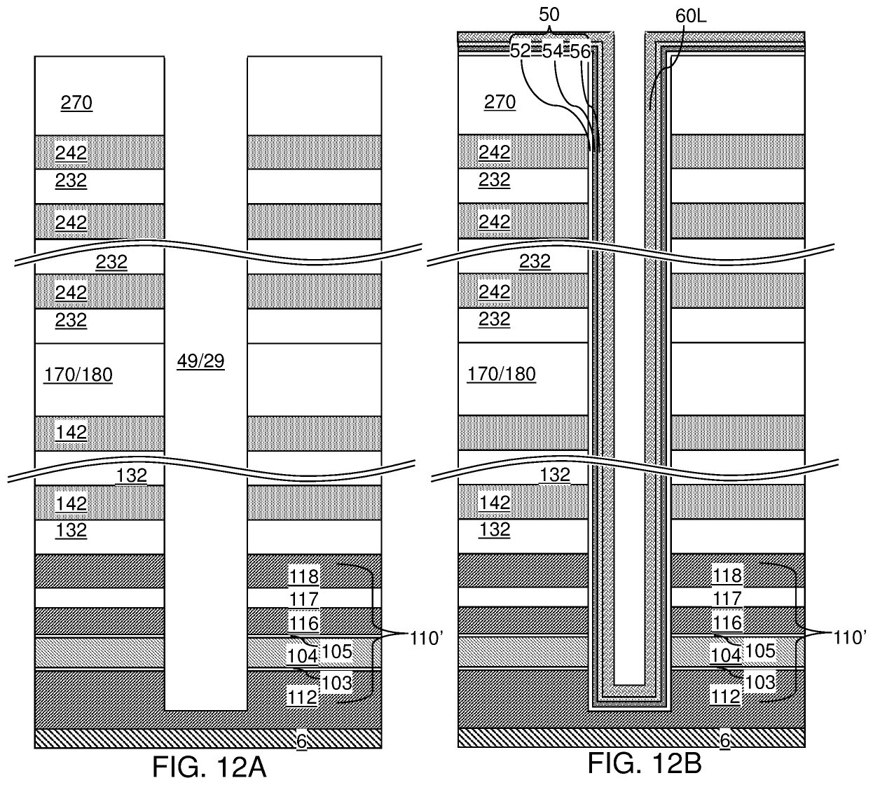

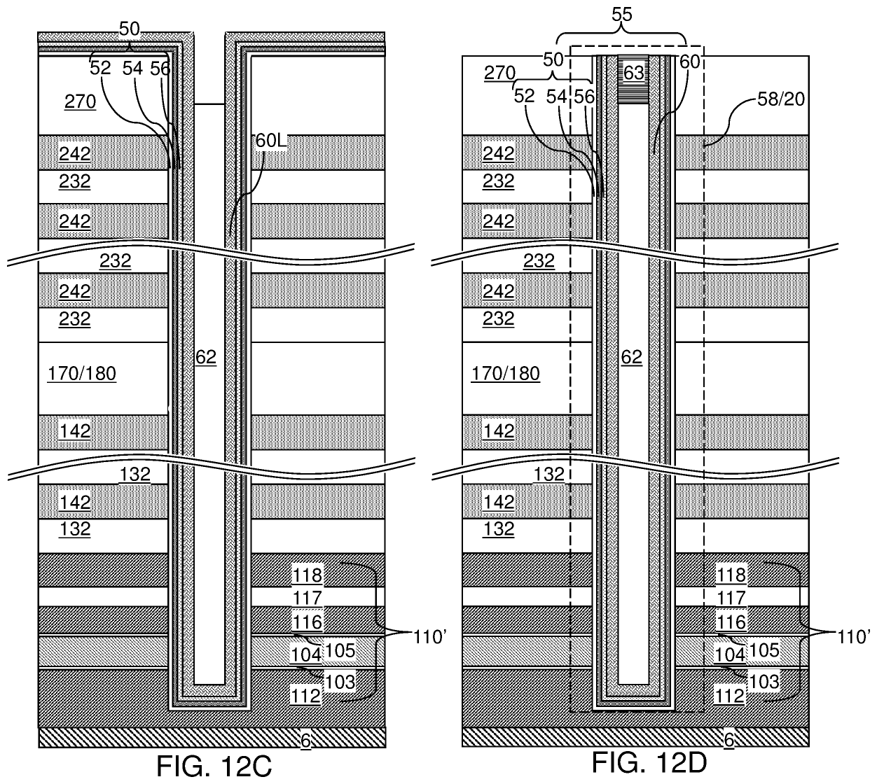

FIGS. 12A-12D illustrate sequential vertical cross-sectional views of an inter-tier memory opening 49 or an inter-tier support opening 29 during formation of a memory opening fill structure 58 or a support pillar structure 20 according to the first embodiment of the present disclosure.

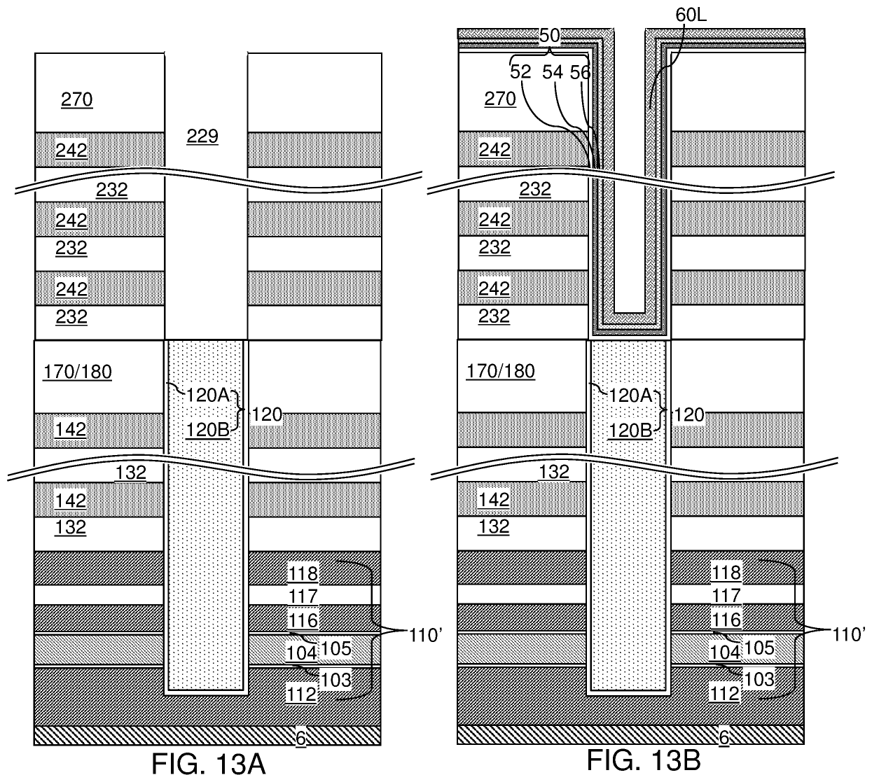

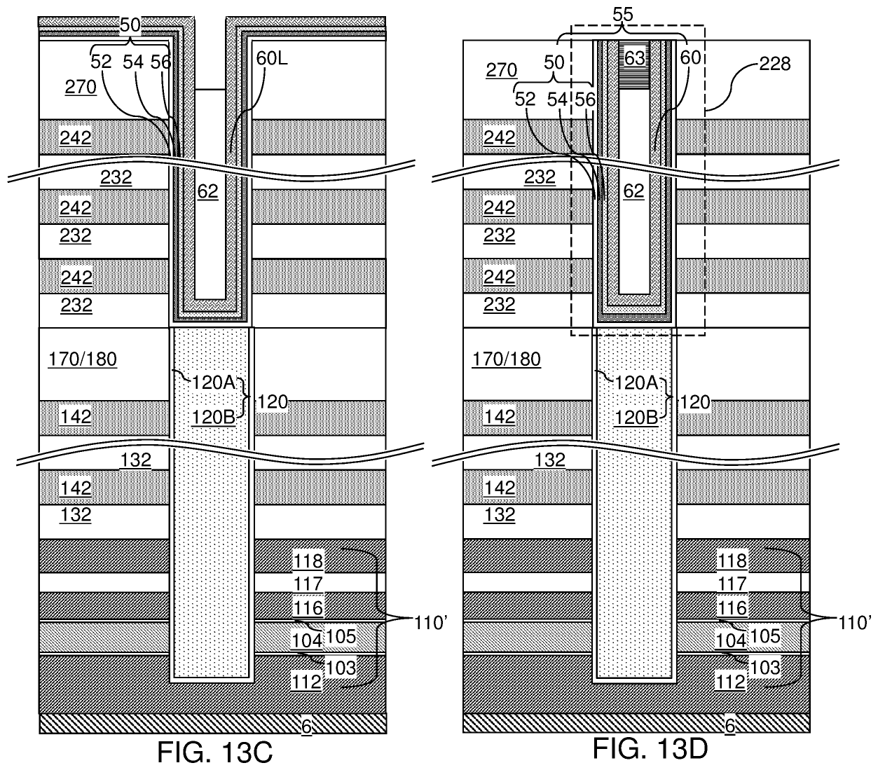

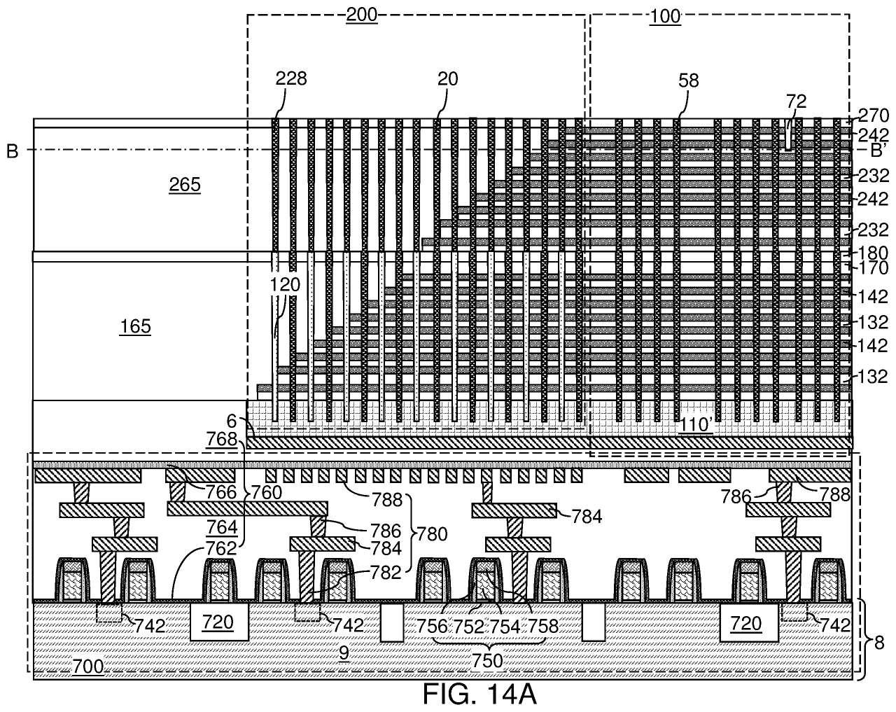

FIGS. 13A-13D illustrate sequential vertical cross-sectional views of a region overlying a dielectric support pillar 120 and containing a second-tier support opening 229 within the first subset 229A of the second-tier support openings 229 during formation of a composite support pillar 128 according to the first embodiment of the present disclosure.

Referring to FIGS. 12A and 13A, an inter-tier memory opening 49 (or an inter-tier support opening 29) and a second-tier support opening 229 are illustrated after the processing steps of FIG. 11.

Referring to FIGS. 12B and 13B, a stack of layers including a blocking dielectric layer 52, a memory material layer 54, an optional dielectric liner 56, and a semiconductor channel material layer 60L may be sequentially deposited in each of the inter-tier memory openings 49, the inter-tier support openings 29, and the second-tier support openings 229. The blocking dielectric layer 52 may include a single dielectric material layer or a stack of a plurality of dielectric material layers. In one embodiment, the blocking dielectric layer may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant greater than 7.9, i.e., having a dielectric constant greater than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 may include a dielectric semiconductor compound such as silicon oxide, silicon oxynitride, silicon nitride, or a combination thereof.

Subsequently, the memory material layer 54 can be formed. Generally, the memory material layer 54 may comprise any memory material such as a charge storage material, a ferroelectric material, a phase change material, or any material that can store data bits in the form of presence or absence of electrical charge, a direction of ferroelectric polarization, electrical resistivity, or another measurable physical parameter. In one embodiment, the memory material layer 54 can be a continuous layer or patterned discrete portions of a charge trapping material including a dielectric charge trapping material, which can be, for example, silicon nitride. Alternatively, the memory material layer 54 can include a continuous layer or patterned discrete portions of a conductive material such as doped polysilicon or a metallic material that is patterned into multiple electrically isolated portions (e.g., floating gates), for example, by being formed within lateral recesses into sacrificial material layers (142, 242). In one embodiment, the memory material layer 54 includes a silicon nitride layer. In one embodiment, the sacrificial material layers (142, 242) and the insulating layers (132, 232) can have vertically coincident sidewalls, and the memory material layer 54 can be formed as a single continuous layer.

In another embodiment, the sacrificial material layers (142, 242) can be laterally recessed with respect to the sidewalls of the insulating layers (132, 232), and a combination of a deposition process and an anisotropic etch process can be employed to form the memory material layer 54 as a plurality of memory material portions that are vertically spaced apart. While an embodiment is described in which the memory material layer 54 is a single continuous layer, alternative embodiments are expressly contemplated herein in which the memory material layer 54 is replaced with a plurality of memory material portions (which can be dielectric charge trapping material portions or electrically isolated floating gates) that are vertically spaced apart. The memory material layer 54 can be formed, for example, by chemical vapor deposition (CVD), atomic layer deposition (ALD), physical vapor deposition (PVD), or any suitable deposition technique for storing electrical charges therein. The thickness of the memory material layer 54 can be in a range from 2 nm to 20 nm, although lesser and greater thicknesses can also be employed.

The optional dielectric liner 56 includes a dielectric material. In one embodiment, the dielectric liner 56 comprises a tunneling dielectric layer through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 may include a stack of a first silicon oxide layer, a silicon oxynitride layer, and a second silicon oxide layer, which is commonly known as an ONO stack. In one embodiment, the dielectric liner 56 may include a silicon oxide layer that is substantially free of carbon or a silicon oxynitride layer that is substantially free of carbon. The thickness of the optional dielectric liner 56 may be in a range from 2 nm to 20 nm, although lesser and greater thicknesses may also be used. The stack of the blocking dielectric layer 52, the memory material layer 54, and the optional dielectric liner 56 constitutes a memory film 50 that stores memory bits.

The semiconductor channel material layer 60L includes a p-doped semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L may having a uniform doping. In one embodiment, the semiconductor channel material layer 60L has a p-type doping in which p-type dopants (such as boron atoms) are present at an atomic concentration in a range from 1.0×10¹²/cm³ to 1.0×10¹⁸/cm³, such as from 1.0×10¹⁴/cm³ to 1.0×10¹⁷/cm³. In one embodiment, the semiconductor channel material layer 60L includes, and/or consists essentially of, boron-doped amorphous silicon or boron-doped polysilicon. In another embodiment, the semiconductor channel material layer 60L has an n-type doping in which n-type dopants (such as phosphor atoms or arsenic atoms) are present at an atomic concentration in a range from 1.0×10¹²/cm to 1.0×10¹⁸/cm³, such as from 1.0×10¹⁴/cm³ to 1.0×10¹⁷/cm³. The semiconductor channel material layer 60L may be formed by a conformal deposition method such as low pressure chemical vapor deposition (LPCVD). The thickness of the semiconductor channel material layer 60L may be in a range from 2 nm to 10 nm, although lesser and greater thicknesses may also be used. A cavity 49′ is formed in the volume of each memory opening 49 that is not filled with the deposited material layers (52, 54, 56, 60L).

Referring to FIGS. 12C and 13C, a dielectric core layer may be deposited in remaining unfilled volumes of the inter-tier memory openings 49, the inter-tier support openings 29, and the second-tier support openings 229 overlying the dielectric pillar structures 120. The dielectric core layer includes a dielectric material such as silicon oxide or organosilicate glass. The dielectric core layer may be deposited by a conformal deposition method such as low pressure chemical vapor deposition (LPCVD), or by a self-planarizing deposition process such as spin coating. The horizontal portion of the dielectric core layer overlying the second insulating cap layer 270 may be removed, for example, by a recess etch. The recess etch continues until top surfaces of the remaining portions of the dielectric core layer are recessed to a height between the top surface of the second insulating cap layer 270 and the bottom surface of the second insulating cap layer 270. Each remaining portion of the dielectric core layer constitutes a dielectric core 62.

Referring to FIGS. 12D and 13D, a doped semiconductor material having a doping of a second conductivity type may be deposited in cavities overlying the dielectric cores 62. The second conductivity type is the opposite of the first conductivity type. For example, if the first conductivity type is p-type, the second conductivity type is n-type, and vice versa. Portions of the deposited doped semiconductor material, the semiconductor channel material layer 60L, the optional dielectric liner 56, the memory material layer 54, and the blocking dielectric layer 52 that overlie the horizontal plane including the top surface of the second insulating cap layer 270 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁸/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. An optional dielectric liner 56 is surrounded by a memory material layer 54, and laterally surrounds a vertical semiconductor channel 60. Each adjoining set of a blocking dielectric layer 52, a memory material layer 54, and an optional dielectric liner 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of backside recesses. As used herein, a macroscopic retention time refers to a retention time suitable for operation of a memory device as a permanent memory device such as a retention time in excess of 24 hours.

Each combination of a memory film 50 and a vertical semiconductor channel 60 within a respective inter-tier memory opening 49 constitutes a memory stack structure 55. The memory stack structure 55 is a combination of a vertical semiconductor channel 60, an optional dielectric liner 56, a plurality of memory elements comprising portions of the memory material layer 54, and an optional blocking dielectric layer 52. Each combination of a memory stack structure 55, a dielectric core 62, and a drain region 63 within an inter-tier memory opening 49 constitutes a memory opening fill structure 58. Each combination of a memory stack structure 55, a dielectric core 62, and a drain region 63 within an inter-tier support opening 29 constitutes a support pillar structure 20. Each combination of a memory stack structure 55, a dielectric core 62, and a drain region 63 within a second-tier support opening 229 constitutes a composite support pillar 228. The in-process source-level material layers 110′, the first-tier structure (132, 142, 170, 165), the second-tier structure (232, 242, 270, 265, 72), the inter-tier dielectric layer 180, the memory opening fill structures 58, the support pillar structures 20, and the composite support pillars 228 collectively constitute a memory-level assembly. Each vertical stack of a dielectric support pillar 120 and a composite support pillar 228 constitutes a hybrid support structure (120, 228).

Generally, the memory opening fill structures 58, the support pillar structures 20 and the composite support pillars 228 can be formed in the inter-tier memory openings 49, in the inter-tier support openings 29 and in the second-tier support openings 229, respectively, by depositing and patterning at least a memory material and a semiconductor material. In one embodiment, the memory opening fill structures 58, the support pillar structures 20 and the composite support pillars 228 can be formed depositing and patterning a layer stack including a blocking dielectric layer 52 including the memory material, a memory material layer 54, an optional dielectric liner 56, and a semiconductor channel 60 material layer including the semiconductor material in each of the inter-tier memory openings 49, in the inter-tier support openings 29, and the second-tier support openings 229. Each of the memory opening fill structures 58 and the support pillar structures 20 comprises a respective vertical stack of memory elements comprising portions of the memory material (e.g., portions of the memory film 50) and a respective vertical semiconductor channel 60 comprising a portion of the semiconductor material.

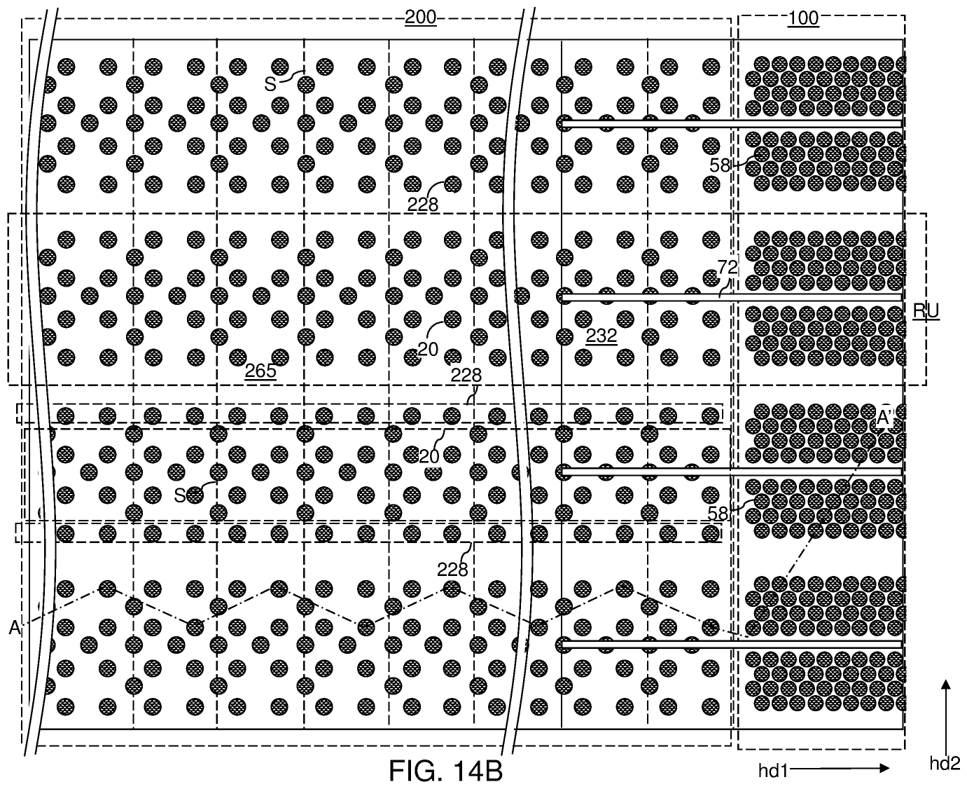

Referring to FIGS. 14A and 14B, the first exemplary structure is illustrated after formation of the memory opening fill structures 58, the support pillar structures 20, and the hybrid support structures (120, 228). The memory opening fill structures 58 can be located in the memory openings 49. Each of the memory opening fill structures 58 and the support pillar structures 20 comprises a respective vertical stack of memory elements (e.g., portions of the memory film 50) and a respective vertical semiconductor channel 60 including a respective portion of a semiconductor material.

Hybrid support structures (120, 228) can vertically extend at least through a respective subset of layers within the first-tier alternating stack (132, 146), and may vertically extend through the second retro-stepped dielectric material portion 265 and/or the first retro-stepped dielectric material portion 165. Each of the hybrid support structures (120, 228) comprises a respective vertical stack of a dielectric support pillar 120 and a composite support pillar 228 having a respective dielectric outer surface and including a respective additional portion of the semiconductor material. In one embodiment, the dielectric support pillar 120 may underlie the composite support pillar 228 within each hybrid support structure (120, 228). The dielectric support pillars 120 may have top surfaces located within a horizontal plane including a bottom surface of the second-tier alternating stack (232, 242).

Support pillar structures 20 can vertically extend through at least a bottommost layer within the first-tier alternating stack (132, 142), can have a same height as the memory opening fill structures 58, and can comprise a respective dummy vertical semiconductor channel 60 having a same height as vertical semiconductor channels 60 within the memory opening fill structures 58.

In one embodiment, a subset of the hybrid support structures (120, 228) vertically extends through each layer within the first-tier alternating stack (132, 142) and the second-tier alternating stack (232, 242). A first stepped dielectric material portion 165 may overlie first stepped surfaces of the first-tier alternating stack (132, 142), and a second stepped dielectric material portion 265 may overlie second stepped surfaces of the second-tier alternating stack (232, 246). A first subset of the hybrid support structures (120, 228) may vertically extend through each layer within the first-tier alternating stack (132, 142), a respective subset of layers within the second-tier alternating stack (232, 242), and the second retro-stepped dielectric material portion 265. In one embodiment, a second subset of the hybrid support structures (120, 228) vertically extends through the first stepped dielectric material portion 165 and the second stepped dielectric material portion 265 and does not extend through the second-tier alternating stack (232, 242).

In one embodiment, each vertical stack of memory elements comprises portions of a memory material (e.g., portions of the memory film 50); and each composite support pillar 228 includes a respective additional portion of the memory material (e.g., memory film 50). In one embodiment, each of the memory opening fill structures 58 comprises a respective blocking dielectric layer 52 laterally surrounding the respective vertical stack of memory elements; and each of the composite support pillars 228 comprises a respective blocking dielectric layer 52 laterally having a same material composition as the blocking dielectric layers 52 in the memory opening fill structures 58.

In one embodiment, each of the memory opening fill structures 58 comprises a respective dielectric core 62 comprising a respective portion of a dielectric fill material; and each of the composite support pillars 228 comprises a respective dielectric core 62 comprising a respective additional portion of the dielectric fill material.

In one embodiment, each additional portion of the semiconductor material in each of the composite support pillars 228 has a lesser vertical extent than the vertical semiconductor channels 60 in the memory opening fill structures 58. In one embodiment, the memory opening fill structures 58 and the hybrid support structures (120, 228) have a same height.

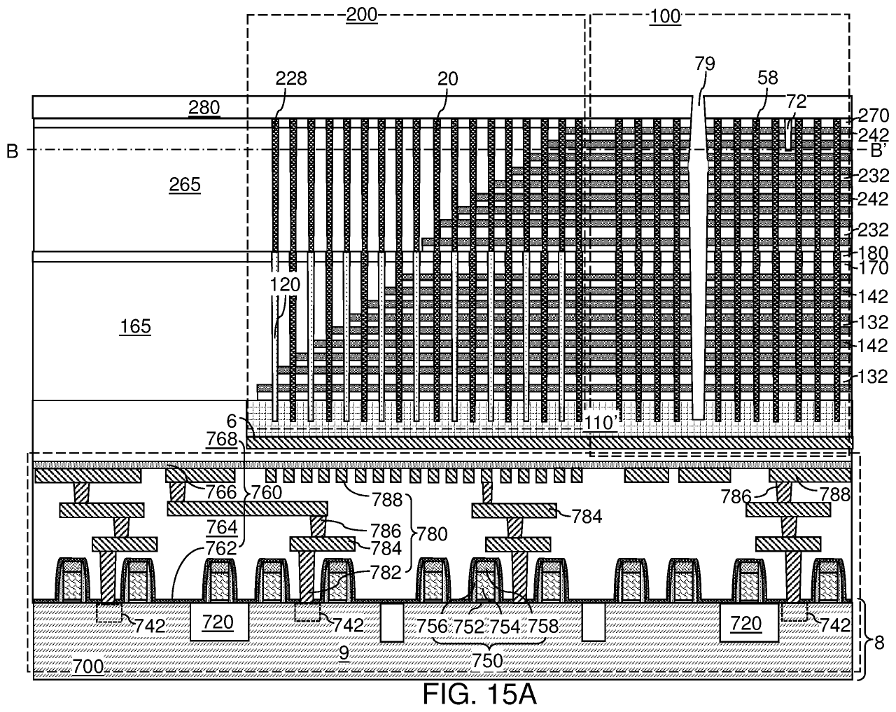

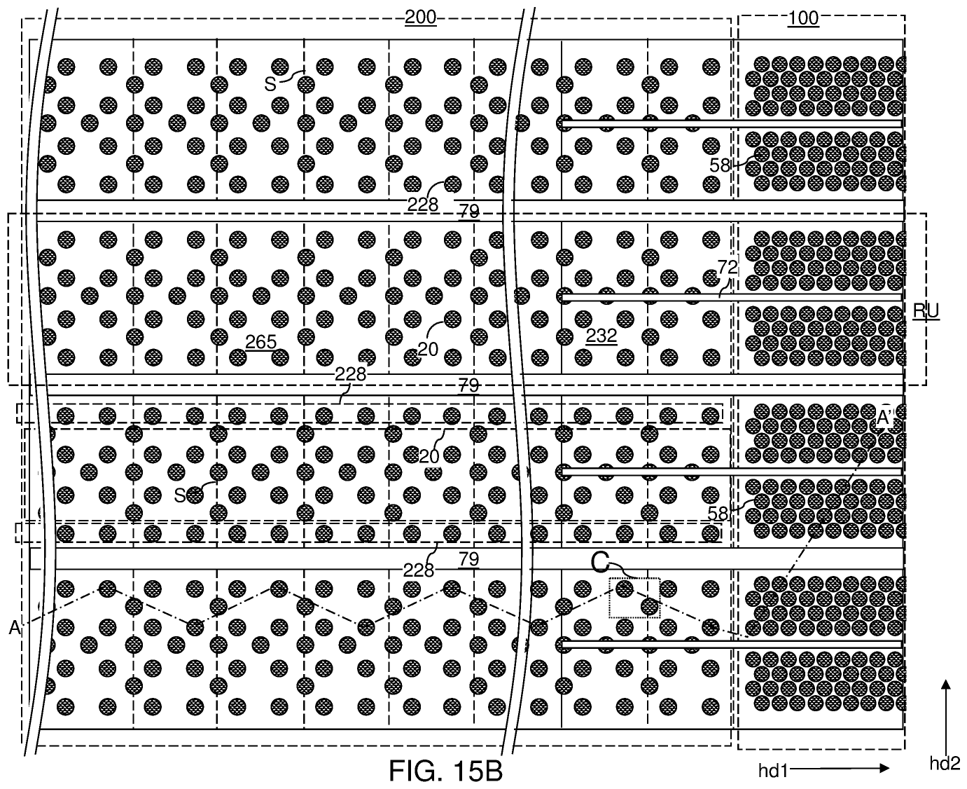

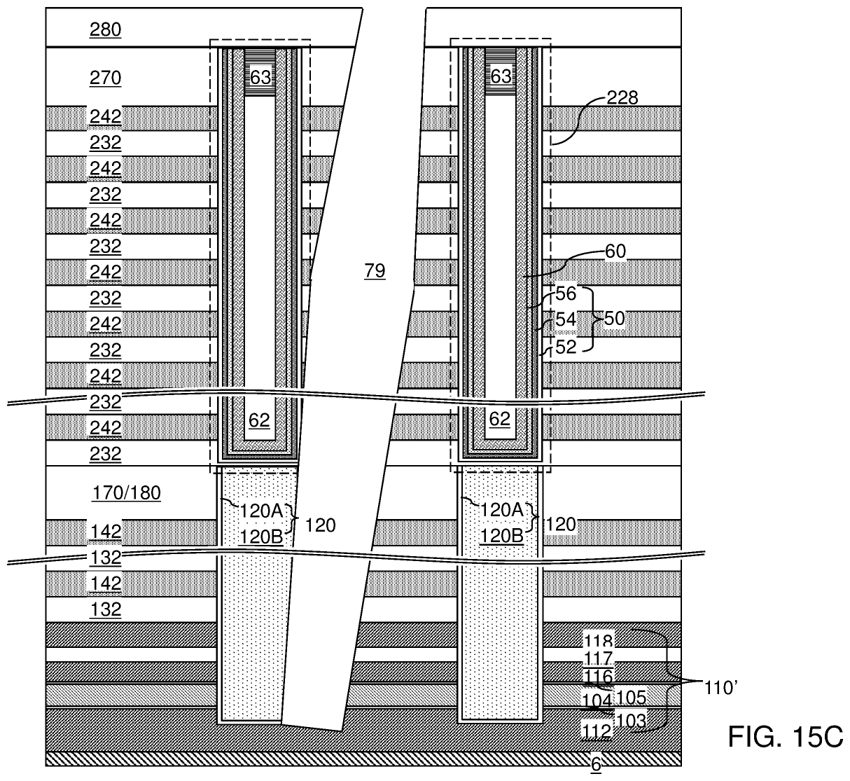

Referring to FIGS. 15A-15C, a first contact-level dielectric layer 280 may be formed over the second-tier structure (232, 242, 270, 265, 72). The first contact-level dielectric layer 280 includes a dielectric material such as silicon oxide, and may be formed by a conformal or non-conformal deposition process. For example, the first contact-level dielectric layer 280 may include undoped silicate glass and may have a thickness in a range from 100 nm to 600 nm, although lesser and greater thicknesses may also be used.

A photoresist layer may be applied over the first contact-level dielectric layer 280 and may be lithographically patterned to form elongated openings that extend along the first horizontal direction hd1 between clusters of memory opening fill structures 58. Backside trenches 79 may be formed by transferring the pattern in the photoresist layer (not shown) through the first contact-level dielectric layer 280, the second-tier structure (232, 242, 270, 265, 72), and the first-tier structure (132, 142, 170, 165), and into the in-process source-level material layers 110′. Portions of the first contact-level dielectric layer 280, the second-tier structure (232, 242, 270, 265, 72), the first-tier structure (132, 142, 170, 165), and the in-process source-level material layers 110′ that underlie the openings in the photoresist layer may be removed to form the backside trenches 79. In one embodiment, the backside trenches 79 may be formed between clusters of memory opening fill structures 58 in the memory array region 100, and may be formed between neighboring rows of hybrid support structures (120, 228).

In one embodiment shown in FIG. 15C, one, a plurality or each of the backside trenches 79 may be located relatively close to the hybrid support structures (120, 228) and have a tilted and/or bent profile (e.g., due to photolithography error), such that dielectric support pillar 120 portion of the hybrid support structure (120, 228) is exposed in the lower portion backside trench 79. In this case, since the dielectric support pillar structure 120 comprises only a dielectric material, such as silicon oxide (which is the same as the material of the insulating layers 132), the dielectric pillar structure 120 is not removed during the subsequent selective etching step during which the sacrificial material layers 142 are removed. In contrast, if the bottom portion of the support pillar structure 20 was exposed in the backside trench 79, then the silicon nitride memory material layer 54 may be removed together with the silicon nitride sacrificial material layers and replaced with a metal layer during formation of the word lines and select gate electrodes. This may cause a short circuit between vertically separated word lines and/or select gate electrodes. Thus, the dielectric pillar structures 120 located in the hybrid support structures (120, 228) adjacent to the backside trenches 79 reduce the likelihood of a short circuit. In contrast, the silicon containing composite support pillars 228 have a higher structural strength than the dielectric pillar structures 120, and thus increase the strength of the hybrid support structures (120, 228). Furthermore, the silicon containing support pillar structure 20 also have a higher structural strength than the dielectric pillar structures 120 and are located farther from the backside trenches 79 than the hybrid support structures (120, 228). Thus, the support pillar structures 20 provide improved structural strength without increasing the likelihood of a short circuit because the support pillar structures 20 are not exposed in the backside trenches 79.

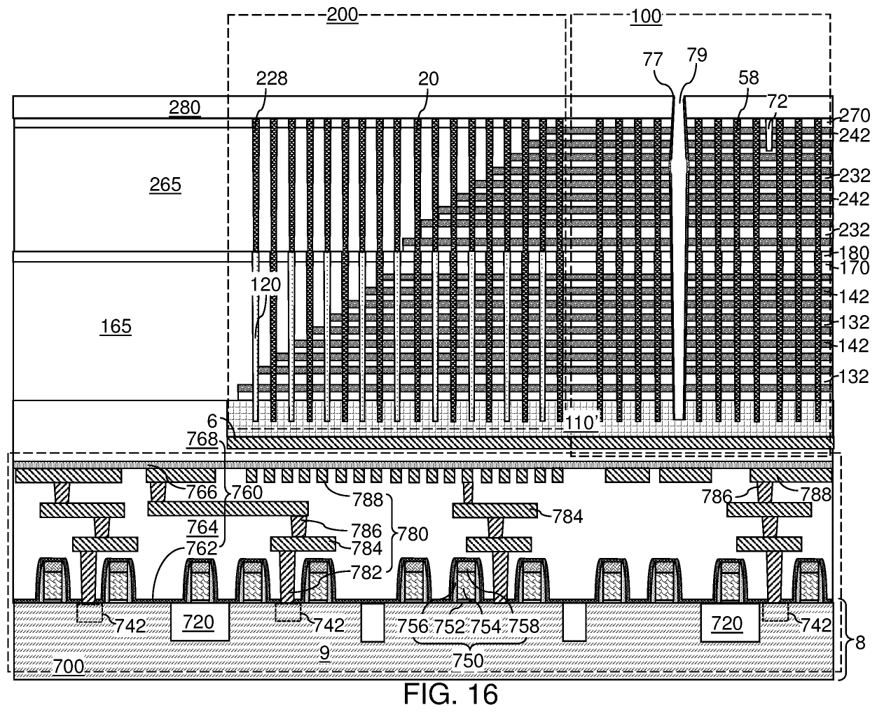

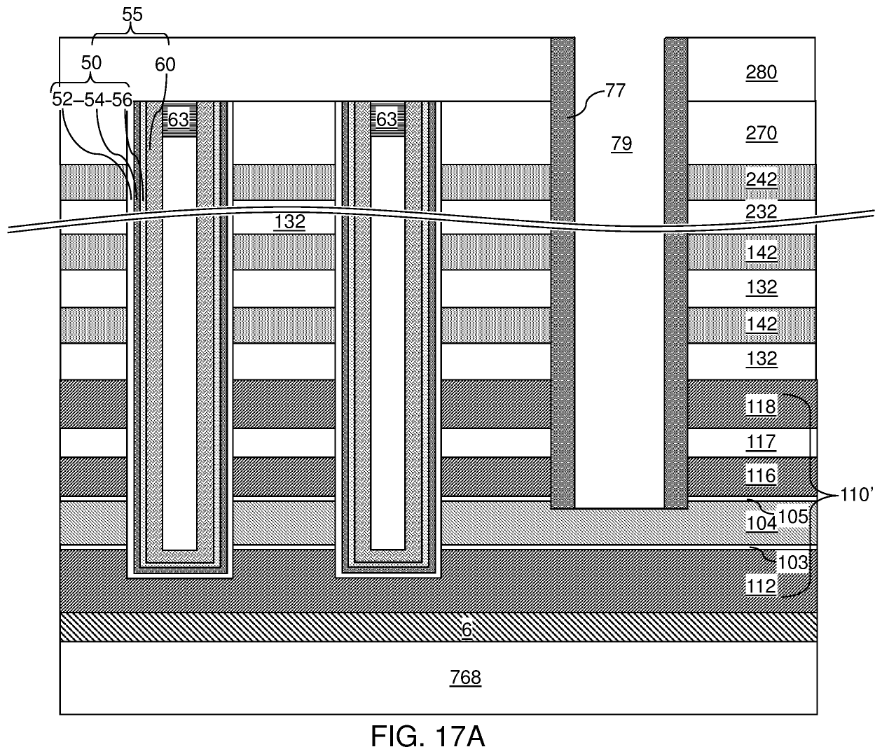

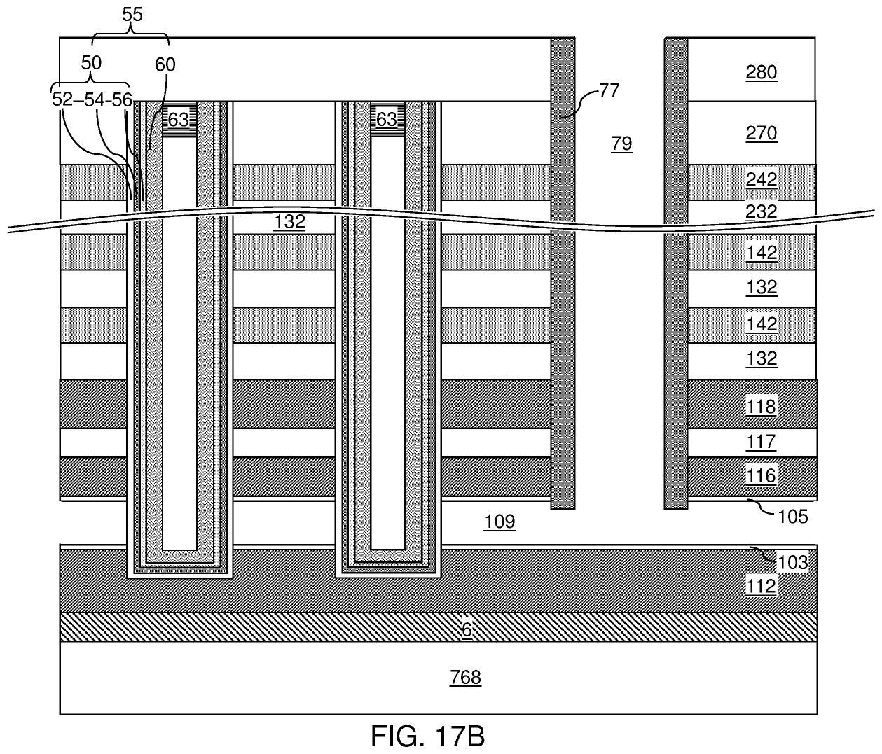

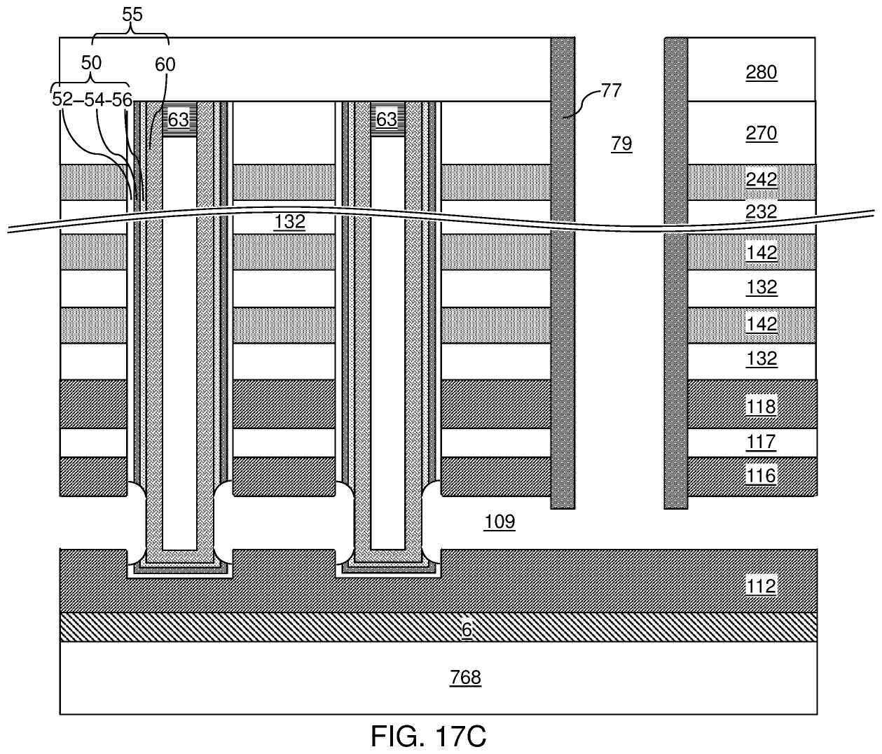

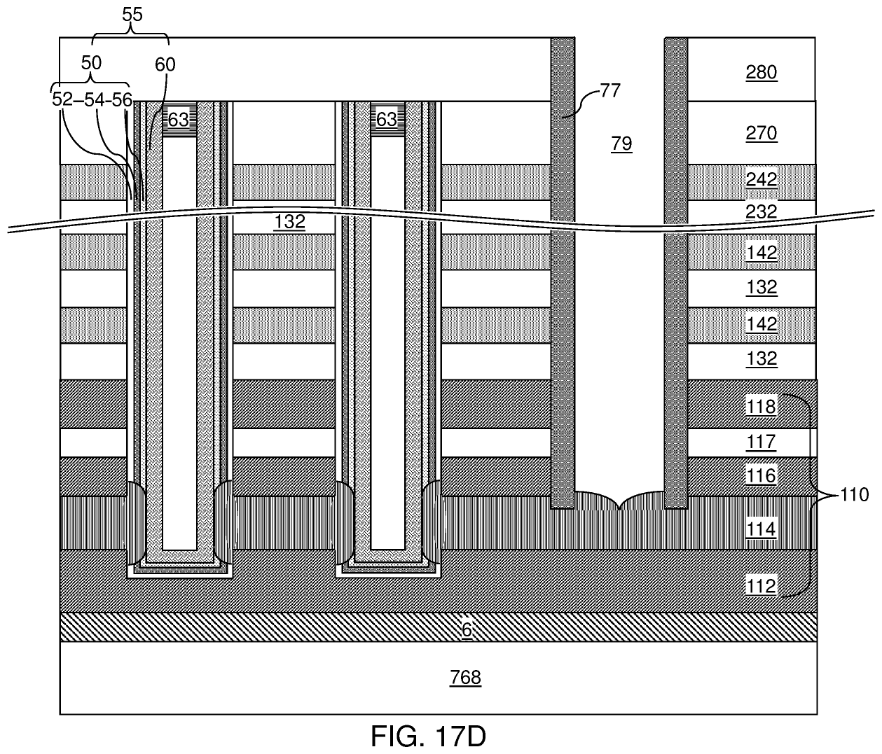

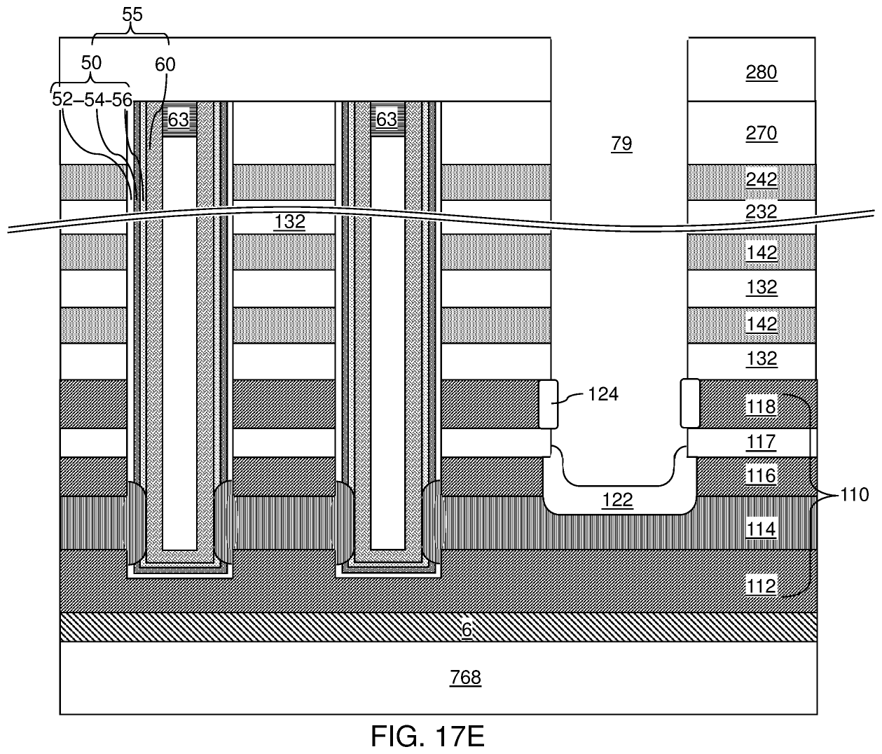

Referring to FIGS. 16 and 17A, a backside trench spacer 77 may be formed on sidewalls of each backside trench 79. For example, a conformal spacer material layer may be deposited in the backside trenches 79 and over the first contact-level dielectric layer 280, and may be anisotropically etched to form the backside trench spacers 77. The backside trench spacers 77 include a material that is different from the material of the source-level sacrificial layer 104. For example, the backside trench spacers 77 may include silicon nitride.

Referring to FIG. 17B, an etchant that etches the material of the source-level sacrificial layer 104 selective to the materials of the first-tier alternating stack (132, 142), the second-tier alternating stack (232, 242), the first and second insulating cap layers (170, 270), the first contact-level dielectric layer 280, the upper sacrificial liner 105, and the lower sacrificial liner 103 may be introduced into the backside trenches in an isotropic etch process. For example, if the source-level sacrificial layer 104 includes undoped amorphous silicon or an undoped amorphous silicon-germanium alloy, the backside trench spacers 77 include silicon nitride, and the upper and lower sacrificial liners (105, 103) include silicon oxide, a wet etch process using hot trimethyl-2 hydroxyethyl ammonium hydroxide (“hot TMY”) or tetramethyl ammonium hydroxide (TMAH) may be used to remove the source-level sacrificial layer 104 selective to the backside trench spacers 77 and the upper and lower sacrificial liners (105, 103). A source cavity 109 is formed in the volume from which the source-level sacrificial layer 104 is removed.

Wet etch chemicals such as hot TMY and TMAH are selective to doped semiconductor materials such as the p-doped semiconductor material and/or the n-doped semiconductor material of the upper source-level semiconductor layer 116 and the lower source-level semiconductor layer 112. Thus, use of selective wet etch chemicals such as hot TMY and TMAH for the wet etch process that forms the source cavity 109 provides a large process window against etch depth variation during formation of the backside trenches 79. Specifically, even if sidewalls of the upper source-level semiconductor layer 116 are physically exposed or even if a surface of the lower source-level semiconductor layer 112 is physically exposed upon formation of the source cavity 109 and/or the backside trench spacers 77, collateral etching of the upper source-level semiconductor layer 116 and/or the lower source-level semiconductor layer 112 is minimal, and the structural change to the first exemplary structure caused by accidental physical exposure of the surfaces of the upper source-level semiconductor layer 116 and/or the lower source-level semiconductor layer 112 during manufacturing steps do not result in device failures. Each of the memory opening fill structures 58 is physically exposed to the source cavity 109. Specifically, each of the memory opening fill structures 58 includes a sidewall and that are physically exposed to the source cavity 109.

Referring to FIG. 17C, a sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper and lower sacrificial liners (105, 103) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners (105, 103). A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom portion of each of the memory films 50 selective to at least one source-level semiconductor layer (such as the lower source-level semiconductor layer 112 and the upper source-level semiconductor layer 116) and the vertical semiconductor channels 60.

Referring to FIG. 17D, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. A semiconductor precursor gas, an etchant, and a dopant gas may be flowed concurrently into a process chamber including the first exemplary structure during the selective semiconductor deposition process. For example, the semiconductor precursor gas may include silane, disilane, or dichlorosilane, the etchant gas may include gaseous hydrogen chloride, and the dopant gas may include a hydride of a dopant atom such as phosphine, arsine, stibine, or diborane. In this case, the selective semiconductor deposition process grows a doped semiconductor material having a doping of the second conductivity type from physically exposed semiconductor surfaces around the source cavity 109. The deposited doped semiconductor material forms a source contact layer 114, which may contact sidewalls of the vertical semiconductor channels 60. The atomic concentration of the dopants of the second conductivity type in the deposited semiconductor material may be in a range from 1.0×10²⁰/cm³ to 2.0×10²¹/cm³, such as from 2.0×10²⁰/cm³ to 8.0×10²⁰/cm³. The source contact layer 114 as initially formed may consist essentially of semiconductor atoms and dopant atoms of the second conductivity type. Alternatively, at least one non-selective doped semiconductor material deposition process may be used to form the source contact layer 114. Optionally, one or more etch back processes may be used in combination with a plurality of selective or non-selective deposition processes to provide a seamless and/or voidless source contact layer 114.

The duration of the selective semiconductor deposition process may be selected such that the source cavity 109 is filled with the source contact layer 114, and the source contact layer 114 contacts bottom end portions of inner sidewalls of the backside trench spacers 77. In one embodiment, the source contact layer 114 may be formed by selectively depositing a doped semiconductor material having a doping of the second conductivity type from semiconductor surfaces around the source cavity 109. In one embodiment, the doped semiconductor material may include doped polysilicon. Thus, the source-level sacrificial layer 104 may be replaced with the source contact layer 114.

The layer stack including the lower source-level semiconductor layer 112, the source contact layer 114, and the upper source-level semiconductor layer 116 constitutes a buried source layer (112, 114, 116). The set of layers including the buried source layer (112, 114, 116), the source-level insulating layer 117, and the source-select-level conductive layer 118 constitutes source-level material layers 110, which replaces the in-process source-level material layers 110′.

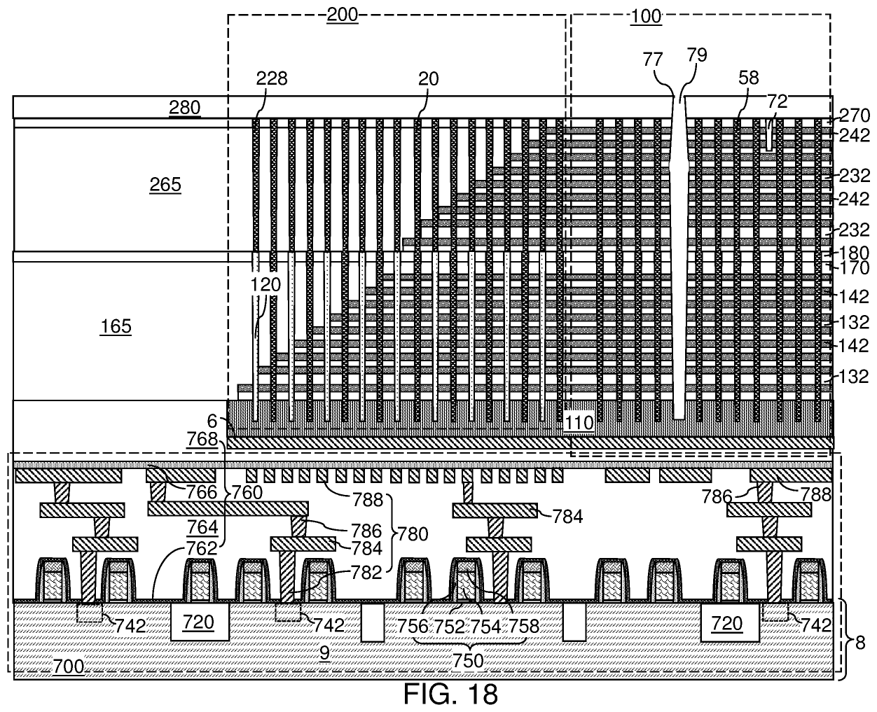

Referring to FIGS. 17E and 18, the backside trench spacers 77 may be removed selective to the insulating layers (132, 232), the first and second insulating cap layers (170, 270), the first contact-level dielectric layer 280, and the source contact layer 114 using an isotropic etch process. For example, if the backside trench spacers 77 include silicon nitride, a wet etch process using hot phosphoric acid may be performed to remove the backside trench spacers 77. In one embodiment, the isotropic etch process that removes the backside trench spacers 77 may be combined with a subsequent isotropic etch process that etches the sacrificial material layers (142, 242) selective to the insulating layers (132, 232), the first and second insulating cap layers (170, 270), the first contact-level dielectric layer 280, and the source contact layer 114.

An oxidation process may be performed to convert physically exposed surface portions of semiconductor materials into dielectric semiconductor oxide portions. For example, surfaces portions of the source contact layer 114 and the upper source-level semiconductor layer 116 may be converted into dielectric semiconductor oxide plates 122, and surface portions of the source-select-level conductive layer 118 may be converted into annular dielectric semiconductor oxide spacers 124.

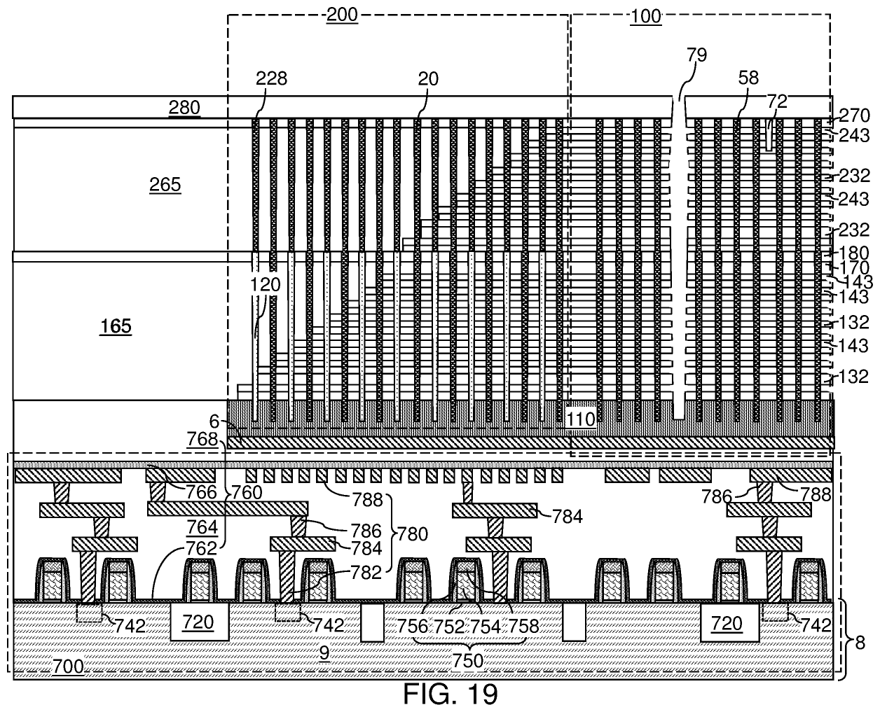

Referring to FIG. 19, the sacrificial material layers (142, 242) are may be removed selective to the insulating layers (132, 232), the first and second insulating cap layers (170, 270), the first contact-level dielectric layer 280, and the source contact layer 114, the dielectric semiconductor oxide plates 122, and the annular dielectric semiconductor oxide spacers 124. For example, an etchant that selectively etches the materials of the sacrificial material layers (142, 242) with respect to the materials of the insulating layers (132, 232), the first and second insulating cap layers (170, 270), the retro-stepped dielectric material portions (165, 265), and the material of the outermost layer of the memory films 50 may be introduced into the backside trenches 79, for example, using an isotropic etch process. For example, the sacrificial material layers (142, 242) may include silicon nitride, the materials of the insulating layers (132, 232), the first and second insulating cap layers (170, 270), the retro-stepped dielectric material portions (165, 265), and the outermost layer of the memory films 50 may include silicon oxide materials.

The isotropic etch process may be a wet etch process using a wet etch solution, or may be a gas phase (dry) etch process in which the etchant is introduced in a vapor phase into the backside trench 79. For example, if the sacrificial material layers (142, 242) include silicon nitride, the etch process may be a wet etch process in which the first exemplary structure is immersed within a wet etch tank including phosphoric acid, which etches silicon nitride selective to silicon oxide, silicon, and various other materials used in the art.

Backside recesses (143, 243) are formed in volumes from which the sacrificial material layers (142, 242) are removed. The backside recesses (143, 243) include first backside recesses 143 that are formed in volumes from which the first sacrificial material layers 142 are removed and second backside recesses 243 that are formed in volumes from which the second sacrificial material layers 242 are removed. Each of the backside recesses (143, 243) may be a laterally extending cavity having a lateral dimension that is greater than the vertical extent of the cavity. In other words, the lateral dimension of each of the backside recesses (143, 243) may be greater than the height of the respective backside recess (143, 243). A plurality of backside recesses (143, 243) may be formed in the volumes from which the material of the sacrificial material layers (142, 242) is removed. Each of the backside recesses (143, 243) may extend substantially parallel to the top surface of the substrate semiconductor layer 9. A backside recess (143, 243) may be vertically bounded by a top surface of an underlying insulating layer (132, 232) and a bottom surface of an overlying insulating layer (132, 232). In one embodiment, each of the backside recesses (143, 243) may have a uniform height throughout.

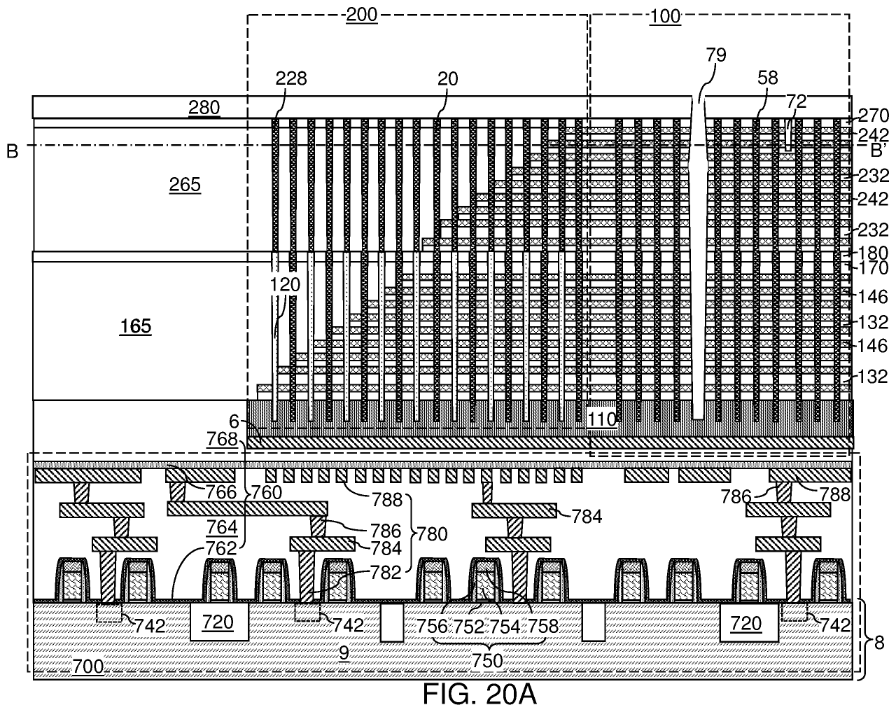

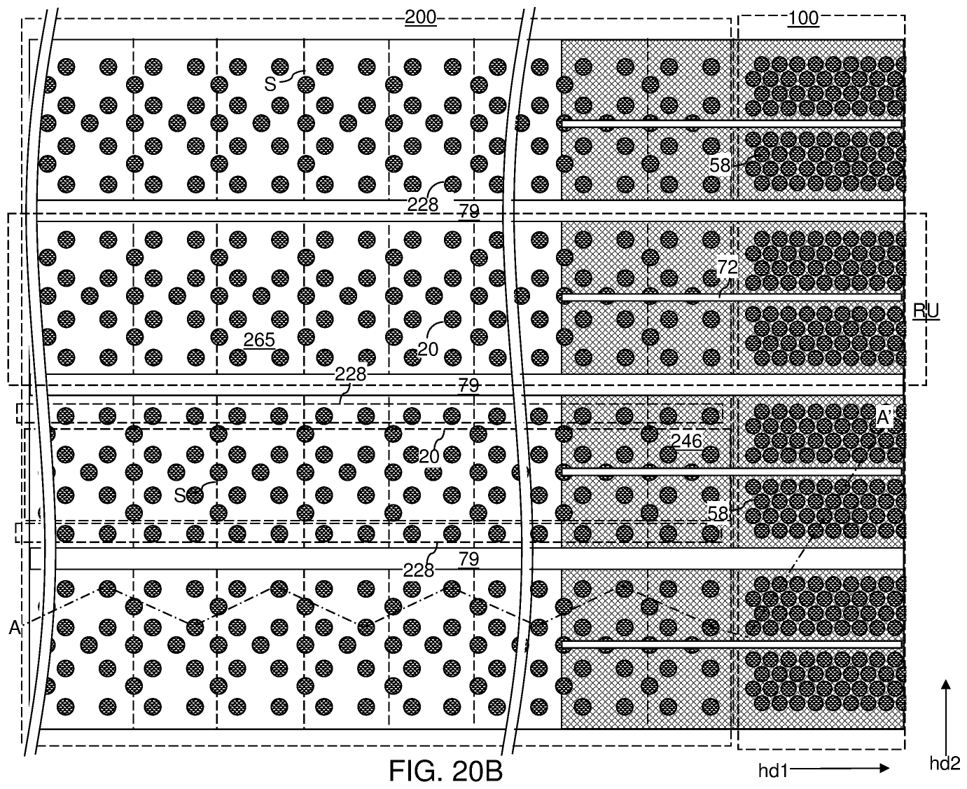

Referring to FIGS. 20A and 20B, a backside blocking dielectric layer (not shown) may be optionally deposited in the backside recesses (143, 243) and the backside trenches 79 and over the first contact-level dielectric layer 280. The backside blocking dielectric layer includes a dielectric material such as a dielectric metal oxide, silicon oxide, or a combination thereof. For example, the backside blocking dielectric layer may include aluminum oxide. The backside blocking dielectric layer may be formed by a conformal deposition process such as atomic layer deposition or chemical vapor deposition. The thickness of the backside blocking dielectric layer may be in a range from 1 nm to 20 nm, such as from 2 nm to 10 nm, although lesser and greater thicknesses may also be used.

At least one conductive material may be deposited in the plurality of backside recesses (143, 243), on the sidewalls of the backside trenches 79, and over the first contact-level dielectric layer 280. The at least one conductive material may be deposited by a conformal deposition method, which may be, for example, chemical vapor deposition (CVD), atomic layer deposition (ALD), electroless plating, electroplating, or a combination thereof. The at least one conductive material may include an elemental metal, an intermetallic alloy of at least two elemental metals, a conductive nitride of at least one elemental metal, a conductive metal oxide, a conductive doped semiconductor material, a conductive metal-semiconductor alloy such as a metal silicide, alloys thereof, and combinations or stacks thereof.

In one embodiment, the at least one conductive material may include at least one metallic material, i.e., an electrically conductive material that includes at least one metallic element. Non-limiting exemplary metallic materials that may be deposited in the backside recesses (143, 243) include tungsten, tungsten nitride, titanium, titanium nitride, tantalum, tantalum nitride, cobalt, and ruthenium. For example, the at least one conductive material may include a conductive metallic nitride liner that includes a conductive metallic nitride material such as TiN, TaN, WN, or a combination thereof, and a conductive fill material such as W, Co, Ru, Mo, Cu, or combinations thereof. In one embodiment, the at least one conductive material for filling the backside recesses (143, 243) may be a combination of titanium nitride layer and a tungsten fill material.

Electrically conductive layers (146, 246) may be formed in the backside recesses (143, 243) by deposition of the at least one conductive material. A plurality of first electrically conductive layers 146 may be formed in the plurality of first backside recesses 143, a plurality of second electrically conductive layers 246 may be formed in the plurality of second backside recesses 243, and a continuous metallic material layer (not shown) may be formed on the sidewalls of each backside trench 79 and over the first contact-level dielectric layer 280. Each of the first electrically conductive layers 146 and the second electrically conductive layers 246 may include a respective conductive metallic nitride liner and a respective conductive fill material. Thus, the first and second sacrificial material layers (142, 242) may be replaced with the first and second electrically conductive layers (146, 246), respectively. Specifically, each first sacrificial material layer 142 may be replaced with an optional portion of the backside blocking dielectric layer and a first electrically conductive layer 146, and each second sacrificial material layer 242 may be replaced with an optional portion of the backside blocking dielectric layer and a second electrically conductive layer 246. A backside cavity is present in the portion of each backside trench 79 that is not filled with the continuous metallic material layer.

Residual conductive material may be removed from inside the backside trenches 79. Specifically, the deposited metallic material of the continuous metallic material layer may be etched back from the sidewalls of each backside trench 79 and from above the first contact-level dielectric layer 280, for example, by an anisotropic or isotropic etch. Each remaining portion of the deposited metallic material in the first backside recesses constitutes a first electrically conductive layer 146. Each remaining portion of the deposited metallic material in the second backside recesses constitutes a second electrically conductive layer 246. Sidewalls of the first electrically conductive material layers 146 and the second electrically conductive layers may be physically exposed to a respective backside trench 79. The backside trenches may have a pair of curved sidewalls having a non-periodic width variation along the first horizontal direction hd1 and a non-linear width variation along the vertical direction.

Each electrically conductive layer (146, 246) may be a conductive sheet including openings therein. A first subset of the openings through each electrically conductive layer (146, 246) may be filled with memory opening fill structures 58. A second subset of the openings through each electrically conductive layer (146, 246) may be filled with the support pillar structures 20. Each electrically conductive layer (146, 246) may have a lesser area than any underlying electrically conductive layer (146, 246) because of the first and second stepped surfaces. Each electrically conductive layer (146, 246) may have a greater area than any overlying electrically conductive layer (146, 246) because of the first and second stepped surfaces.

In some embodiment, drain-select-level isolation structures 72 may be provided at topmost levels of the second electrically conductive layers 246. A subset of the second electrically conductive layers 246 located at the levels of the drain-select-level isolation structures 72 constitutes drain select gate electrodes. A subset of the electrically conductive layer (146, 246) located underneath the drain select gate electrodes may function as combinations of a control gate and a word line located at the same level. The control gate electrodes within each electrically conductive layer (146, 246) are the control gate electrodes for a vertical memory device including the memory stack structure 55.

Each of the memory stack structures 55 comprises a vertical stack of memory elements located at each level of the electrically conductive layers (146, 246). A subset of the electrically conductive layers (146, 246) may comprise word lines for the memory elements. The semiconductor devices in the underlying peripheral device region 700 may comprise word line switch devices configured to control a bias voltage to respective word lines. The memory-level assembly is located over the substrate semiconductor layer 9. The memory-level assembly includes at least one alternating stack (132, 146, 232, 246) and memory stack structures 55 vertically extending through the at least one alternating stack (132, 146, 232, 246).

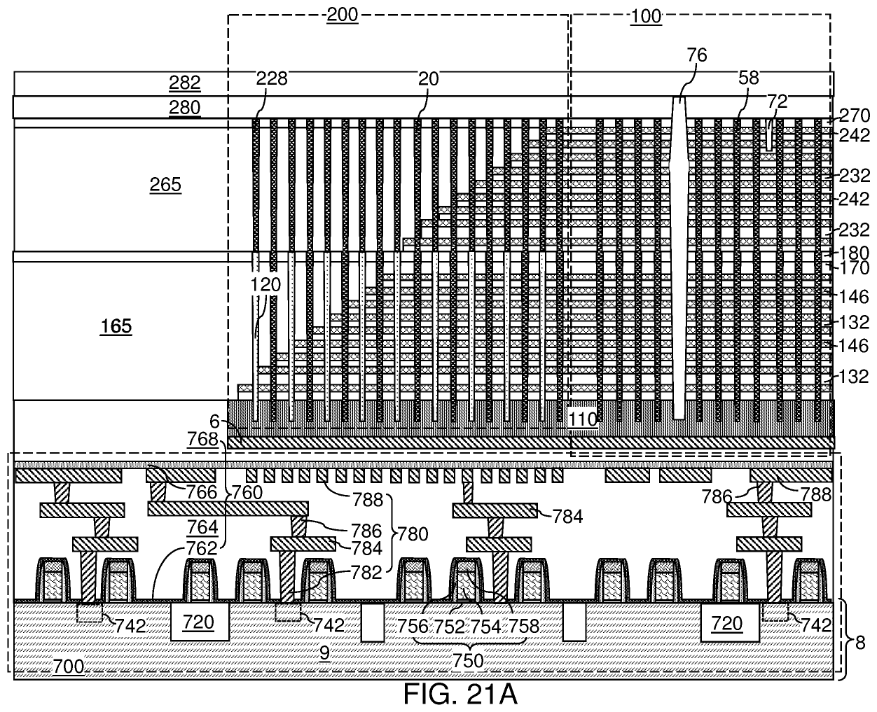

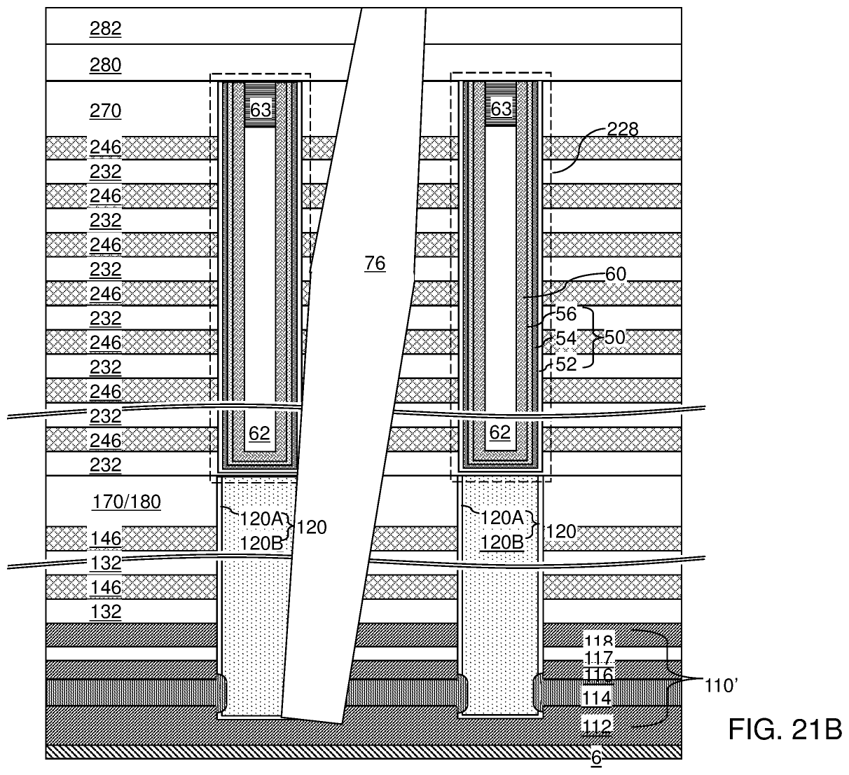

Referring to FIGS. 21A and 21B, a dielectric fill material may be conformally deposited in the backside trenches 79 and over the first contact-level dielectric layer 280 by a conformal deposition process. The dielectric material layer may include, for example, silicon oxide. Each portion of the dielectric fill material that fills a backside trench 79 constitutes a backside trench fill structure 76. The horizontally-extending portion of the dielectric fill material that overlies the first contact-level dielectric layer 280 constitutes a second contact-level dielectric layer 282. The second contact-level dielectric layer 282 may have a thickness in a range from 100 nm to 600 nm, although lesser and greater thicknesses may also be used.

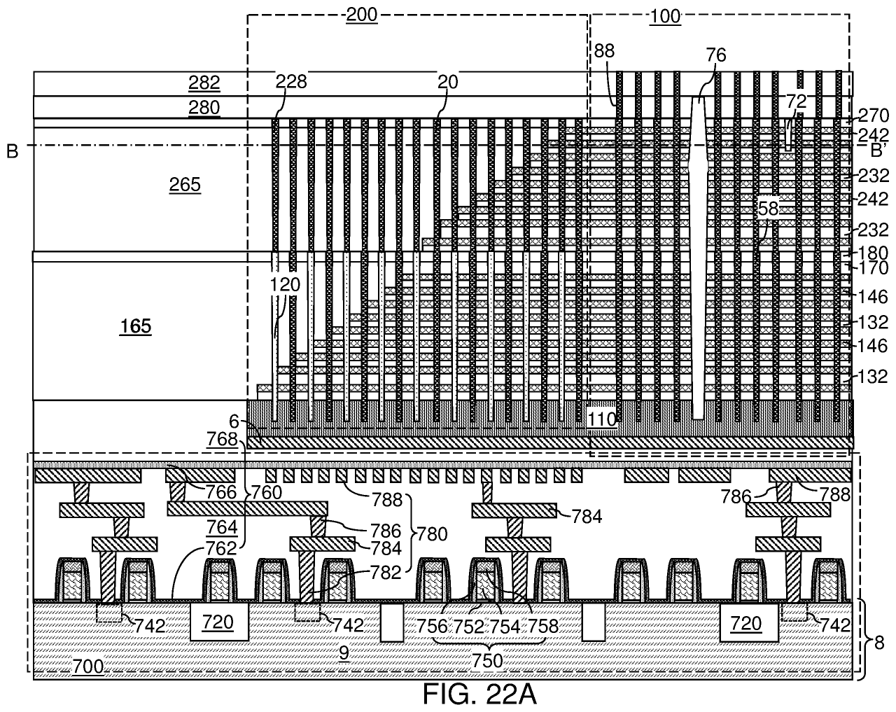

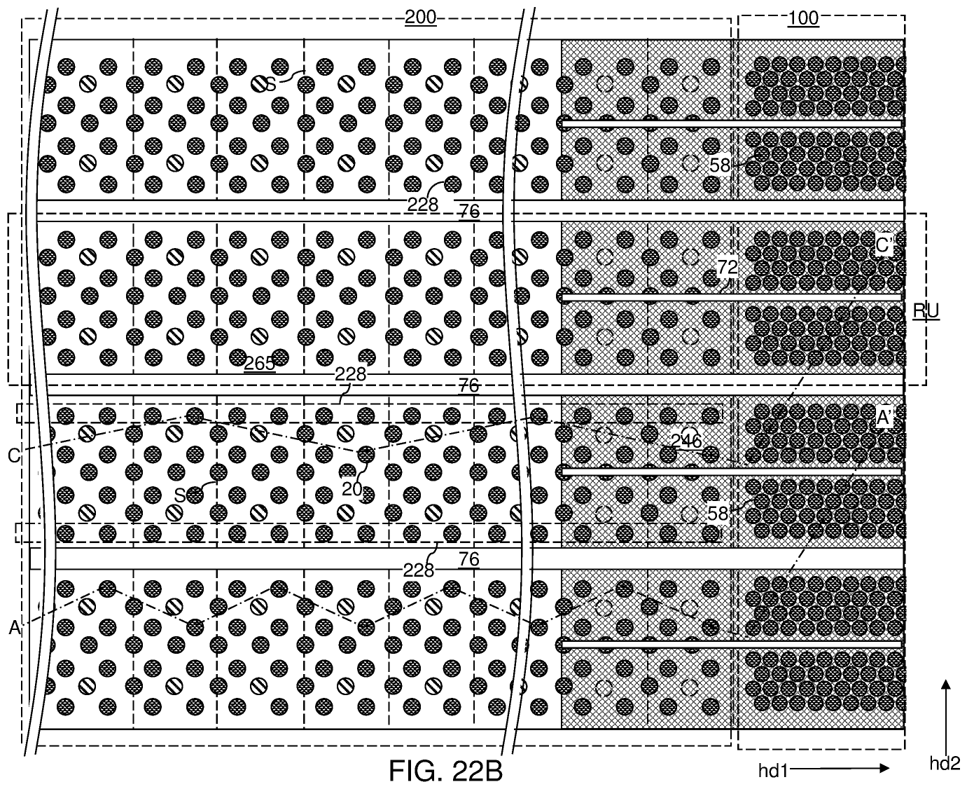

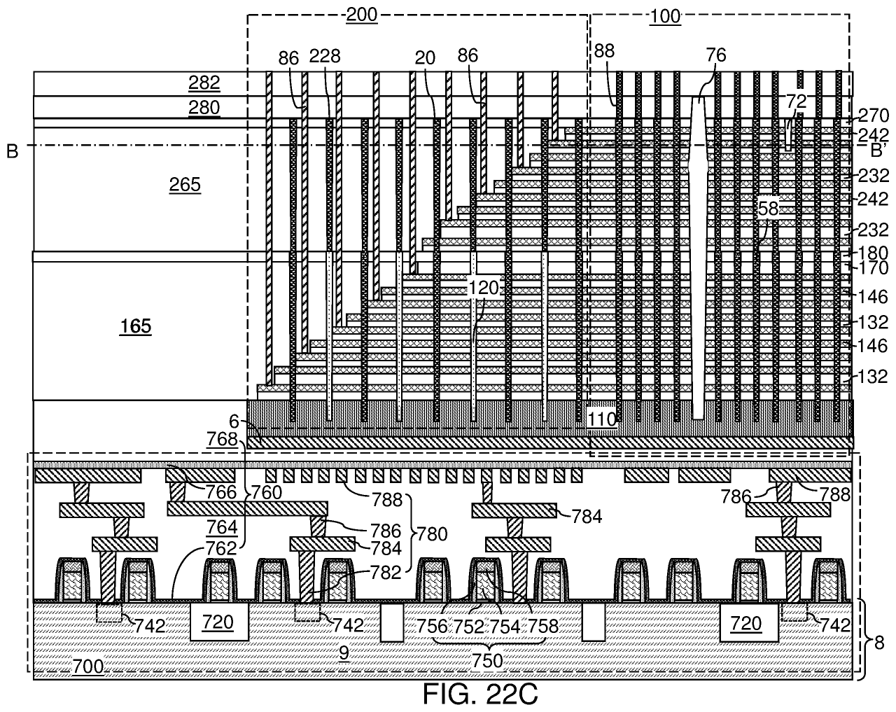

Referring to FIGS. 22A-22C, a photoresist layer (not shown) may be applied over the second contact-level dielectric layer 282, and may be lithographically patterned to form various openings therein. The openings in the photoresist layer may comprise openings for forming drain contact via structures in the memory array region 100, and openings for forming layer contact via structures in the staircase region 200. An anisotropic etch process is performed to transfer the pattern in the photoresist layer through the contact-level dielectric layers (282, 280) and underlying dielectric material portions. The drain regions 63 and the electrically conductive layers (146, 246) may be used as etch stop structures. Drain contact via cavities may be formed over each drain region 63, and layer contact via cavities may be formed over each electrically conductive layer (146. 246) at the stepped surfaces underlying the first and second retro-stepped dielectric material portions (165, 265). The photoresist layer may be subsequently removed, for example, by ashing.

Drain contact via structures 88 are formed in the drain contact via cavities and on a top surface of a respective one of the drain regions 63. Layer contact via structures 86 are formed in the layer contact via cavities and on a top surface of a respective one of the electrically conductive layers (146, 246). The layer contact via structures 86 may include drain select level contact via structures that contact a subset of the second electrically conductive layers 246 that function as drain select level gate electrodes. Further, the layer contact via structures 86 may include word line contact via structures that contact electrically conductive layers (146, 246) that underlie the drain select level gate electrodes and function as word lines for the memory stack structures 55.

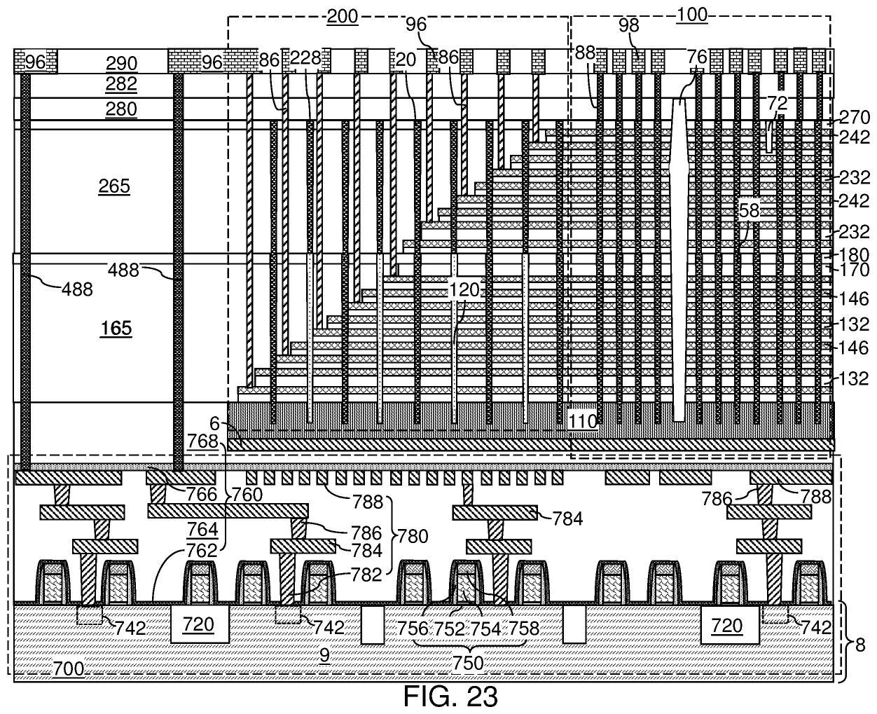

Referring to FIG. 23, peripheral-region via cavities may be formed through the second and first contact-level dielectric layers (282, 280), the second and first retro-stepped dielectric material portions (265, 165), and the at least one second dielectric material layer 768 to top surfaces of a first subset of the lower-level metal interconnect structure 780 in the peripheral device region 400. At least one conductive material may be deposited in the peripheral-region via cavities. Excess portions of the at least one conductive material may be removed from above the horizontal plane including the top surface of the second contact-level dielectric layer 282. Each remaining portion of the at least one conductive material in a peripheral-region via cavity constitutes a through-memory-level contact via structure 488.

At least one additional dielectric layer may be formed over the contact-level dielectric layers (280, 282), and additional metal interconnect structures (herein referred to as upper-level metal interconnect structures) may be formed in the at least one additional dielectric layer. For example, the at least one additional dielectric layer may include a line-level dielectric layer 290 that is formed over the contact-level dielectric layers (280, 282). The upper-level metal interconnect structures may include bit lines 98 contacting a respective one of the drain contact via structures 88, and interconnection line structures 96 contacting, and/or electrically connected to, at least one of the layer contact via structures 86 and/or the through-memory-level contact via structures 488. The word line contact via structures (which are provided as a subset of the layer contact via structures 86) may be electrically connected to the word line driver circuit through a subset of the lower-level metal interconnect structures 780 and through a subset of the through-memory-level contact via structures 488.

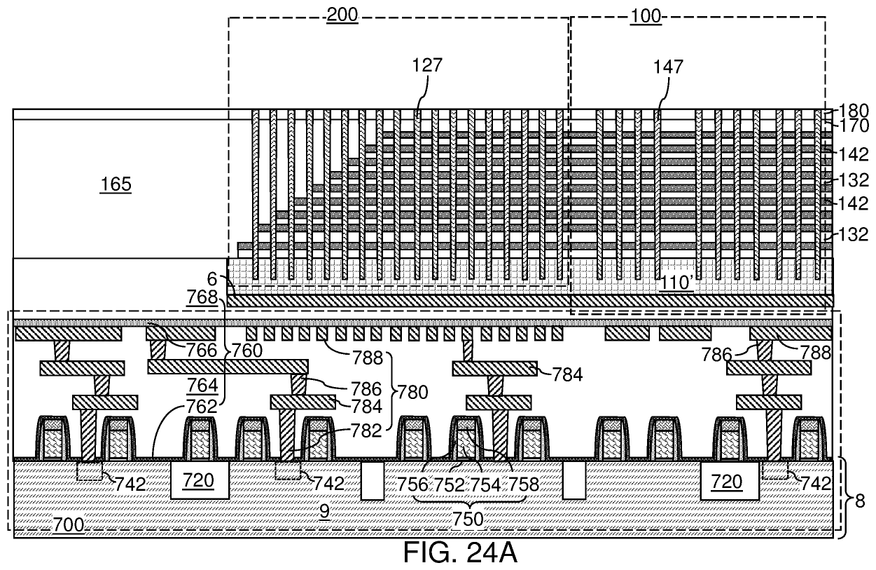

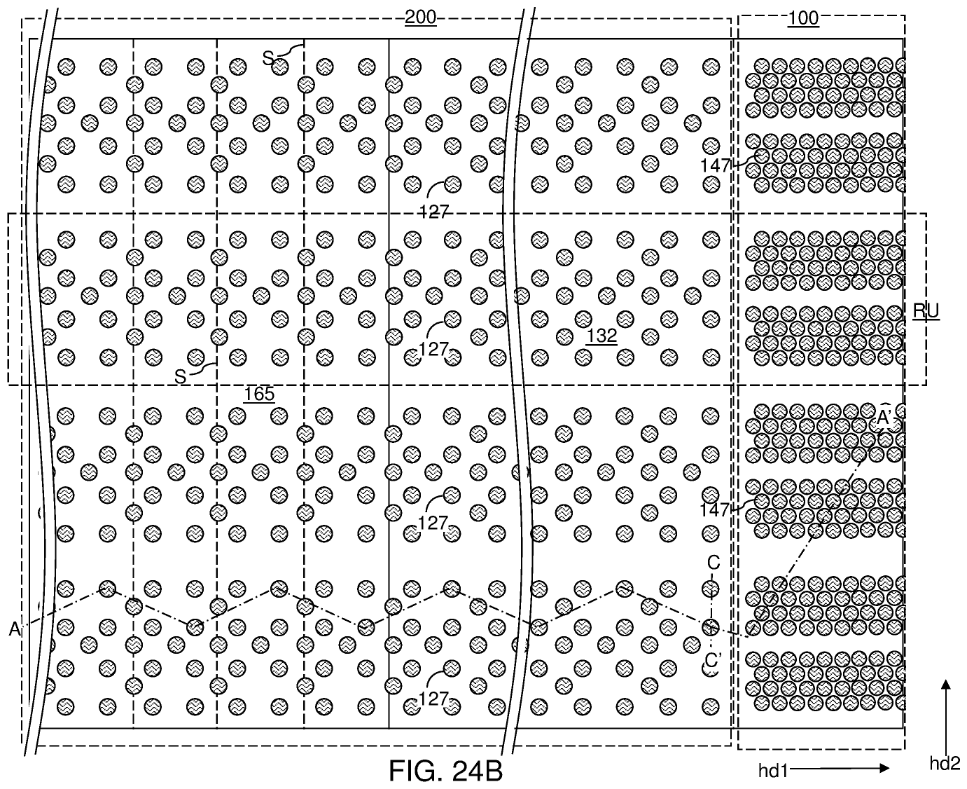

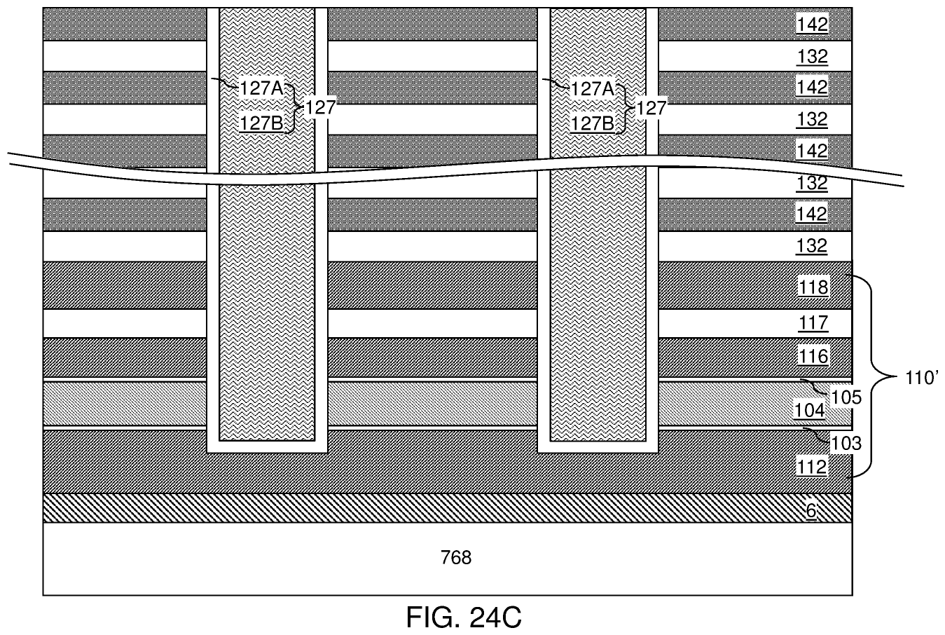

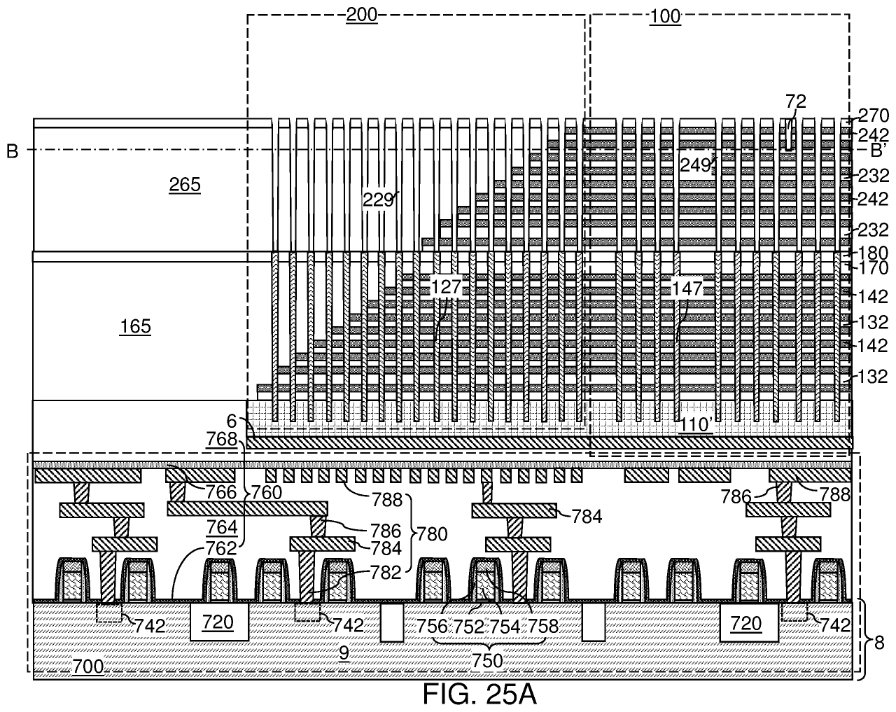

Referring to FIGS. 24A-24C, a second exemplary structure according to a second embodiment of the present disclosure may be derived from the first exemplary structure illustrated in FIGS. 4A-4C by omitting the processing steps described with reference to FIGS. 5A and 5B, 6, and 7A-7C, and by performing the processing steps described with reference to FIGS. 8A and 8B. In this case, each of the first-tier support openings 129 can be filled with a first-tier support opening fill portion 127. In other words, each of the dielectric support pillars 120 in the first exemplary structure may be replaced with a respective first-tier support opening fill portion 127 in the second exemplary structure.

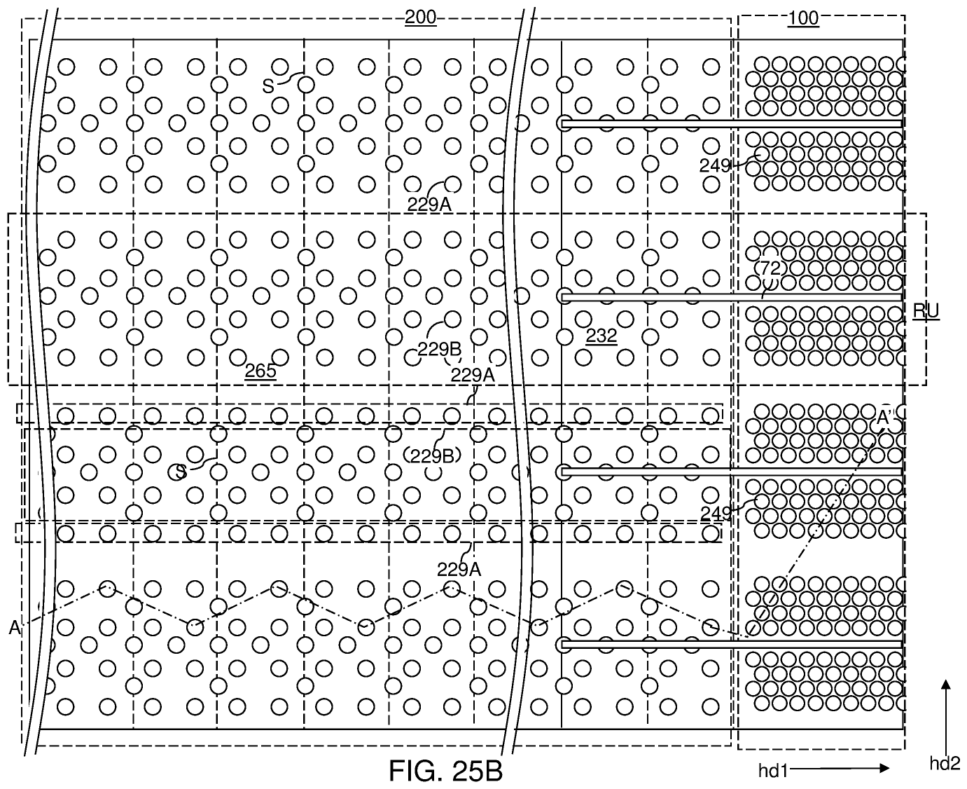

Referring to FIGS. 25A and 25B, the processing steps described with reference to FIG. 9 can be performed to form a second-tier alternating stack of second insulating layers 232 and second sacrificial material layers 242, a second retro-stepped dielectric material portion 265, a second insulating cap layer 270, and drain-select-level isolation structures 72.

The processing steps described with reference to FIGS. 10A and 10B can be subsequently performed to form second-tier memory openings 249 and second-tier support openings 229. The second-tier memory openings 249 are formed directly on a top surface of a respective one of the sacrificial first-tier memory opening fill portions 147. Each of the second-tier support openings 229 can be formed directly on a top surface of a respective one of the sacrificial first-tier support opening fill portions 127. The second-tier support openings 229 may comprise a first subset 229A of the second-tier support openings 229 and a second subset 229B of the second-tier support openings 229. The first subset 229A of the second-tier support openings 229 may be arranged with the same pattern as in the first exemplary structure. The second subset 229B of the second-tier support openings 229 may be arranged with the same pattern as in the first exemplary structure. A predominant fraction and/or each of the second-tier support openings 229 may be formed through a horizontal surface within the second stepped surfaces, which include the interfacial surfaces between the second-tier alternating stack (232, 242) and the second retro-stepped dielectric material portion 265. Locations of steps S in the first-tier alternating stack (132, 142) and the second-tier alternating stack (232, 242) are illustrated as dotted lines in FIG. 25B.

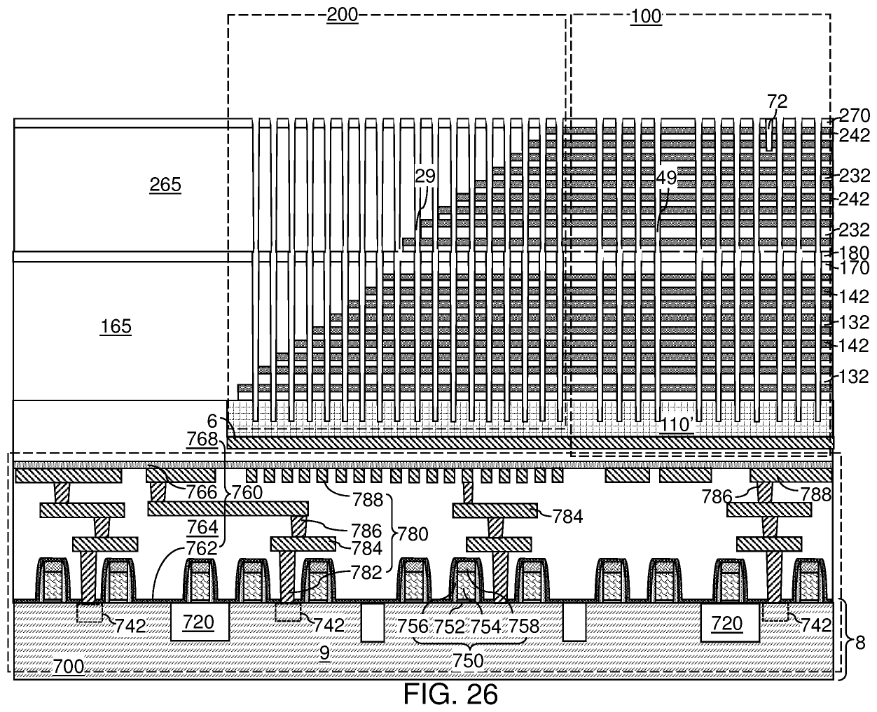

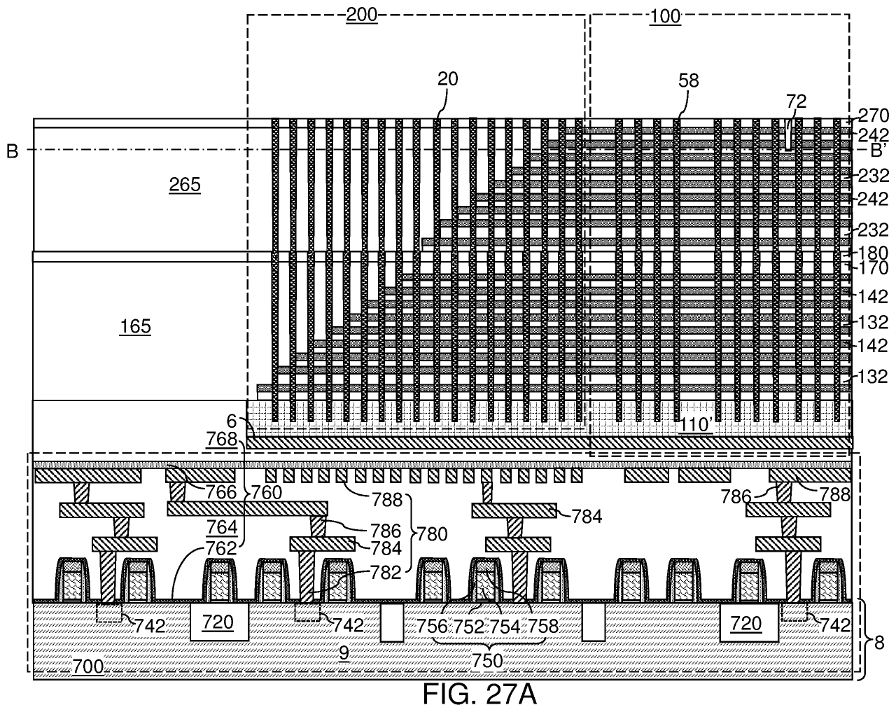

Referring to FIG. 26, the sacrificial first-tier fill material of the sacrificial first-tier opening fill portions (147, 127) may be removed using a selective removal process (e.g., ashing or selective etching) that removes the sacrificial first-tier fill material selective to the materials of the first and second insulating layers (132, 232), the first and second sacrificial material layers (142, 242), the first and second insulating cap layers (170, 270), the inter-tier dielectric layer 180. A memory opening 49, which is also referred to as an inter-tier memory opening 49, is formed in each contiguous combination of second-tier memory openings 249 and a volume of the first-tier memory openings 149 from which a sacrificial first-tier memory opening fill portion 147 is removed. A support opening 29, which is also referred to as an inter-tier support opening 29, is formed in each contiguous combination of second-tier support openings 229 and a volume first-tier support openings 129 from which a sacrificial first-tier support opening fill portion 127 is removed.

Therefore, each of the inter-tier memory openings 49 vertically extends through each layer within the first-tier alternating stack (132, 142) and the second-tier alternating stack (232, 242). Each of the inter-tier support openings 29 vertically extends through at least a subset of layers within the first-tier alternating stack (132, 142), and may vertically extend through at least the second retro-stepped dielectric material portion 265. Each of the inter-tier memory openings 49 and the inter-tier support openings 29 vertically extends from the horizontal plane including the top surface of the second insulating cap layer 270 into the in-process source-level material layers 110′.

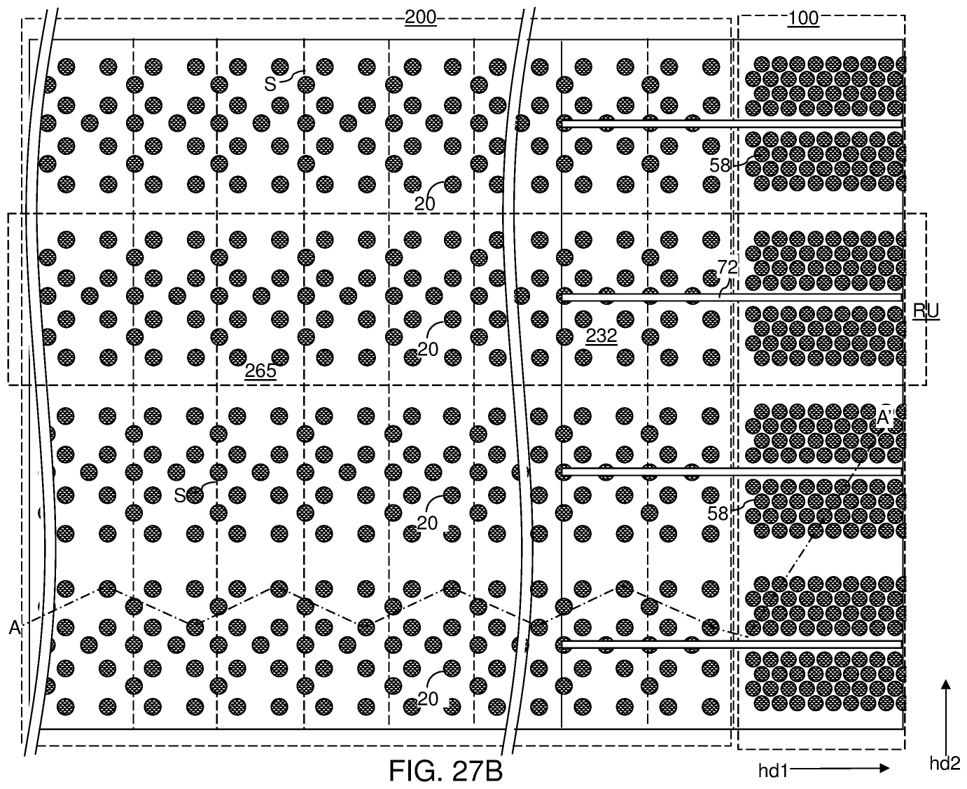

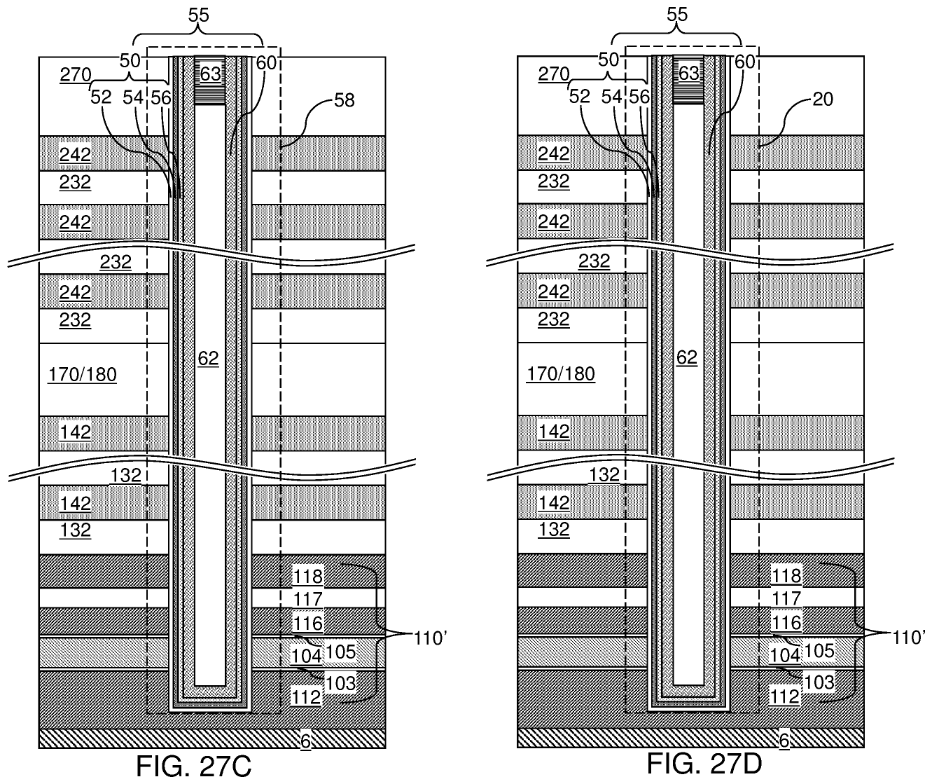

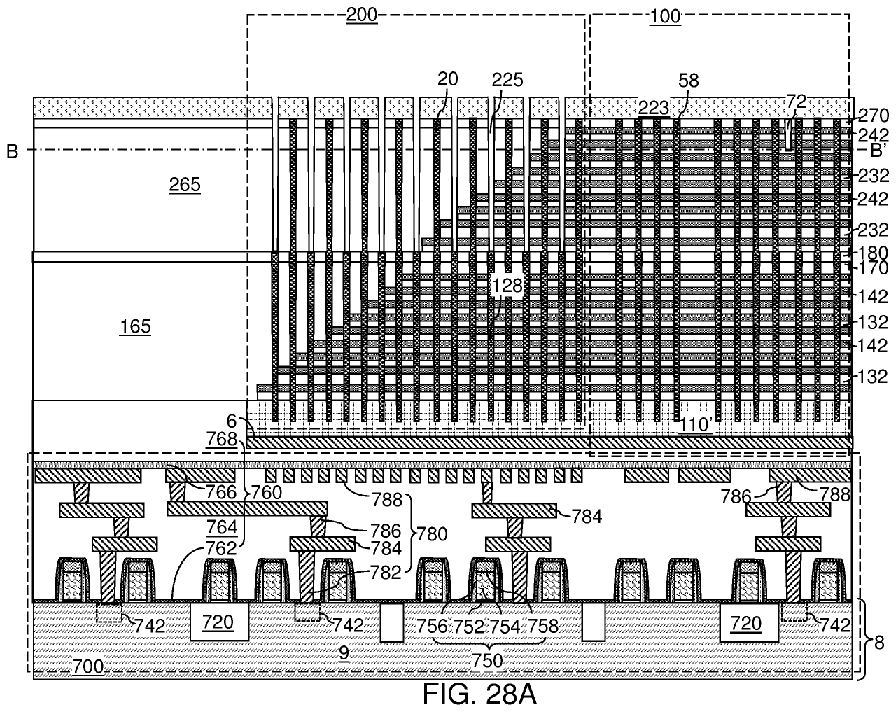

Referring to FIGS. 27A-27D, the processing steps described with reference to FIGS. 12A-12D can be performed to form a memory opening fill structure 58 in each inter-tier memory opening 49, and to form a support pillar structure 20 in each inter-tier support opening 20. Generally, memory opening fill structures 58 and support pillar structures 20 can be formed in the inter-tier memory openings 49 and in the inter-tier support openings 29, respectively, by depositing and patterning at least a memory material and a semiconductor material in each of the inter-tier memory openings 49 and the inter-tier support openings 29. Each of the memory opening fill structures 58 and the support pillar structures 20 comprises a respective vertical stack of memory elements comprising portions of the memory material (e.g., portions of the memory film 50) and a respective vertical semiconductor channel 60 comprising a portion of the semiconductor material.

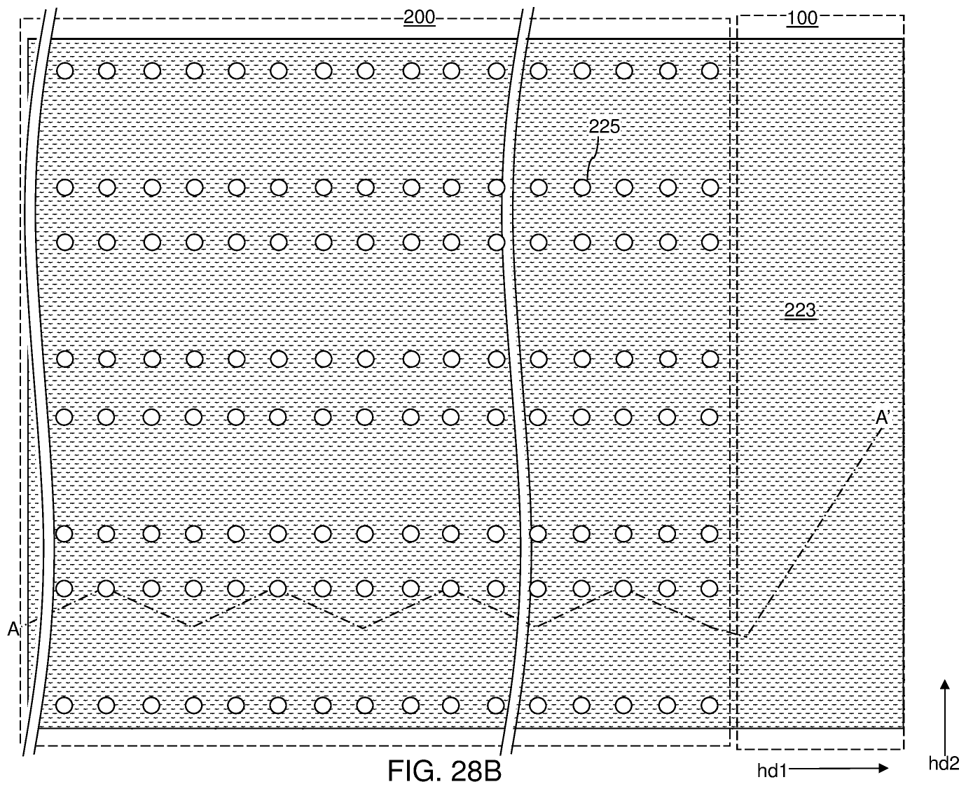

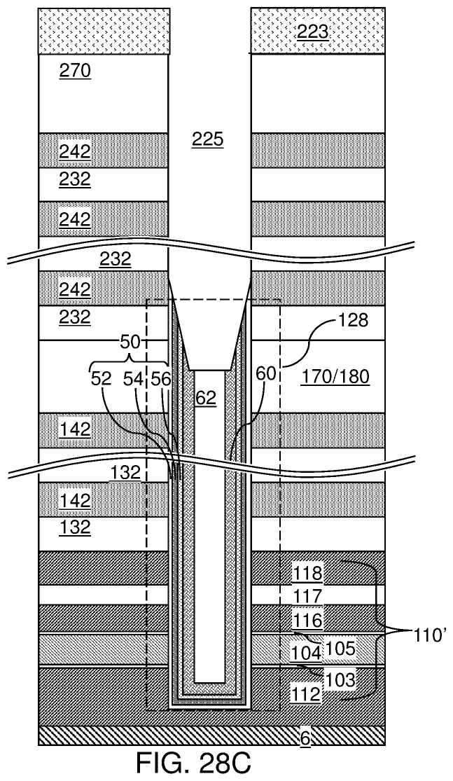

Referring to FIGS. 28A and 28B, a patterned etch mask layer 223 can be formed over the second dielectric cap layer 270, and can be patterned to form openings therethrough. For example, the patterned etch mask layer 223 may comprise a photoresist layer that can be patterned by lithographic exposure and development and/or a patterned hard mask. Openings in the patterned etch mask layer 223 overlie a first subset of the support pillar structures 20. The pattern of the openings in the patterned etch mask layer 223 may be the same as the pattern of the first subset 229A of the second-tier support openings 229 as provided at the processing steps of FIGS. 25A and 25B.

An anisotropic etch process may be performed to remove upper portions of the first subset of the support pillar structures 20 that are not covered by the photoresist layer. The anisotropic etch process may have an etch chemistry that etches the various materials in the support pillar structures 20 non-selectively, or may comprises a series of etch steps having different etch chemistries for etching various components of the support pillar structures 20. In an illustrative example, the anisotropic etch process may comprise a first etch step for etching the material of the drain regions 63, a second etch step for etching the material of the dielectric cores 62 and collaterally etching the memory films 50, and a third etch step for etching the materials of the memory films 50 and collaterally etching the material of the dielectric cores 62. The anisotropic etch process is performed while the patterned etch mask layer 223 is present over the second-tier alternating stack (232, 242) and is employed as an etch mask layer.

Cavities 225 are formed in each volume from which the materials of upper portions of the first subset of the support pillar structures 20 are removed. Remaining portions of the first subset of the support pillar structures 20 constitute a composite support pillar 128. Each composite support pillar 128 may comprise a respective memory film 50, a respective vertical semiconductor channel 60, and a respective dielectric core 62. The top surface of one, a plurality or each of the composite pillar structures 128 may be contoured, i.e., non-planar. In some embodiments, the center portion of the top surface of one, a plurality or each of the composite pillar structures 128 may be recessed relative to the peripheral portion of the top surface. The top surface of one, a plurality or each of the composite pillar structures 128 may intersect, may formed entirely or partly above, and/or may be formed entirely or partly below, the horizontal plane including the top surface of the inter-tier dielectric layer 180 and the bottom surface of the second-tier alternating stack (232, 242). The patterned etch mask layer 223 can be subsequently removed, for example, by ashing.

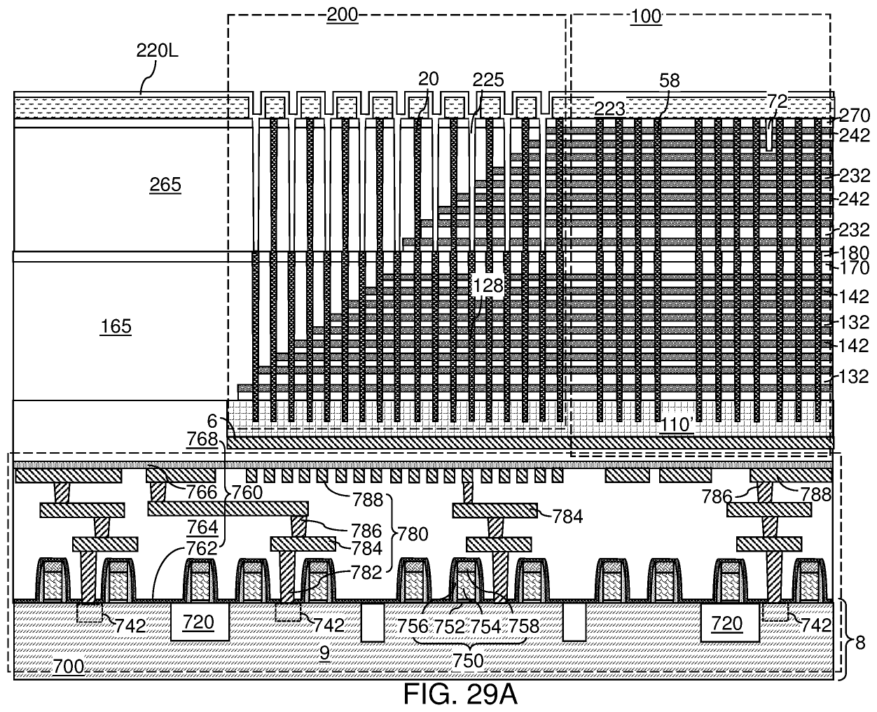

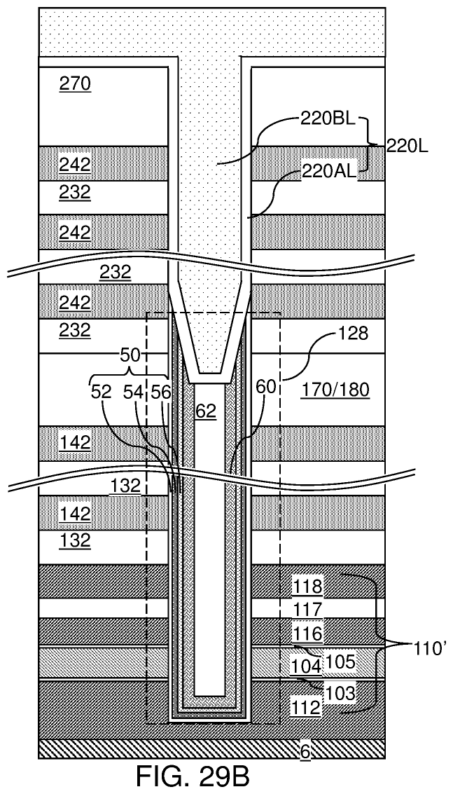

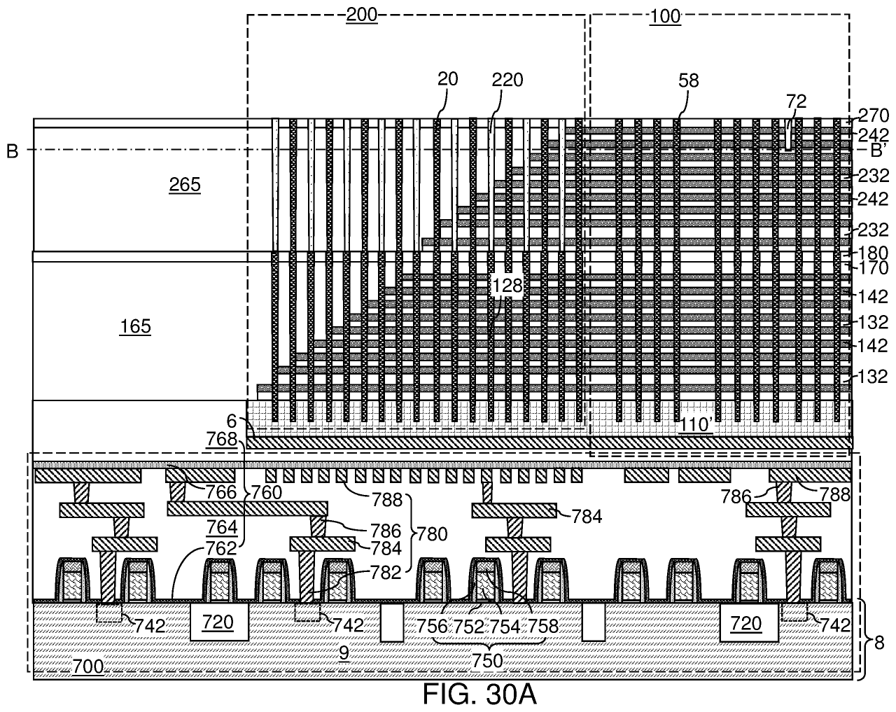

Referring to FIGS. 29A and 29B, at least one dielectric fill material layer 220L can be conformally deposited in the cavities 225 and over the second insulating cap layer 270. In one embodiment, the at least one dielectric fill material layer 220L may comprise a dielectric liner layer 220AL and a dielectric fill material layer 220BL. In an illustrative example, the dielectric liner layer 220AL may comprise a low-temperature oxide (LTO) layer, and the dielectric fill material layer 220BL may comprise a silicate glass fill material layer.

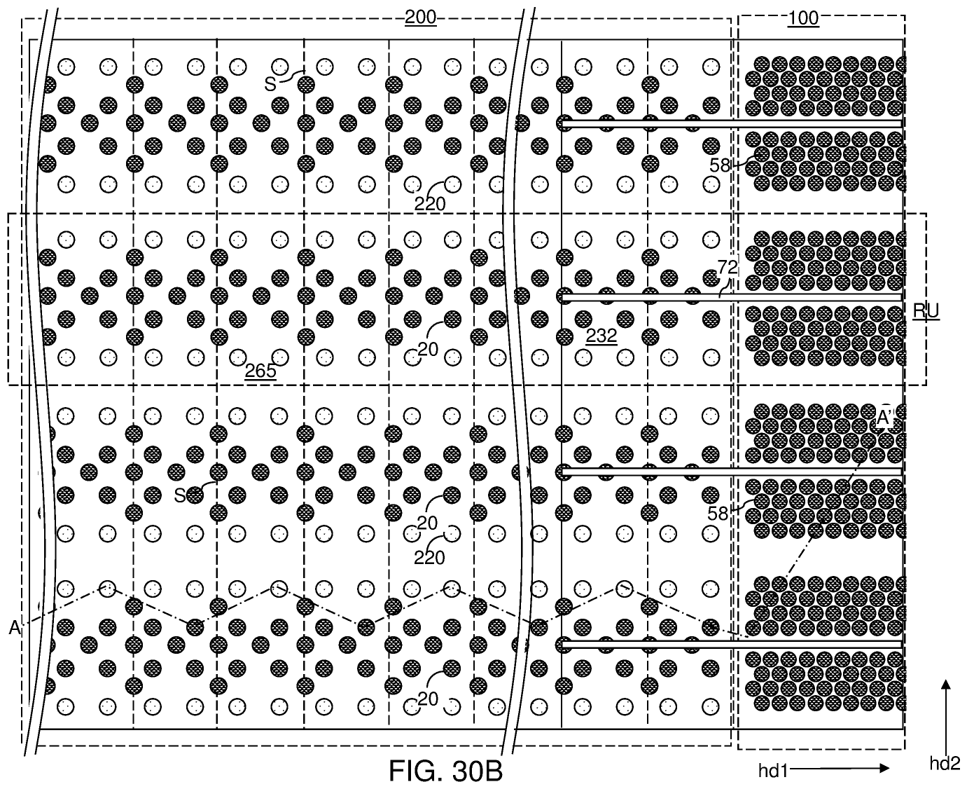

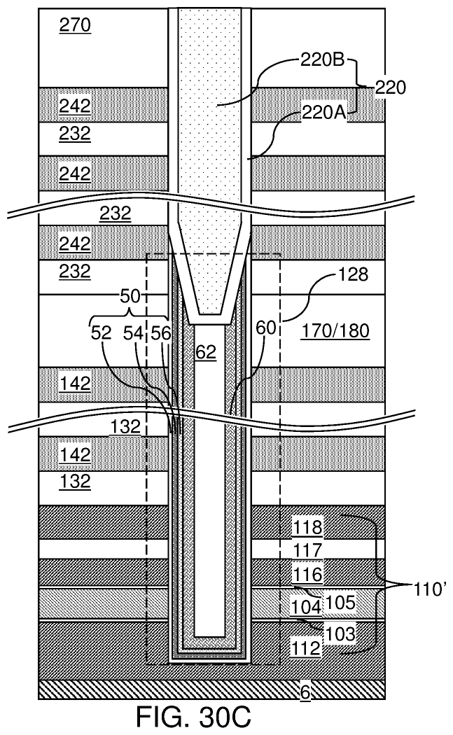

Referring to FIGS. 30A-30C, the at least one dielectric fill material layer 220L can be isotropically recessed, for example, by performing an isotropic etch process. Portions of the at least one dielectric fill material layer 220L that overlies the second insulating cap layer 270 can be removed by the isotropic etch process. Each remaining portion of the at least one dielectric fill material layer 220L constitutes a dielectric support pillar 220. If the at least one dielectric fill material layer 220L includes a dielectric liner material and a dielectric fill material, each of the dielectric support pillars 220 may comprise a dielectric liner 220A and a dielectric fill material portion 220B. In an illustrative example, the dielectric liner 220A may comprise a low-temperature oxide (LTO) material (which is a silicon oxide material formed at a low temperature), and the dielectric fill material portion 220B may comprise undoped silicate glass or a doped silicate glass. Optionally, a suitable reflow process may be performed as needed. Each cavity 225 can be filled with a respective dielectric support pillar 220. Each vertical stack of a composite support pillar 128 and a dielectric support pillar 220 constitutes a hybrid support structure (128, 220).

In the second exemplary structure, an upper portion of each support pillar structure 20 in a first subset of the support pillar structures 20 can be replaced with a respective dielectric support pillar 220. Each remaining portion of the first subset of the support pillar structures 20 comprises a composite support pillar 128 including a respective remaining portion of a memory material (such as a remaining portion of a memory material layer 54 of the memory film 50) and a respective remaining portion of the semiconductor material (such as a remaining portion of a vertical semiconductor channel 60). Each vertical stack of a composite support pillar 128 and a dielectric support pillar 220 constitutes a hybrid support structure (128, 220). The dielectric support pillar 220 overlies the composite support pillar 128 within each of the hybrid support structures (128, 220).

In one embodiment, one, a plurality or each of the dielectric support pillars 220 may have a respective contoured bottom surface having a vertical extent that is greater than a thickness of a bottommost layer within the second-tier alternating stack (232, 242). A second subset of the support pillar structures 20 may not be modified during replacement of the first subset of the support pillar structures 20 with the hybrid support structures (128, 220). Each support pillar structures 20 in the second subset of the support pillar structures 20 vertically extends through at least a bottommost layer within the first-tier alternating stack (132, 142), and may have the same height as the memory opening fill structures 58.

The memory opening fill structures 58 can be located in the memory openings 49. Each of the memory opening fill structures 58 comprises a respective vertical stack of memory elements and a respective vertical semiconductor channel 60 including a respective portion of a semiconductor material. The hybrid support structures (128, 220) vertically extend at least through a respective subset of layers within the first-tier alternating stack (132, 142). Each of the hybrid support structures (128, 220) comprises a respective vertical stack of a dielectric support pillar 220 and a composite support pillar 128 having a respective dielectric outer surface (such as an outer sidewall of a blocking dielectric layer 52) and including a respective additional portion of the semiconductor material.

In one embodiment, a subset of the hybrid support structures (128, 220) vertically extends through each layer within the first-tier alternating stack (132, 142) and the second-tier alternating stack (232, 242).

In one embodiment, the second exemplary structure may comprise a first stepped dielectric material portion 165 overlying first stepped surfaces of the first-tier alternating stack (132, 142); and a second stepped dielectric material portion 265 overlying second stepped surfaces of the second-tier alternating stack (232, 242). A first subset of the hybrid support structures (128, 220) vertically extends through each layer within the first-tier alternating stack (132, 142), a respective subset of layers within the second-tier alternating stack (232, 242), and the second retro-stepped dielectric material portion 265. In one embodiment, a second subset of the hybrid support structures (128, 220) vertically extends through the first stepped dielectric material portion 165 and the second stepped dielectric material portion 265 and does not extend through the second-tier alternating stack (232, 242).

In one embodiment, each vertical stack of memory elements comprises portions of a memory material (e.g., the material of the memory material layer 54 of the memory film 50); and each composite support pillar 128 includes a respective additional portion of the memory material. In one embodiment, each of the memory opening fill structures 58 comprises a respective blocking dielectric layer 52 laterally surrounding the respective vertical stack of memory elements; and each of the composite support pillars 128 comprises a respective blocking dielectric layer 52 laterally having a same material composition as the blocking dielectric layers 52 in the memory opening fill structures 58.

In one embodiment, each of the memory opening fill structures 58 comprises a respective dielectric core 62 comprising a respective portion of a dielectric fill material; and each of the composite support pillars 128 comprises a respective dielectric core 62 comprising a respective additional portion of the dielectric fill material. In one embodiment, each additional portion of the semiconductor material in the composite support pillars 128 has a lesser vertical extent than the vertical semiconductor channels 60 in the memory opening fill structures 58. In one embodiment, the memory opening fill structures 58 and the hybrid support structures (128, 220) have a same height.

In one embodiment, the dielectric support pillar 220 overlies the composite support pillar 128 within each of the hybrid support structures (128, 220). In one embodiment, the dielectric support pillars 220 have contoured bottom surfaces having a vertical extent that is greater than a thickness of a bottommost layer within the second-tier alternating stack (232, 242). In one embodiment, support pillar structures 20 (i.e., the second subset of the support pillar structures 20 as formed at the processing steps of FIGS. 27A-27D) vertically extending through at least a bottommost layer within the first-tier alternating stack (132, 142) and having a same height as the memory opening fill structures 58.

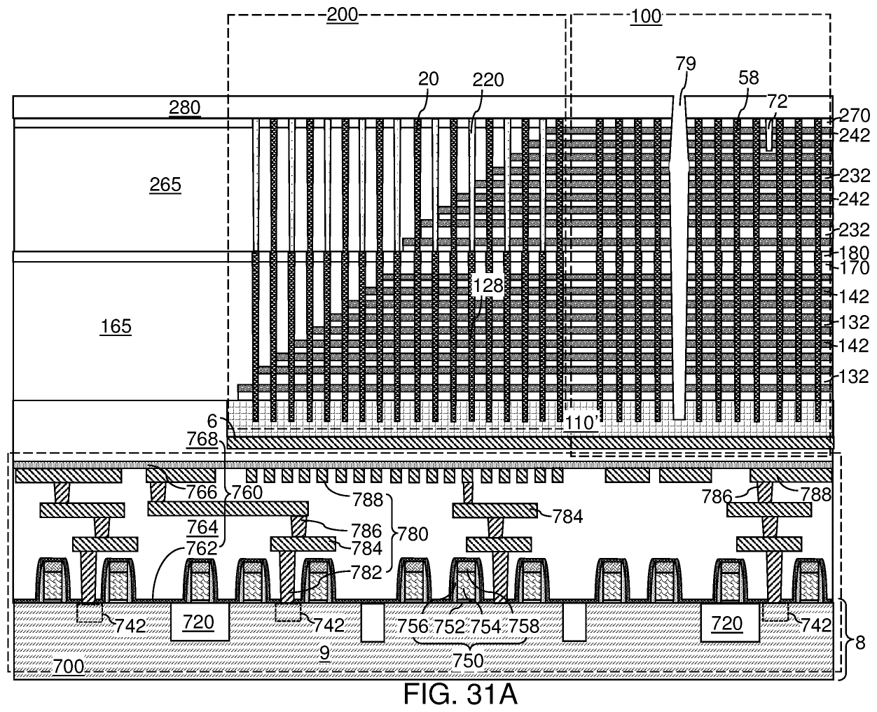

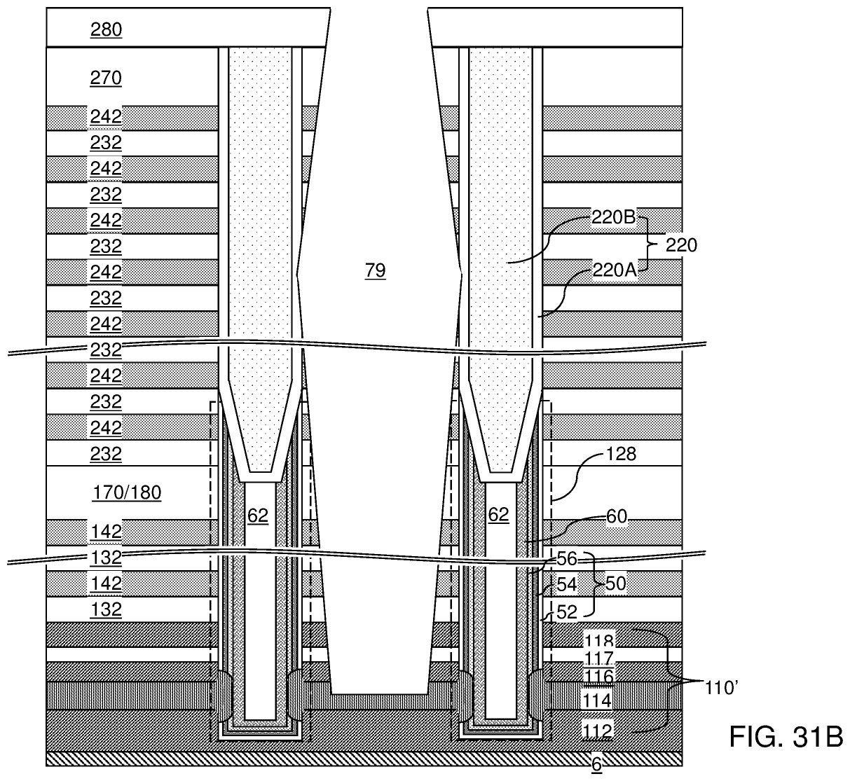

Referring to FIGS. 31A and 31B, the processing steps described with reference to FIGS. 15A-15C can be performed to form a first contact-level dielectric layer 280 and backside trenches 79.

In an embodiment shown in FIG. 31B, the vertical cross-sectional profile of one, a plurality or each of the backside trenches 79 along vertical planes that are parallel to the second horizontal direction hd2 may have a bulging profile in which the widest portion of the respective backside trench 79 is located within the second-tier alternating stack (232, 242). In this case, the dielectric support pillar 220 may be physically exposed in the upper portion of the backside trench 79. In this case, since the dielectric support pillar structure 220 comprises only a dielectric material, such as silicon oxide (which is the same as the material of the insulating layers 232), the dielectric pillar structure 220 is not removed during the subsequent selective etching step during which the sacrificial material layers 242 are removed. In contrast, if the upper portion of the support pillar structure 20 was exposed in the backside trench 79, then the silicon nitride memory material layer 54 may be removed together with the silicon nitride sacrificial material layers and replaced with a metal layer during formation of the word lines and select gate electrodes. This may cause a short circuit between vertically separated word lines and/or select gate electrodes. Thus, the dielectric pillar structures 220 located in the hybrid support structures (220, 128) adjacent to the backside trenches 79 reduce the likelihood of a short circuit. In contrast, the silicon containing composite support pillars 128 have a higher structural strength than the dielectric pillar structures 220, and thus increase the strength of the hybrid support structures (220, 128). Furthermore, the silicon containing support pillar structure 20 also have a higher structural strength than the dielectric pillar structures 220 and are located farther from the backside trenches 79 than the hybrid support structures (220, 128). Thus, the support pillar structures 20 provide improved structural strength without increasing the likelihood of a short circuit because the support pillar structures 20 are not exposed in the backside trenches 79.

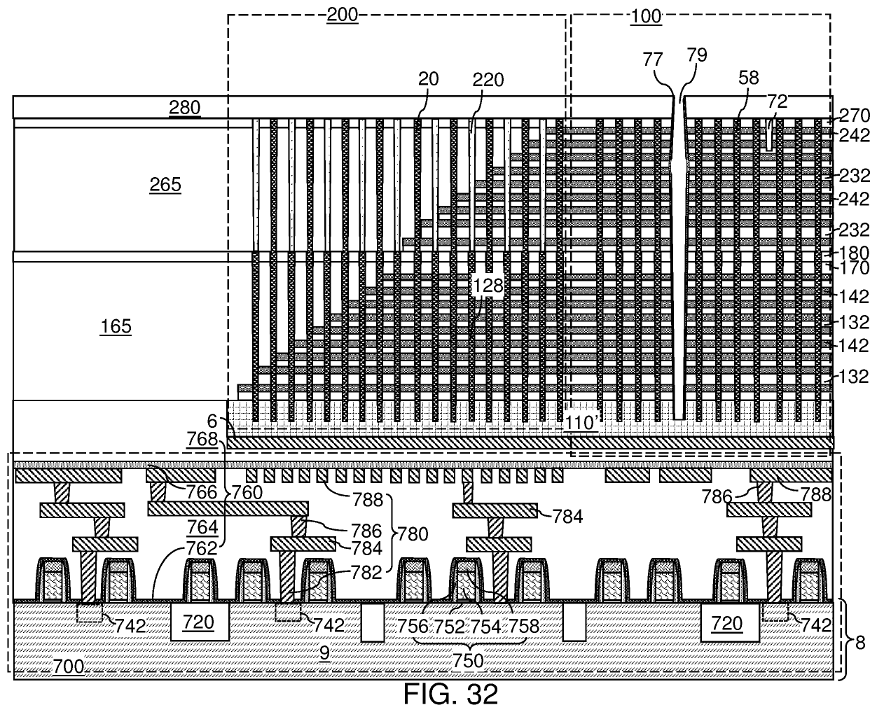

Referring to FIG. 32, the processing steps described with reference to FIGS. 16 and 17A can be performed to form backside trench spacers 77.

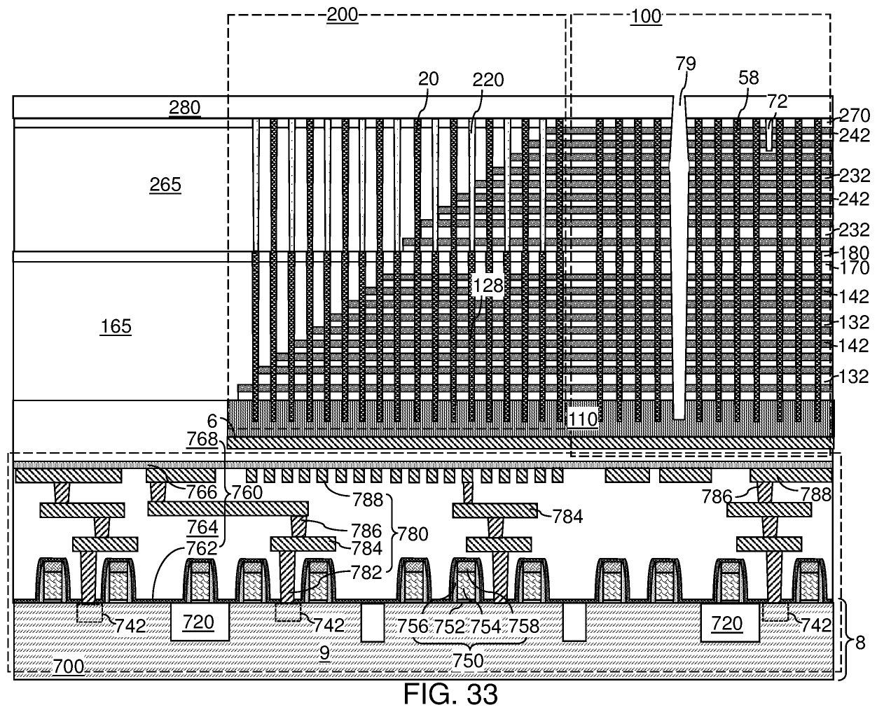

Referring to FIG. 33, the processing steps described with reference to FIGS. 17B-17E and 18 can be performed to replace the in-process source-level material layers 110′ with source-level material layers 110.

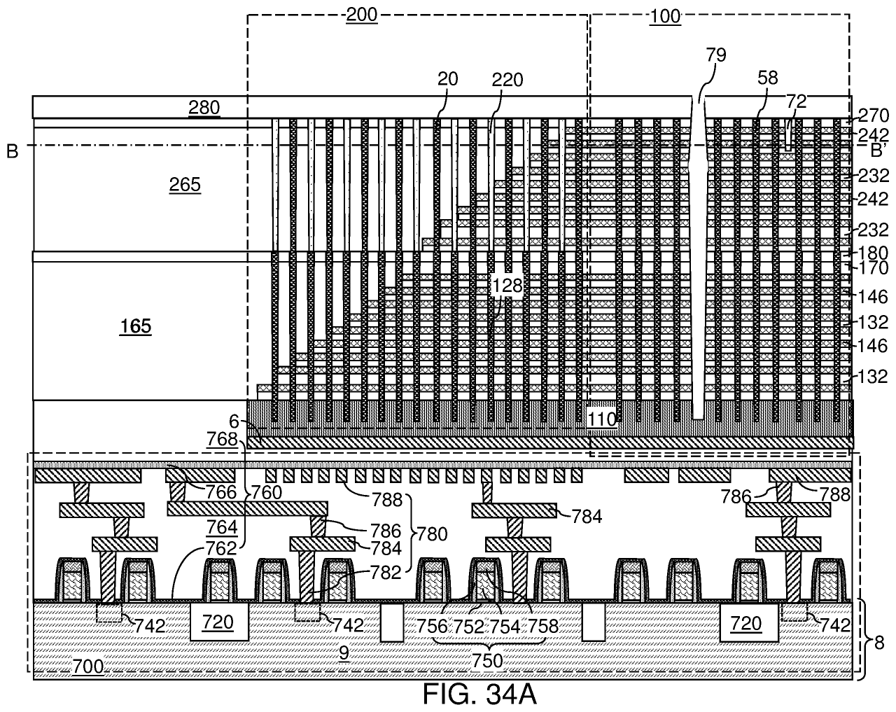

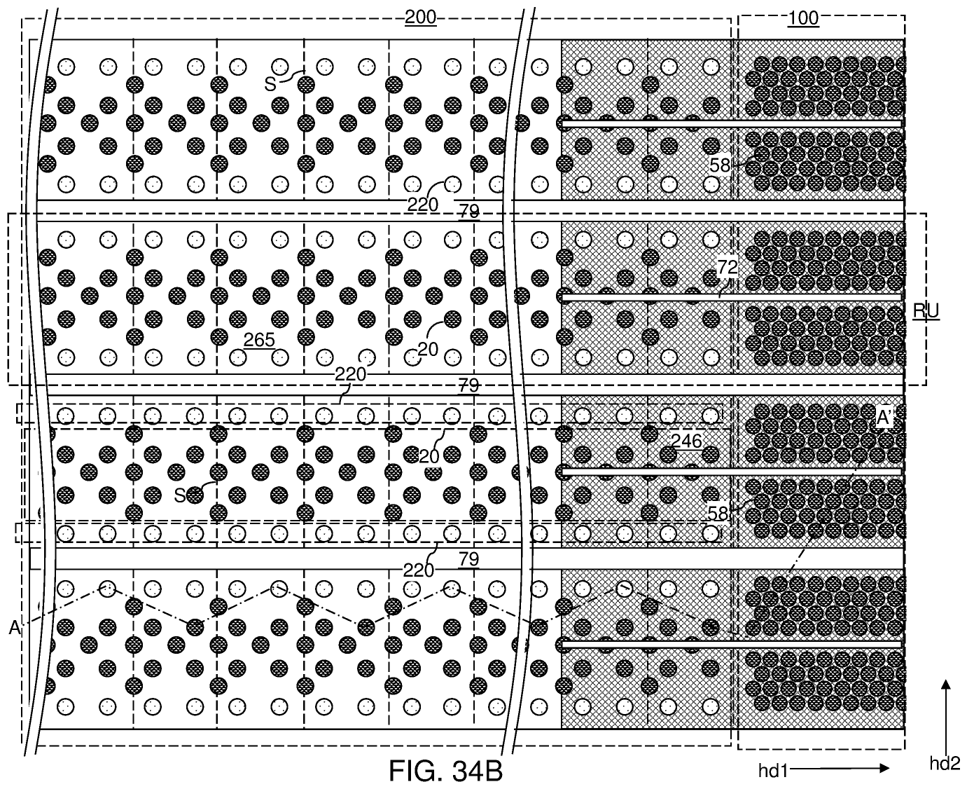

Referring to FIGS. 34A and 34B, the processing steps described with reference to FIGS. 19, 20A, and 20B can be performed to replace the sacrificial material layers (142, 242) with electrically conductive layers (146, 246). The first sacrificial material layers 142 and the second sacrificial material layers 242 can be replaced with first electrically conductive layers 146 and second electrically conductive layers 246, respectively. A backside blocking dielectric layer (not shown) may be formed in each backside recess (143, 243) prior to formation of the electrically conductive layers (146, 246).

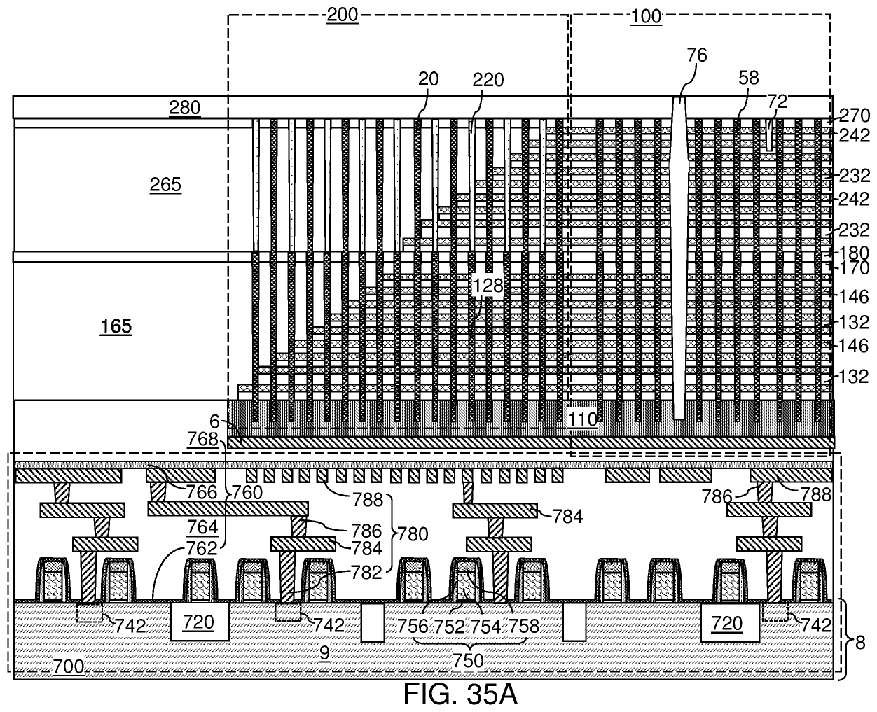

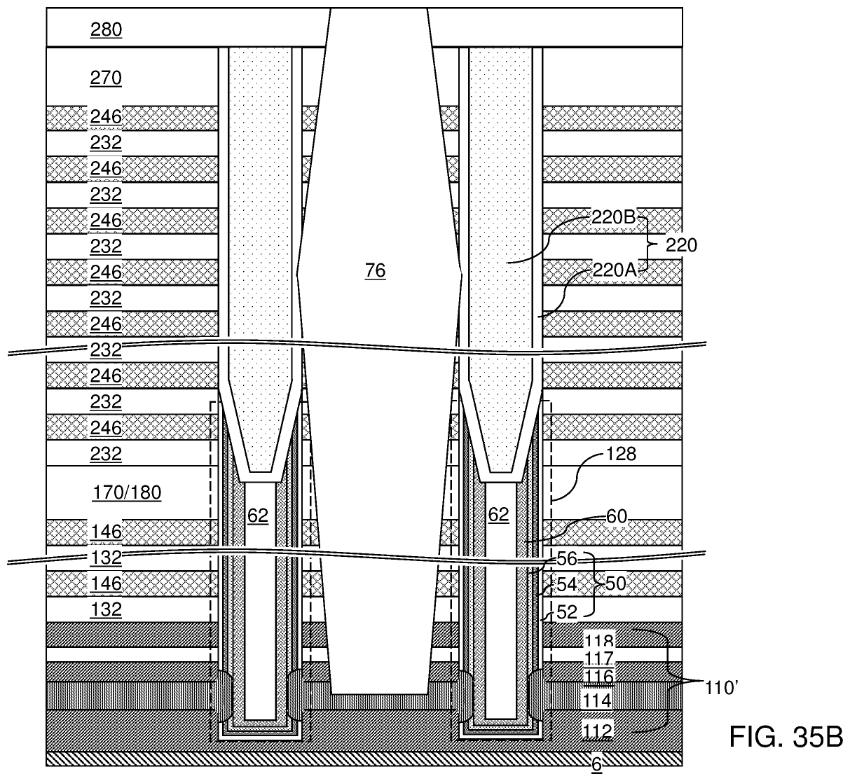

Referring to FIGS. 35A and 35B, the processing steps described with reference to FIGS. 21A and 21B can be performed to form backside trench fill structures 76 and a first contact-level dielectric layer 280.

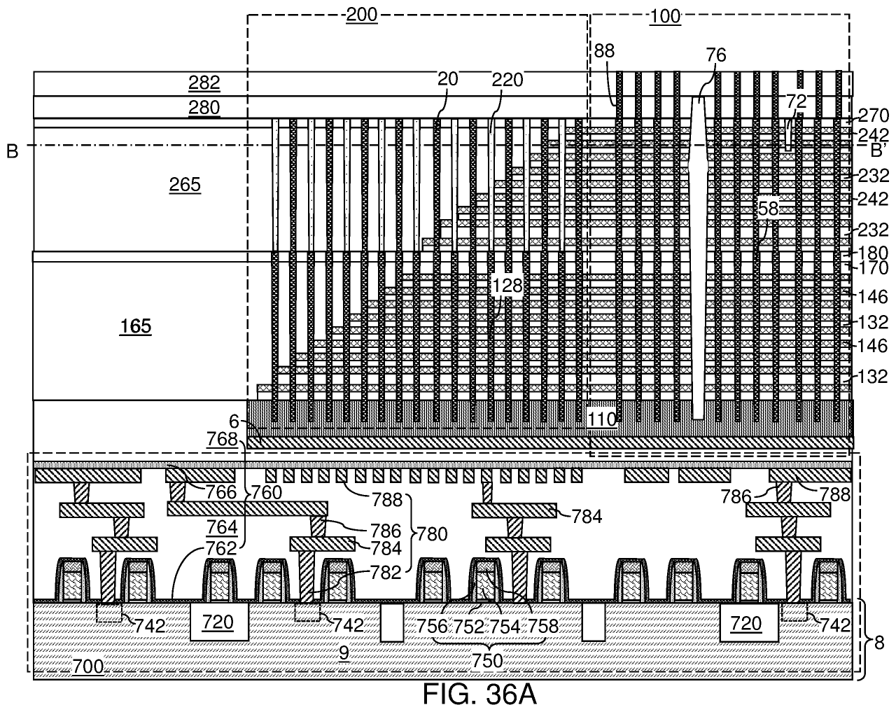

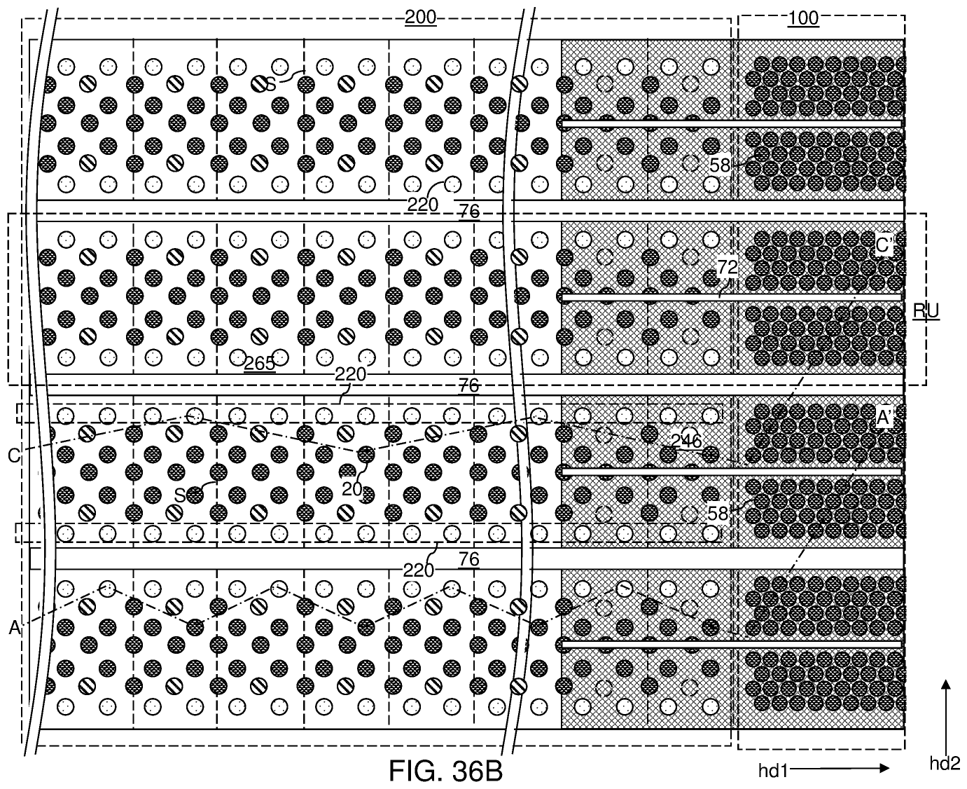

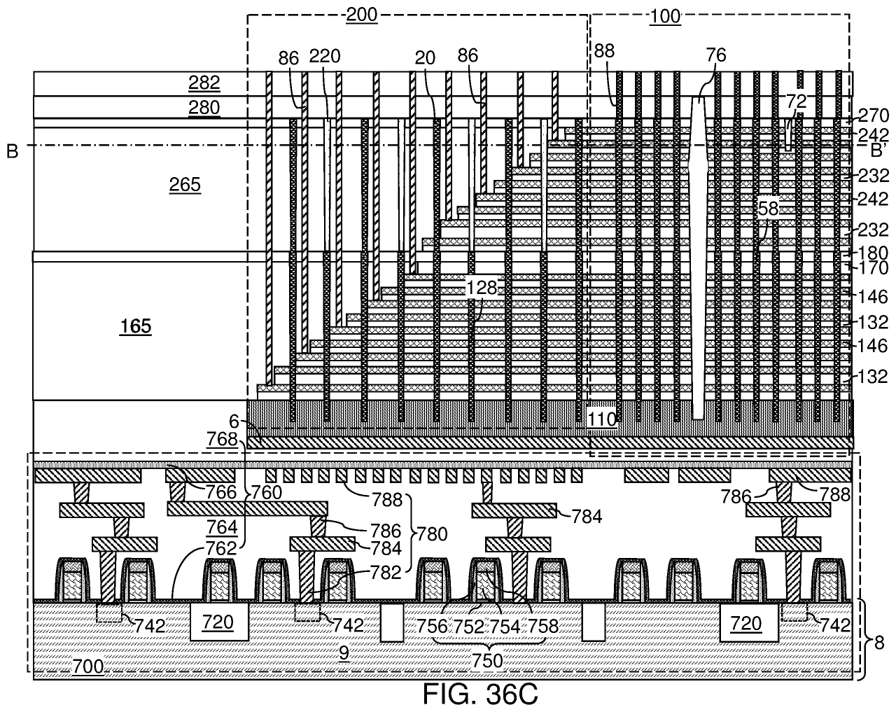

Referring to FIGS. 36A-36C, the processing steps described with reference to FIGS. 22A-22C can be performed to form various contact via structures (88, 86).

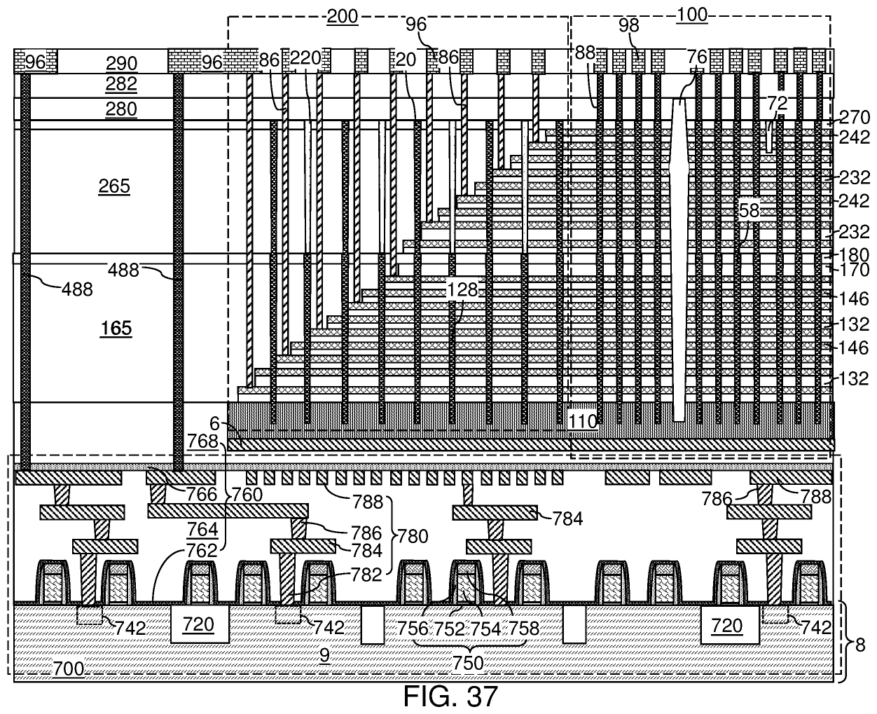

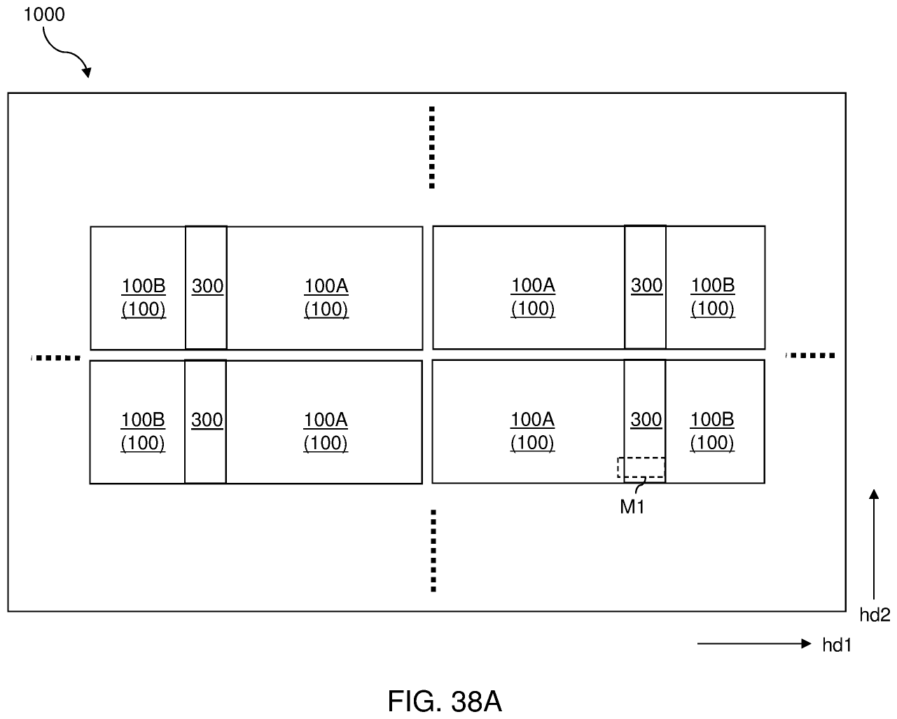

Referring to FIG. 37, the processing steps described with reference to FIG. 23 can be performed to form through-memory-level contact via structures 488, at least one additional dielectric layer, and additional metal interconnect structures.

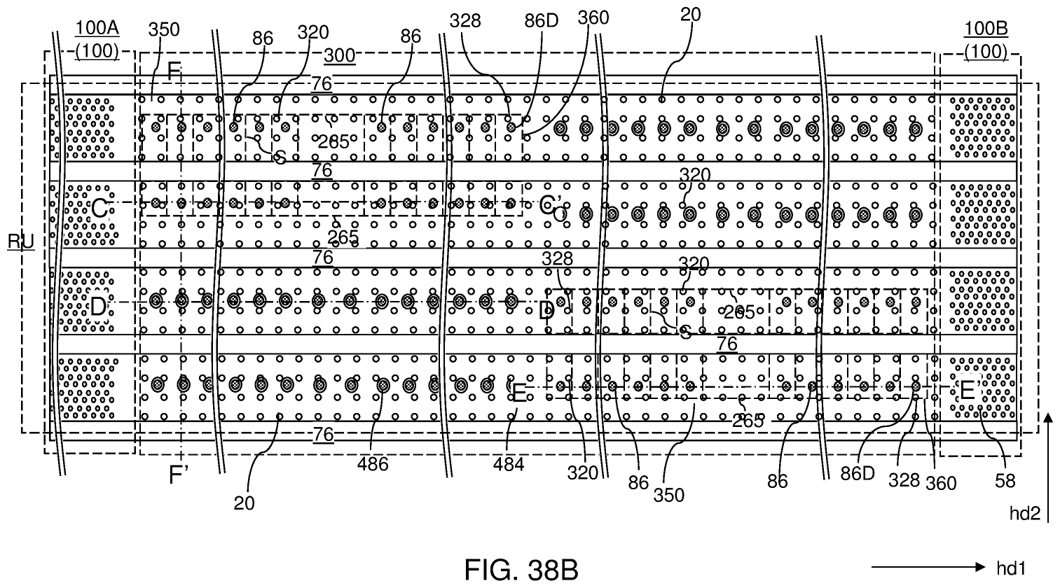

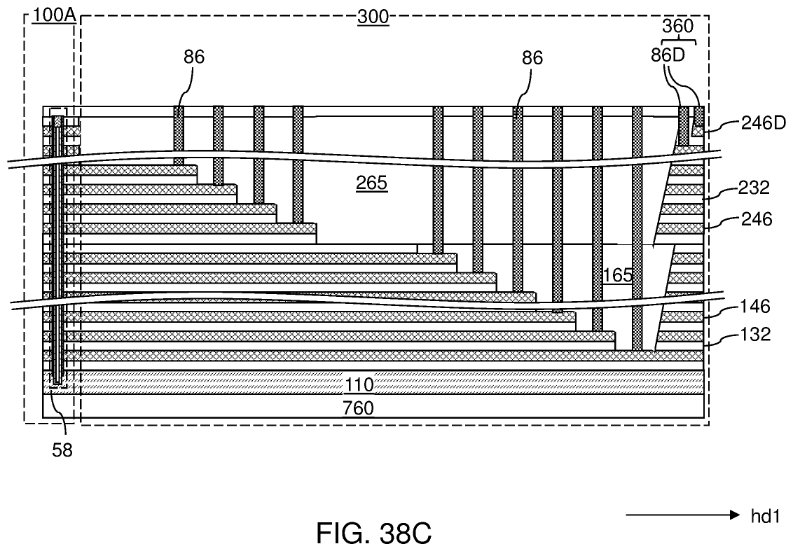

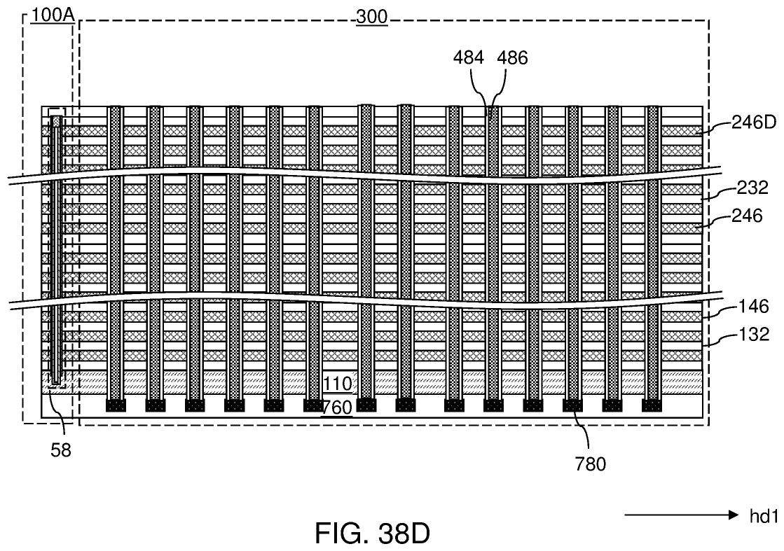

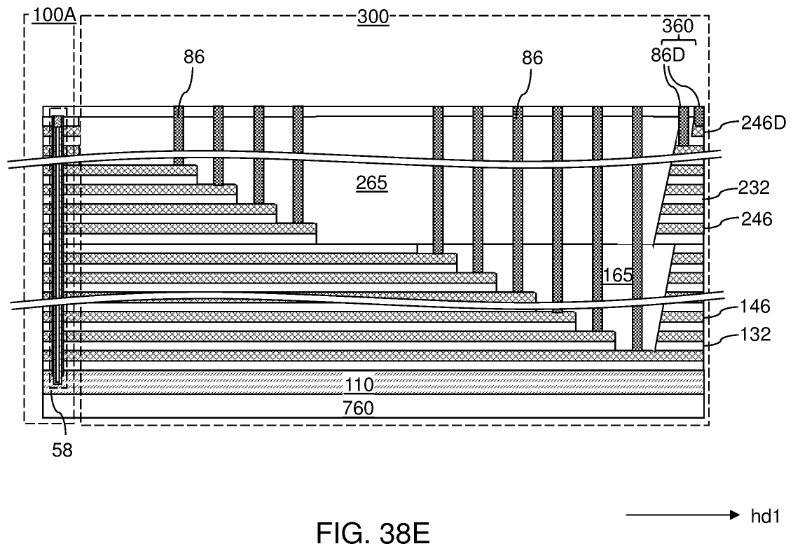

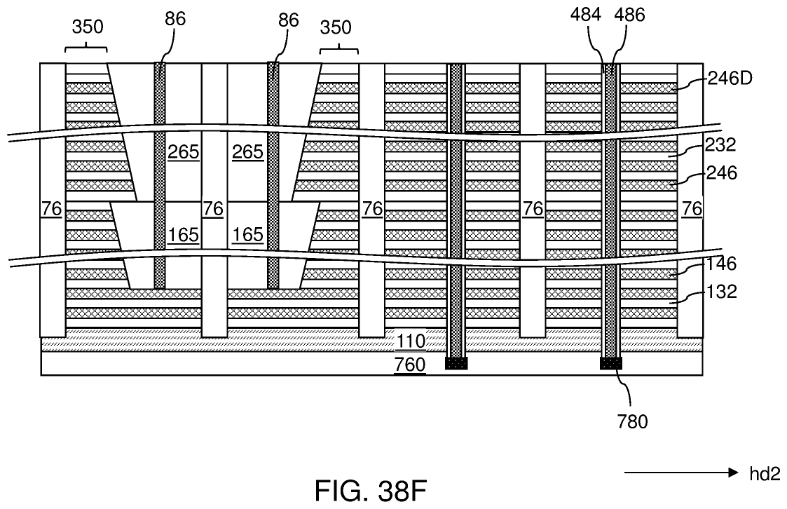

Referring to FIGS. 38A-38F, a third exemplary structure according to a third embodiment of the present disclosure is illustrated, which comprises a semiconductor die 1000. The semiconductor die 1000 includes multiple three-dimensional memory array regions and multiple inter-array regions. The semiconductor die 1000 can include multiple planes, each of which includes two memory array regions 100, such as a first memory array region 100A and a second memory array region 100B that are laterally spaced apart by a respective inter-array region 300 which contains the above described staircase region. Generally, a semiconductor die 1000 may include a single plane or multiple planes. The total number of planes in the semiconductor die 1000 may be selected based on performance requirements on the semiconductor die 1000. A pair of memory array regions 100 in a plane may be laterally spaced apart along a first horizontal direction hd1 (which may be the word line direction). A second horizontal direction hd2 (which may be the bit line direction) can be perpendicular to the first horizontal direction hd1.

Each memory array region 100 includes first-tier alternating stacks of first insulating layers 132 and first electrically conductive layers 146 (which function as first word lines and select gate electrodes) and second-tier alternating stacks of second insulating layers 232 and second electrically conductive layers 246 (which function as second word lines and select gate electrodes). Each second-tier alternating stack (232, 246) overlies a respective first-tier alternating stack (132, 146), and each first-tier alternating stack (132, 146) underlies a respective second-tier alternating stack (232, 246). Each combination of a first-tier alternating stack (132, 146) and an overlying second-tier alternating stack (232, 246) may be laterally spaced apart from neighboring combinations of a respective first-tier alternating stack (132, 146) and a respective second-tier alternating stack (232, 246) by the backside trench fill structures 76 that laterally extend along the first horizontal direction hd1.

The first exemplary structure can include an optional semiconductor material layer 110 that includes a single crystalline or polycrystalline semiconductor material, such as single crystalline silicon or polysilicon. In one embodiment, the semiconductor material layer 110 may be a substrate. Optionally, underlying dielectric material layers may be provided underneath the semiconductor material layer 110. In this case, the underlying dielectric material layers are referred to as lower-level dielectric material layers 760.

A first-tier alternating stack of first insulating layers 132 and first electrically conductive layers 146 is located over a substrate (which may include the semiconductor material layer 110 or another structure, such as a silicon wafer) that underlies the semiconductor material layer 110) between each neighboring pair of backside trench fill structures 76. A first-tier retro-stepped dielectric material portion 165 overlies, and contacts, first stepped surfaces of the first-tier alternating stack (132, 146). A second-tier alternating stack of second insulating layers 232 and second electrically conductive layers 246 overlies the first-tier alternating stack (132, 146), and overlies a horizontal plane including a planar top surface of the first-tier retro-stepped dielectric material portion 165 between each neighboring pair of backside trench fill structures 76. A second-tier retro-stepped dielectric material portion 265 overlies, and contacts, second stepped surfaces of the second-tier alternating stack (232, 246). Vertical steps S of the first stepped surfaces and the second stepped surfaces laterally extend along the second horizontal direction hd2 (e.g., bit line direction).

Memory opening fill structures 58 can be located within each memory array region 100 (which includes a first memory array region 100A and a second memory array region 100B) between each neighboring pair of backside trench fill structures 76. The memory opening fill structures 58 can be located within memory openings that vertically extend through each layer within the first-tier alternating stack (132, 146) and the second-tier alternating stack (232, 246) that are located between a respective neighboring pair of backside trench fill structures 76. Each of the memory opening fill structures 58 comprises a respective memory film and a respective vertical semiconductor channel, as will be described in more detail below.

Each memory opening fill structure 58 includes a respective memory stack structure, which includes a respective memory film and a respective vertical semiconductor channel. The memory openings and the memory opening fill structures 58 are formed in region in which each layer of a first-tier alternating stack and each layer of the second-tier alternating stack are present. For each area within which a continuous combination of a first-tier alternating stack (132, 146) and a second-tier alternating stack (232, 246) continuously laterally extends, first memory stack structures can be located within a respective first memory array region 100A and second memory stack structures can be located within a respective second memory array region 100B. The second memory array region 100B can be connected to the first memory array region 100A through a respective inter-array region 300, in which a first-tier retro-stepped dielectric material portion 165, a second-tier retro-stepped dielectric material portion 265, a backside trench fill structure 76, and a bridge region 350 are located.

A first-tier retro-stepped dielectric material portion 165 can be located between each neighboring pair of backside trench fill structures 76. Each first-tier retro-stepped dielectric material portion 165 overlies first stepped surfaces of a respective first-tier alternating stack (132, 146). Each first-tier retro-stepped dielectric material portion 165 can have a sidewall that laterally extends along the first horizontal direction hd1 and contacts a respective backside trench fill structure 76. The first stepped surfaces comprise vertical steps of the first-tier alternating stack (132, 146) that are laterally spaced apart along the first horizontal direction hd1 and vertically offset from each other.

A second-tier retro-stepped dielectric material portion 265 can be located between each neighboring pair of backside trench fill structures 76. Each second-tier retro-stepped dielectric material portion 265 overlies second stepped surfaces of a respective second-tier alternating stack (232, 246). Each second-tier retro-stepped dielectric material portion 265 can have a sidewall that laterally extends along the second horizontal direction hd1 and contacts a respective backside trench fill structure 76. The second stepped surfaces comprise vertical steps of the second-tier alternating stack (232, 246) that are laterally spaced apart along the first horizontal direction hd1 and vertically offset from each other. In one alternative embodiment, the second-tier retro-stepped dielectric material portion 265 does not contact the first-tier retro-stepped dielectric material portion 165 or the backside trench fill structure 76.

Backside trenches can laterally extend along the first horizontal direction hd1. Each backside trench can be filled with a backside trench fill structure 76, which may include a combination of a backside contact via structure and an insulating spacer that laterally surround the backside contact via structure. Alternatively, each backside trench fill structure 76 may consist of an insulating fill structure.

The bridge region 350 comprises a contiguous combination of a first-tier alternating stack (132, 146) and an overlying second-tier alternating stack (232, 246) the is located between backside trench fill structure 76 and first and second-tier retro-stepped dielectric material portion 265. The electrically conductive layers (146, 246) extend from the first memory array region 100A to the second memory array region 100B through the bridge region 350 of the inter-array region 300.

For each contiguous combination of a first-tier alternating stack (132, 146) and an overlying second-tier alternating stack (232, 246), a respective first backside trench fill structure 76 laterally extends along the first horizontal direction hd1 (e.g., word line direction) and contacts first sidewalls of the first-tier alternating stack (132, 146) and first sidewalls of the second-tier alternating stack (232, 246), and a second backside trench fill structure 76 laterally extends along the first horizontal direction hd1 and contacts second sidewalls of the first-tier alternating stack (132, 146) and second sidewalls of the second-tier alternating stack (232, 246). The first backside trench fill structure 76 can contact each layer within the first-tier alternating stack (132, 146) and the second-tier alternating stack (232, 246), and can contact a sidewall of the first-tier retro-stepped dielectric material portion 165. The second backside trench fill structure 76 can contact each layer within the first-tier alternating stack (132, 146) and the second-tier alternating stack (232, 246), and can be laterally spaced from the first-tier retro-stepped dielectric material portion 165. The backside trench fill structure 76 can be laterally offset from each of the first backside trench fill structure 76 and the second backside trench fill structure 76.

For each contiguous combination of a first-tier alternating stack (132, 146) and an overlying second-tier alternating stack (232, 246), first memory opening fill structures 58 can be located within a first memory array region 100A in which each layer of the first-tier alternating stack and each layer of the second-tier alternating stack are present. Second memory opening fill structures 58 can be located within a second memory array region 100B that is laterally offset along the first horizontal direction hd1 from the first memory array region 100A by the first-tier retro-stepped dielectric material portion 165, the second-tier retro-stepped dielectric material portion 265 and the bridge region 350. Each layer of the first-tier alternating stack (132, 146) and each layer of the second-tier alternating stack (232, 246) are present within the second memory array region 100B. At least a portion of the first electrically conductive layers 146 and at least a portion of the second electrically conductive layers 246 continuously extend from the first memory array region 100A to the second memory array region 100B through the bridge region 350 located between a backside trench fill structures 76 and the second-tier retro-stepped dielectric material portion 265, and between the backside trench fill structure 76 and the first-tier retro-stepped dielectric material portion 165.

The bridge region 350 including strips of the first insulating layers 132, the first electrically conductive layers 146, the second insulating layers 232, and the second electrically conductive layers 246 can be located between a laterally neighboring pair of backside trench fill structures 76 and adjacent to a respective first-tier retro-stepped dielectric material portion 165, a backside trench fill structure 76, and a second-tier retro-stepped dielectric material portion 265. Each layer within the first-tier alternating stack (132, 146) and the second-tier alternating stack (232, 246) comprises a respective strip portion located within bridge region 350 of the inter-array region 300 and laterally extending continuously from the first memory array region 100A to the second memory array region 100B. Thus, each strip of the first insulating layers 132, the first electrically conductive layers 146, the second insulating layers 232, and the second electrically conductive layers 246 can continuously extend from the first memory array region 100A to the second memory array region 100B.

Staircases including the first stepped surfaces and the second stepped surfaces of combinations of a first-tier alternating stack (132, 146) and an overlying second-tier alternating stack (232, 246) can rise from the substrate along the first horizontal direction hd1, or along the opposite direction of the first horizontal direction hd1. In one embodiment, the direction of rise of the staircases can change for every other pair of combinations of a respective first-tier alternating stack (132, 146) and a respective second-tier alternating stack (232, 246). In other words, the direction of rise is staggered in adjacent alternating stacks that are separated along the second horizontal direction. In one embodiment, a vertical distance between the first stepped surfaces and the substrate increases along the first horizontal direction hd1, a vertical distance between the second stepped surfaces and the substrate increases along the first horizontal direction hd1, a vertical distance between the additional first stepped surfaces and the substrate decreases along the first horizontal direction hd1, and a vertical distance between the additional second stepped surfaces and the substrate decreases along the first horizontal direction hd1.

For each contiguous combination of a first-tier alternating stack (132, 146) and an overlying second-tier alternating stack (232, 246), a first-tier retro-stepped dielectric material portion 165 overlies first stepped surfaces of the first-tier alternating stack (132, 146), and a second-tier retro-stepped dielectric material portion 265 overlies second stepped surfaces of the second-tier alternating stack (232, 246). First and second contact via structures 86 vertically extend through the first and second-tier retro-stepped dielectric material portions and contact a respective one of the first or second stepped surfaces of the respective first and second electrically conductive layers (146, 246). The first and second contact via structures 86 may comprise word line contact via structures and source-side select gate electrode contact via structures.

An additional, relatively shallow terrace region 360 may be located at the opposite end of the stepped surfaces. The surfaces of the drain-side select gate electrodes 246D may be located in the terrace region 360. Drain-side select gate electrode contact via structures 86D may extend through the second-tier retro-stepped dielectric material portion 265 to contact the drain-side select gate electrodes 246D in the terrace region 360.

Dielectric support pillars 320, hybrid support structures 328 and optional support pillar structures 20 are located in the inter-array region 300. The hybrid support structures 328 of the third exemplary structure may include hybrid support structures (120, 228) described with reference to the first exemplary structure, or may include hybrid support structures (128, 220) described with reference to the second exemplary structure. In case the hybrid support structures 328 of the third exemplary structure include hybrid support structures (120, 228) described with reference to the first exemplary structure, the processing steps described with reference to the first exemplary structure may be employed to form such hybrid support structures 328, In case the hybrid support structures 328 of the third exemplary structure include hybrid support structures (128, 220) described with reference to the second exemplary structure, the processing steps described with reference to the second exemplary structure may be employed to form such hybrid support structures 328. The hybrid support structures 328 may be located in the terrace region 360.

The dielectric support pillars 320 may have the same structure as the dielectric support pillars 120 of the first embodiment or the dielectric support pillars 220 of the second embodiment. The dielectric support pillars 320 may extend through the stepped surfaces of the first and second electrically conductive layers (146, 246) in the respective staircase regions.

In some embodiments, the support pillar structures (if present) 20 of the third exemplary structure may have the same structure as the support pillar structures 20 described with reference to the first exemplary structure or the second exemplary structure. The support pillar structures 20 (if present) may be located in the bridge region 350 and/or in other remaining portions of the inter-array region 300.

Laterally-isolated vertical interconnection structures (484, 486) can be formed through the inter-array region 300. Each laterally-isolated vertical interconnection structure (484, 486) can include a through-memory-level conductive via structure 486 and a tubular insulating spacer 484 that laterally surrounds the conductive via structure 486. Each through-memory-level conductive via structure 486 can contact a lower-level metal interconnect structure 780 located in the lower-level dielectric material layers 760, as shown in FIGS. 38D and 38F. The lower-level metal interconnect structures 780 can be embedded in the lower-level dielectric material layers 760, which are located between the first-tier alternating stack (132, 146) and a substrate (not shown) that can be provided underneath the lower-level dielectric material layers 760. The laterally-isolated vertical interconnection structures (484, 486) vertically extend through the strip portions of the first-tier alternating stack (132, 146) and the second-tier alternating stack (232, 246), and contact a respective one of the lower-level metal interconnect structures 780.

Drain contact via structures can extend through the contact-level dielectric layer 280, and can contact an upper portion of a respective memory opening fill structure 58 (such as a drain region within the respective memory opening fill structure 58). Bit lines (not shown) can laterally extend along the second horizontal direction hd2, and can contact top surfaces of a respective subset of the drain contact via structures. Additional metal interconnect structures embedded in overlying dielectric material layers (not shown) may be employed to provide electrical connection among the various nodes of the three-dimensional memory device located in the semiconductor die 1000.

Referring to all drawings and according to various embodiments of the present disclosure, a three-dimensional memory device is provided, which comprises: a first-tier alternating stack (132, 146) of first insulating layers 132 and first electrically conductive layers 146; a second-tier alternating stack (232, 246) of second insulating layers 232 and second electrically conductive layers 246 overlying the first-tier alternating stack (132, 146); memory openings 49 vertically extending through the second-tier alternating stack (232, 246) and the first-tier alternating stack (132, 146); memory opening fill structures 58 located in the memory openings 49, wherein each of the memory opening fill structures 58 comprises a respective vertical stack of memory elements and a respective vertical semiconductor channel 60 including a respective portion of a semiconductor material; and hybrid support structures {(120, 228), (128, 220), 328} vertically extending at least through a respective subset of layers within the first-tier alternating stack (132, 146), wherein each of the hybrid support structures {(120, 228), (128, 220), 328} comprises a respective vertical stack of a dielectric support pillar (120 or 220) and a composite support pillar (128 or 228) having a respective dielectric outer surface and including a respective additional portion of the semiconductor material.

In one embodiment, a subset of the hybrid support structures {(120, 228), (128, 220), 328} vertically extends through each layer within the first-tier alternating stack (132, 146) and the second-tier alternating stack (232, 246). In one embodiment, the three-dimensional memory device comprises: a first stepped dielectric material portion 165 overlying first stepped surfaces of the first-tier alternating stack (132, 146); and a second stepped dielectric material portion 265 overlying second stepped surfaces of the second-tier alternating stack (232, 246), wherein a first subset of the hybrid support structures {(120, 228), (128, 220), 328} vertically extends through each layer within the first-tier alternating stack (132, 146), a respective subset of layers within the second-tier alternating stack (232, 246), and the second retro-stepped dielectric material portion. In one embodiment, a second subset of the hybrid support structures {(120, 228), (128, 220), 328} vertically extends through the first stepped dielectric material portion 165 and the second stepped dielectric material portion 265 and does not extend through the second-tier alternating stack (232, 246).

In one embodiment, each vertical stack of memory elements comprises portions of a memory material; and each composite support pillar (128 or 228) structure includes a respective additional portion of the memory material.

In one embodiment, each of the memory opening fill structures 58 comprises a respective blocking dielectric layer 52 laterally surrounding the respective vertical stack of memory elements; and each of the composite support pillars (128 or 228) comprises a respective blocking dielectric layer 52 laterally having a same material composition as the blocking dielectric layers 52 in the memory opening fill structures 58.

In one embodiment, each of the memory opening fill structures 58 comprises a respective dielectric core 62 comprising a respective portion of a dielectric fill material; and each of the composite support pillars (128 or 228) comprises a respective dielectric core 62 comprising a respective additional portion of the dielectric fill material.

In one embodiment, each additional portion of the semiconductor material in the composite support pillars (128 or 228) has a lesser vertical extent than the vertical semiconductor channels 60 in the memory opening fill structures 58.

In one embodiment, the memory opening fill structures 58 and the hybrid support structures {(120, 228), (128, 220), 328} have a same height.

In one embodiment, the three-dimensional memory device comprises support pillar structures vertically extending through at least a bottommost layer within the first-tier alternating stack (132, 146), having a same height as the memory opening fill structures 58, and comprising a respective vertical semiconductor channel 60 having a same height as vertical semiconductor channels 60 within the memory opening fill structures 58. In one embodiment, each of the dielectric support pillars (120, 220) consists essentially of a dielectric material and entirely fills a respective support opening (129, 229) extending at least through one of the first-tier alternating stack or the second-tier alternating stack.

In the first and second embodiments, backside trenches 79 extend through the first-tier alternating stack and the second-tier alternating stack. The hybrid support structures {(120, 228), (128, 220)} are located closer to the backside trenches 79 than the support pillar structures 20.

In the first embodiment, the dielectric support pillar 120 underlies the composite support pillar 229 within each of the hybrid support structures (120, 228). In the first embodiment, the dielectric support pillars (120 or 220) have top surfaces located within a horizontal plane including a bottom surface of the second-tier alternating stack (232, 246).

In the second embodiment, the dielectric support pillar 220 overlies the composite support pillar 128 within each of the hybrid support structures (128, 220). In the second embodiment, the dielectric support pillars (120 or 220) may have contoured bottom surfaces having a vertical extent that is greater than a thickness of a bottommost layer within the second-tier alternating stack (232, 246).

In the third embodiment, additional dielectric support pillars 320 vertically extend through at least a bottommost layer within the first-tier alternating stack and having a same height as the memory opening fill structures 58. The hybrid support structures 328 are located in a terrace region 360 containing drain-side select gate electrode contact via structures 86 which contact drain-side select gate electrodes 246D.

The various embodiments of the present disclosure provide a multi-tier memory device containing hybrid support structures {(120, 228), (128, 220), 328} reduce the likelihood of electrical shorts caused by lateral tilting, bending or bulging of the backside trenches 79, while maintaining a high structural strength to increase the process yield and the reliability of multi-tier memory device.

Although the foregoing refers to particular embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A three-dimensional memory device, comprising:
a first-tier alternating stack of first insulating layers and first electrically conductive layers;
a second-tier alternating stack of second insulating layers and second electrically conductive layers overlying the first-tier alternating stack;
memory openings vertically extending through the second-tier alternating stack and the first-tier alternating stack;
memory opening fill structures located in the memory openings, wherein each of the memory opening fill structures comprises a respective vertical stack of memory elements and a respective vertical semiconductor channel including a respective portion of a semiconductor material; and
hybrid support structures vertically extending at least through a respective subset of layers within the first-tier alternating stack, wherein each of the hybrid support structures comprises a respective vertical stack of a dielectric support pillar and a composite support pillar having a respective dielectric outer surface and including a respective additional portion of the semiconductor material.

2. The three-dimensional memory device of claim 1, wherein a subset of the hybrid support structures vertically extends through each layer within the first-tier alternating stack and the second-tier alternating stack.

3. The three-dimensional memory device of claim 1, further comprising:
a first stepped dielectric material portion overlying first stepped surfaces of the first-tier alternating stack; and
a second stepped dielectric material portion overlying second stepped surfaces of the second-tier alternating stack,
wherein a first subset of the hybrid support structures vertically extends through each layer within the first-tier alternating stack, a respective subset of layers within the second-tier alternating stack, and the second retro-stepped dielectric material portion.

4. The three-dimensional memory device of claim 3, wherein a second subset of the hybrid support structures vertically extends through the first stepped dielectric material portion and the second stepped dielectric material portion and does not extend through the second-tier alternating stack.

5. The three-dimensional memory device of claim 1, wherein:
each vertical stack of memory elements comprises portions of a memory material; and
each composite support pillar includes a respective additional portion of the memory material.

6. The three-dimensional memory device of claim 1, wherein:
each of the memory opening fill structures comprises a respective blocking dielectric layer laterally surrounding the respective vertical stack of memory elements; and
each of the composite support pillars comprises a respective blocking dielectric layer laterally having a same material composition as the blocking dielectric layers in the memory opening fill structures.

7. The three-dimensional memory device of claim 1, wherein:
each of the memory opening fill structures comprises a respective dielectric core comprising a respective portion of a dielectric fill material; and
each of the composite support pillars comprises a respective dielectric core comprising a respective additional portion of the dielectric fill material.

8. The three-dimensional memory device of claim 1, wherein each additional portion of the semiconductor material in the composite support pillars has a lesser vertical extent than the vertical semiconductor channels in the memory opening fill structures.

9. The three-dimensional memory device of claim 1, wherein the memory opening fill structures and the hybrid support structures have a same height.

10. The three-dimensional memory device of claim 1, further comprising support pillar structures vertically extending through at least a bottommost layer within the first-tier alternating stack, having a same height as the memory opening fill structures, and comprising a respective vertical semiconductor channel having a same height as vertical semiconductor channels within the memory opening fill structures.

11. The three-dimensional memory device of claim 10, wherein each of the dielectric support pillars consists essentially of a dielectric material and entirely fills a respective support opening extending at least through one of the first-tier alternating stack or the second-tier alternating stack.

12. The three-dimensional memory device of claim 10, further comprising backside trenches extending through the first-tier alternating stack and the second-tier alternating stack, wherein the hybrid support structures are located closer to the backside trenches than the support pillar structures.

13. The three-dimensional memory device of claim 1, further comprising additional dielectric support pillars vertically extending through at least a bottommost layer within the first-tier alternating stack and having a same height as the memory opening fill structures, wherein the hybrid support structures are located in a terrace region containing drain-side select gate electrode contact via structures which contact drain-side select gate electrodes.

14. The three-dimensional memory device of claim 1, wherein the dielectric support pillar underlies the composite support pillar within each of the hybrid support structures.

15. The three-dimensional memory device of claim 1, wherein the dielectric support pillar overlies the composite support pillar within each of the hybrid support structures.

16. A method of forming a three-dimensional memory device, comprising:
forming a first-tier alternating stack of first insulating layers and first sacrificial material layers over a substrate;
forming first-tier memory openings and first-tier support openings through the first-tier alternating stack;
forming first-tier sacrificial memory opening fill structures in the first-tier memory openings;
forming dielectric support pillars in the first-tier support openings;
forming a second-tier alternating stack of second insulating layers and second sacrificial material layers over the second-tier alternating stack;
forming second-tier memory openings over the first-tier sacrificial memory opening fill structures and forming second-tier support openings over the dielectric support pillars;
forming inter-tier memory openings by removing the first-tier sacrificial memory opening fill structures from underneath the second-tier memory openings;
forming memory opening fill structures in the inter-tier memory openings and forming composite support pillars in the second-tier support openings by depositing and patterning at least a memory material and a semiconductor material in each of the inter-tier memory openings and the second-tier support openings, wherein each of the memory opening fill structures comprises a respective vertical stack of memory elements comprising portions of the memory material and a respective vertical semiconductor channel comprising a portion of the semiconductor material; and
replacing the first sacrificial material layers and the second sacrificial material layers with first electrically conductive layers and second electrically conductive layers, respectively.

17. The method of claim 16, wherein:
the dielectric support pillars comprise a different material than the first-tier sacrificial memory opening fill structures; and
the first-tier sacrificial memory opening fill structures are removed by performing a selective removal process that removes a material of the first-tier sacrificial memory opening fill structures selective to a material of the dielectric pillar structures.

18. The method of claim 16, wherein the forming the memory opening fill structures and the composite support pillars comprises depositing and patterning a layer stack including a blocking dielectric layer, a memory material layer including the memory material, and a semiconductor channel material layer including the semiconductor material in each of the inter-tier memory openings and the second-tier support openings.

19. A method of forming a three-dimensional memory device, comprising:
forming a first-tier alternating stack of first insulating layers and first sacrificial material layers over a substrate;
forming a second-tier alternating stack of second insulating layers and second sacrificial material layers over the second-tier alternating stack;
forming inter-tier memory openings and inter-tier support openings that vertically extend through the first-tier alternating stack and the second-tier alternating stack;
forming memory opening fill structures and support pillar structures in the inter-tier memory openings and in the inter-tier support openings, respectively, by depositing and patterning at least a memory material and a semiconductor material in each of the inter-tier memory openings and the inter-tier support openings, wherein each of the memory opening fill structures and the support pillar structures comprises a respective vertical stack of memory elements comprising portions of the memory material and a respective vertical semiconductor channel comprising a portion of the semiconductor material;
replacing an upper portion of each of the support pillar structures with a dielectric support pillar, wherein a remaining portion of each of the support pillar structures comprises a composite support pillar including a respective remaining portion of the memory material and a respective remaining portion of the semiconductor material; and
replacing the first sacrificial material layers and the second sacrificial material layers with first electrically conductive layers and second electrically conductive layers, respectively.

20. The method of claim 19, further comprising:
forming a patterned etch mask layer over the second-tier alternating stack after formation of the memory opening fill structures and the support pillar structures, wherein openings in the patterned etch mask layer overlie a subset of the support pillar structures; and
forming cavities in the upper portions of the subset of the support pillar structures by etching materials within the support pillar structures by performing an anisotropic etch process while the patterned etch mask layer is present over the second-tier alternating stack.
